(19) United States
(12) Patent Application Publication
(10) Pub. No.: US 2026/0271339 A1
(43) Pub. Date: Sep. 10, 2026

(54) SEMICONDUCTOR DEVICE AND METHOD FOR MANUFACTURING SEMICONDUCTOR DEVICE

(71) Applicant: Semiconductor Energy Laboratory Co., Ltd., Atsugi-shi, Kanagawa-ken (JP)

(72) Inventors: Takahiro IGUCHI, Nikko (JP); Masami JINTYOU, Shimotsuga (JP)

(21) Appl. No.: 19/164,702

(22) PCT Filed: Mar. 25, 2024
(86) PCT No.: PCT/IB2024/052819

§ 371 Date: Sep. 12, 2025

(30) Foreign Application Priority Data
Mar. 31, 2023 (JP) 2023-057493

(51) Int. Cl. H10D 30/67; H10D 30/01; H10D 86/01; H10D 86/40; H10D 86/60; H10K 59/121; H10K 59/122; H10K 59/123; H10K 65/00

(52) U.S. Cl. CPC H10D 30/6728; H10D 30/0318; H10D 30/6734; H10D 30/6736; H10D 30/6755; H10D 30/6757; H10D 86/0221; H10D 86/423; H10D 86/431; H10D 86/471; H10D 86/60; H10K 59/1213; H10K 59/122; H10K 59/123; H10K 65/00

(57) ABSTRACT

Provided is a semiconductor device including a transistor having high saturation. The semiconductor device is provided with a vertical transistor including a back gate electrode. In the semiconductor device, a lower electrode, a spacer, and an upper electrode are provided in this order. The spacer includes a first opening portion reaching the lower electrode, and the upper electrode includes a second opening portion including a region overlapping with the first opening portion. The back gate electrode is provided in the first opening portion and includes a region in contact with the lower electrode. A back gate insulating layer, a semiconductor layer, a gate insulating layer, and a gate electrode are provided in this order to cover the back gate electrode. After the formation of the first opening portion and the second opening portion, a conductive film is formed to cover the first opening portion and is subjected to anisotropic etching, whereby the back gate electrode can be formed. An insulating film is formed to cover the back gate electrode and is subjected to anisotropic etching, whereby the back gate insulating layer can be formed.

### TECHNICAL FIELD

One embodiment of the present invention relates to a semiconductor device and a method for manufacturing the semiconductor device. One embodiment of the present invention relates to a transistor and a method for manufacturing the transistor. One embodiment of the present invention relates to a display device that includes a semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### BACKGROUND ART

Semiconductor devices that include transistors are applied to a wide range of electronic devices. In a display device, for example, when transistors occupy smaller areas, the pixel size can be smaller and higher resolution can be achieved. Therefore, miniaturization of transistors has been required.

As devices requiring high-resolution display devices, for example, devices for virtual reality (VR), augmented reality (AR), substitutional reality (SR), or mixed reality (MR) have been actively developed.

As display devices, for example, light-emitting apparatuses that include organic EL (Electro Luminescence) elements or light-emitting diodes (LEDs) have been developed.

Patent Document 1 discloses a high-resolution display device that includes an organic EL element.

### REFERENCE

### Patent Document

[Patent Document 1] International Publication No. 2016/038508

### SUMMARY OF THE INVENTION

### Problems to be Solved by the Invention

When a transistor is miniaturized to have a short channel length, the saturation of the transistor becomes poor. For example, when a driving transistor that controls current flowing through a light-emitting element (also referred to as a light-emitting device) in a pixel included in a display device is miniaturized, the channel length of the driving transistor becomes short. When the saturation of the driving transistor becomes low, the current flowing through the light-emitting element becomes unstable and the emission luminance of the light-emitting element becomes unstable in some cases. For example, a time-related variation might be caused in the current flowing through the light-emitting element, leading to a time-related variation in emission luminance of the light-emitting element even in still image display.

In this specification and the like, “high saturation” refers to a small change (a small slope) in current in a saturation region in Id-Vd characteristics of a transistor. Similarly, “low saturation” refers to a large change (a large slope) in current in a saturation region in Id-Vd characteristics of a transistor.

An object of one embodiment of the present invention is to provide a transistor having high saturation. Another object is to provide a miniaturized transistor. Another object is to provide a transistor having favorable electrical characteristics. Another object is to provide a semiconductor device including any of these transistors. Another object is to provide a highly reliable semiconductor device. Another object is to provide a display device capable of displaying a high-quality image.

Another object is to provide a small semiconductor device. Another object is to provide a semiconductor device having low wiring resistance. Another object is to provide a semiconductor device that is driven at high speed. Another object is to provide an inexpensive semiconductor device. Another object is to provide a semiconductor device with low power consumption. Another object is to provide a high-resolution display device. Another object is to provide a method for manufacturing a semiconductor device with high productivity. Another object is to provide a method for manufacturing a semiconductor device at a low manufacturing cost. Another object is to provide a novel transistor, semiconductor device, or display device and a manufacturing method thereof.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a semiconductor device including a transistor and a first insulating layer. The transistor includes a first conductive layer, a second conductive layer, a third conductive layer, a fourth conductive layer, a semiconductor layer, a second insulating layer, and a third insulating layer. The first insulating layer includes a first opening portion that is provided over the first conductive layer and reaches the first conductive layer. The second conductive layer includes a second opening portion that is provided over the first insulating layer and includes a region overlapping with the first opening portion. The third conductive layer includes a region in contact with the side surface of the first insulating layer that is positioned in the first opening portion. The third conductive layer includes a region in contact with the first conductive layer. The uppermost portion of the third conductive layer is positioned below the end portion of the top surface of the first insulating layer on the first opening portion side. The second insulating layer is provided to cover the third conductive layer in the first opening portion. The semiconductor layer is provided to include a region in contact with the first conductive layer and a region in contact with the second conductive layer and to include a region facing the third conductive layer with the second insulating layer therebetween in the first opening portion. The third insulating layer is provided over the semiconductor layer to include a region positioned in the first opening portion. The fourth conductive layer is provided to include a region facing the third conductive layer with the second insulating layer, the semiconductor layer, and the third insulating layer therebetween in the first opening portion.

Alternatively, in the above embodiment, the semiconductor device may include a fourth insulating layer. The fourth insulating layer may be provided between the first insulating layer and the third insulating layer. The fourth insulating layer may include a region in contact with the side surface of the second conductive layer on a side opposite to the second opening portion.

Alternatively, in the above embodiment, the second insulating layer may include a region positioned over the first insulating layer. The second conductive layer may be provided over the second insulating layer.

Alternatively, in the above embodiment, the semiconductor layer may include a metal oxide. the metal oxide may include two or three selected from In, an element M, and Zn, and the element M may be one or more selected from Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb.

Another embodiment of the present invention is a method for manufacturing a semiconductor device, the method including: forming a first conductive layer; forming a first insulating layer over the first conductive layer; forming a second conductive layer over the first insulating layer; processing the second conductive layer to form a first opening portion including a region overlapping with the first conductive layer; processing the first insulating layer to form a second opening portion that includes a region overlapping with the first opening portion and reaches the first conductive layer; forming a conductive film covering the first opening portion and the second opening portion; performing anisotropic etching on the conductive film to form a third conductive layer that includes a region in contact with the first conductive layer and has the uppermost portion positioned below the end portion of the bottom surface of the second conductive layer on the first opening portion side; forming an insulating film covering the second conductive layer and the third conductive layer; performing anisotropic etching on the insulating film until at least part of the top surface of the second conductive layer is exposed to form a second insulating layer covering the third conductive layer; forming a semiconductor layer including a region in contact with the first conductive layer and a region in contact with the second conductive layer; forming a third insulating layer including a region positioned in the second opening portion; and forming, over the third insulating layer, a fourth conductive layer including a region positioned in the second opening portion.

Another embodiment of the present invention is a method for manufacturing a semiconductor device, the method including: forming a first conductive layer; forming a first insulating layer over the first conductive layer; processing the first insulating layer to form a first opening portion reaching the first conductive layer; forming a conductive film covering the first opening portion; performing anisotropic etching on the conductive film to form a second conductive layer that includes a region in contact with the first conductive layer and has the uppermost portion positioned below the end portion of the top surface of the first insulating layer on the first opening portion side; forming a second insulating layer covering the first conductive layer, the second conductive layer, and the first insulating layer; forming, over the second insulating layer, a third conductive layer including a second opening portion including a region overlapping with the first opening portion; forming, in the second insulating layer, a third opening portion reaching the first conductive layer in the first opening portion; forming a semiconductor layer comprising a region in contact with the first conductive layer and a region in contact with the third conductive layer; forming a third insulating layer including a region positioned in the first opening portion; forming, over the third insulating layer, a fourth conductive layer including a region positioned in the first opening portion.

Alternatively, in the above embodiment, the semiconductor layer may be formed by forming a semiconductor film by an ALD method and then processing the semiconductor film.

### Effect of the Invention

According to one embodiment of the present invention, a transistor having high saturation can be provided. Alternatively, a miniaturized transistor can be provided. Alternatively, a transistor having favorable electrical characteristics can be provided. Alternatively, a semiconductor device including any of these transistors can be provided. Alternatively, a highly reliable semiconductor device can be provided. Alternatively, a display device capable of displaying a high-quality image can be provided.

Alternatively, a small semiconductor device can be provided. Alternatively, a semiconductor device having low wiring resistance can be provided. Alternatively, a semiconductor device that is driven at high speed can be provided. Alternatively, an inexpensive semiconductor device can be provided. Alternatively, a semiconductor device with low power consumption can be provided. Alternatively, a high-resolution display device can be provided. Alternatively, a method for manufacturing a semiconductor device with high productivity can be provided. Alternatively, a method for manufacturing a semiconductor device at a low manufacturing cost can be provided. Alternatively, a novel transistor, semiconductor device, or display device and a manufacturing method thereof can be provided.

Note that the description of these effects does not preclude the existence of other effects. One embodiment of the present invention does not need to have all of these effects. Other effects can be derived from the description of the specification, the drawings, and the claims.

### BRIEF DESCRIPTION OF THE DRAWINGS

FIG. 1A is a plan view illustrating a structure example of a semiconductor device. FIG. 1B and

FIG. 1C are cross-sectional views illustrating the structure example of the semiconductor device.

FIG. 2A to FIG. 2C are plan views illustrating a structure example of a semiconductor device.

FIG. 3A is a plan view illustrating a structure example of a semiconductor device. FIG. 3B is a cross-sectional view illustrating the structure example of the semiconductor device.

FIG. 4A and FIG. 4B are cross-sectional views illustrating structure examples of a semiconductor device.

FIG. 5 is a cross-sectional view illustrating a structure example of a semiconductor device.

FIG. 6A is a plan view illustrating a structure example of a semiconductor device. FIG. 6B is a cross-sectional view illustrating the structure example of the semiconductor device.

FIG. 7A, FIG. 7B1, and FIG. 7B2 are cross-sectional views illustrating structure examples of a semiconductor device.

FIG. 8 is a cross-sectional view illustrating a structure example of a semiconductor device.

FIG. 9 is a cross-sectional view illustrating a structure example of a semiconductor device.

FIG. 10A is a plan view illustrating a structure example of a semiconductor device. FIG. 10B is a cross-sectional view illustrating the structure example of the semiconductor device.

FIG. 11A is a plan view illustrating a structure example of a semiconductor device. FIG. 11B and FIG. 11C are cross-sectional views illustrating the structure example of the semiconductor device.

FIG. 12A to FIG. 12D are plan views illustrating examples of opening portion shapes.

FIG. 13A is a block diagram illustrating a structure example of a display device. FIG. 13B is a plan view illustrating a structure example of a pixel. FIG. 13C and FIG. 13D are circuit diagrams illustrating structure examples of the pixel.

FIG. 14A to FIG. 14D are circuit diagrams illustrating structure examples of a pixel.

FIG. 15A is a plan view illustrating a structure example of a pixel. FIG. 15B is a cross-sectional view illustrating a structure example of a pixel.

FIG. 16A to FIG. 16I are circuit diagrams illustrating structure examples of a semiconductor device.

FIG. 17A is a plan view illustrating a structure example of a semiconductor device. FIG. 17B is a cross-sectional view illustrating a structure example of a semiconductor device.

FIG. 18A and FIG. 18B are cross-sectional views illustrating structure examples of a semiconductor device.

FIG. 19A and FIG. 19B are cross-sectional views illustrating a structure example of a semiconductor device.

FIG. 20A is a plan view illustrating a structure example of a semiconductor device. FIG. 20B is a cross-sectional view illustrating the structure example of the semiconductor device.

FIG. 21A and FIG. 21B are cross-sectional views illustrating a structure example of a semiconductor device.

FIG. 22A is a plan view illustrating a structure example of a semiconductor device. FIG. 22B is a cross-sectional view illustrating the structure example of the semiconductor device.

FIG. 23A is a plan view illustrating a structure example of a semiconductor device. FIG. 23B is a cross-sectional view illustrating the structure example of the semiconductor device.

FIG. 24A is a plan view illustrating a structure example of a semiconductor device. FIG. 24B is a cross-sectional view illustrating the structure example of the semiconductor device.

FIG. 25A to FIG. 25C are cross-sectional views illustrating an example of a method for manufacturing a semiconductor device.

FIG. 26A to FIG. 26C are cross-sectional views illustrating an example of a method for manufacturing a semiconductor device.

FIG. 27A to FIG. 27C are cross-sectional views illustrating an example of a method for manufacturing a semiconductor device.

FIG. 28A and FIG. 28B are cross-sectional views illustrating an example of a method for manufacturing a semiconductor device.

FIG. 29A and FIG. 29B are cross-sectional views illustrating an example of a method for manufacturing a semiconductor device.

FIG. 30A to FIG. 30C are cross-sectional views illustrating an example of a method for manufacturing a semiconductor device.

FIG. 31A to FIG. 31C are cross-sectional views illustrating an example of a method for manufacturing a semiconductor device.

FIG. 32A to FIG. 32C are cross-sectional views illustrating an example of a method for manufacturing a semiconductor device.

FIG. 33A and FIG. 33B are cross-sectional views illustrating an example of a method for manufacturing a semiconductor device.

FIG. 34A to FIG. 34G are plan views illustrating structure examples of a pixel.

FIG. 35A to FIG. 35K are plan views illustrating structure examples of a pixel.

FIG. 36 is a perspective view illustrating a structure example of a display device.

FIG. 37A and FIG. 37B are cross-sectional views illustrating structure examples of display devices.

FIG. 38 is a cross-sectional view illustrating a structure example of a display device.

FIG. 39A to FIG. 39C are cross-sectional views illustrating structure examples of a display device.

FIG. 40A and FIG. 40B are cross-sectional views illustrating structure examples of display devices.

FIG. 41 is a cross-sectional view illustrating a structure example of a display device.

FIG. 42 is a cross-sectional view illustrating a structure example of a display device.

FIG. 43 is a cross-sectional view illustrating a structure example of a display device.

FIG. 44A and FIG. 44B are cross-sectional views illustrating structure examples of display devices.

FIG. 45A to FIG. 45D are diagrams illustrating examples of electronic devices.

FIG. 46A to FIG. 46F are diagrams illustrating examples of electronic devices.

FIG. 47A to FIG. 47G are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). In some cases, an ordinal number used for a component in a certain part in this specification is not the same as an ordinal number used for the component in another part in this specification or claims.

Note that the terms “film” and “layer” can be used interchangeably depending on the case or the circumstances. For example, the term “conductive layer” can be replaced with the term “conductive film” in some cases. For another example, the term “insulating layer” can be replaced with the term “insulating film” in some cases. For another example, the term “semiconductor layer” can be replaced with the term “semiconductor film” in some cases.

A transistor is a kind of semiconductor element and can achieve a function of amplifying current or voltage, a switching operation for controlling conduction or non-conduction, and the like. An IGFET (Insulated Gate Field Effect Transistor) and a thin film transistor (TFT) are in the category of a transistor in this specification.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

In this specification and the like, the term “electrically connected” includes the case where components are connected to each other through an “object having any electric action”. Here, there is no particular limitation on the “object having any electric function” as long as electric signals can be transmitted and received between the components that are connected through the object. Examples of the “object having any electric function” include a switching element such as a transistor, a resistor, a coil, and other elements with a variety of functions as well as an electrode or a wiring.

Unless otherwise specified, an off-state current in this specification and the like refers to a leakage current between a source and a drain generated when a transistor is in an off state (also referred to as a non-conducting state or a cutoff state). Unless otherwise specified, an off state of an n-channel transistor refers to a state where a voltage V_{gs} between its gate and source is lower than a threshold voltage Vₜₕ (in a p-channel transistor, higher than Vₜₕ).

In this specification and the like, normally-on characteristics mean a state where a channel exists without application of voltage to a gate and current flows through a transistor. Furthermore, normally-off characteristics mean a state where current does not flow through a transistor when no potential or a ground potential is applied to a gate.

In this specification and the like, the expression “having substantially the same plan-view shapes” means that the outlines of stacked layers at least partly overlap with each other. For example, the expression encompasses the case of processing an upper layer and a lower layer with the use of the same mask pattern or mask patterns that are partly the same. The expression “having substantially the same plan-view shapes” also sometimes encompasses the case where the outlines do not completely overlap with each other; for instance, the outline of the upper layer may be positioned inward or outward from the outline of the lower layer. In the case where plan-view shapes are the same or substantially the same, it can be said that end portions match or substantially match each other.

In this specification and the like, a plan-view shape of a component means the contour shape of the component in a plan view. A plan view means that the component is observed from a normal direction of a surface where the component is formed or from a normal direction of a surface of a support (e.g., a substrate) where the component is formed.

In this specification and the like, a tapered shape refers to such a shape that at least part of a side surface of a component is inclined with respect to a substrate surface or a formation surface. For example, a tapered shape preferably includes a region where the angle between the inclined side surface and the substrate surface or the formation surface (such an angle is also referred to as a taper angle) is greater than 0° and less than 90°. Note that the side surface, the substrate surface, and the formation surface of the component are not necessarily completely flat, and may have a substantially planar shape with a small curvature or a substantially planar shape with slight unevenness.

Note that in this specification and the like, an oxynitride refers to a material in which the oxygen content is higher than the nitrogen content. A nitride oxide refers to a material in which the nitrogen content is higher than the oxygen content. Here, an oxide film encompasses a film including an oxynitride, and a nitride film encompasses a film including a nitride oxide.

In this specification and the like, when the expression “A is in contact with B” is used, at least part of A is in contact with B. In other words, A includes a region in contact with B, for example.

In this specification and the like, when the expression “A is provided over B” is used, at least part of A is provided over B. In other words, A includes a region provided over B, for example.

In this specification and the like, when the expression “A overlaps with B” is used, at least part of A overlaps with B. In other words, A includes a region overlapping with B, for example.

In this specification and the like, a device formed using a metal mask or an FMM (fine metal mask, high-resolution metal mask) may be referred to as a device having an MM (metal mask) structure. In this specification and the like, a device manufactured without using a metal mask or an FMM is sometimes referred to as a device having an MML (metal maskless) structure.

In this specification and the like, a structure in which light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can extend the freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, the light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may also be referred to as a mask layer) refers to a layer that is positioned above at least a light-emitting layer (specifically, a layer processed into an island shape among layers included in an EL layer) and has a function of protecting the light-emitting layer in the manufacturing process.

In this specification and the like, an island shape refers to a state where two or more layers formed using the same material in the same step are physically separated from each other. For example, an island-shaped light-emitting layer refers to a state where the light-emitting layer and its adjacent light-emitting layer are physically separated from each other.

In this specification and the like, step disconnection refers to a phenomenon in which a layer, a film, or an electrode is split because of the shape of its formation surface (e.g., a step).

### Embodiment 1

In this embodiment, structure examples of a semiconductor device of one embodiment of the present invention and a manufacturing method example thereof are described.

In a transistor included in the semiconductor device of one embodiment of the present invention (also referred to as a transistor of one embodiment of the present invention), a source electrode and a drain electrode are positioned at different levels, and current flows in the height direction in a semiconductor layer. In other words, the channel length direction can be regarded as having a component of the height direction (vertical direction); accordingly, the transistor of one embodiment of the present invention can also be referred to as a vertical transistor, a vertical channel-type transistor, a vertical-channel transistor, or the like.

Specifically, an insulating layer functioning as a spacer is provided between a lower electrode that is one of the source electrode and the drain electrode of the transistor and an upper electrode that is the other of the source electrode and the drain electrode of the transistor. Note that in the following description, an insulating layer functioning as a spacer is sometimes simply referred to as a spacer, and a spacer may be rephrased as an insulating layer. A first opening portion reaching the lower electrode is provided in the spacer, and a second opening portion including a region overlapping with the first opening portion is provided in the upper electrode.

The semiconductor layer where a channel is formed is provided to include a region in contact with the lower electrode and a region in contact with the upper electrode and to include the region positioned in the first opening portion and the region positioned in the second opening portion. A gate insulating layer and a gate electrode are provided in the first opening portion and the second opening portion to overlap with the semiconductor layer. Since the source electrode, the semiconductor layer, and the drain electrode can be provided to overlap with each other, the area occupied by the transistor can be significantly smaller than that of what is called a planar transistor in which a semiconductor layer is positioned over a plane.

The transistor with the above structure in which the channel length direction has a vertical component can have a channel length having a value smaller than that of the definition limit of a light-exposure apparatus. This enables the transistor to have a high on-state current. However, the shorter the channel length is, the lower the saturation of the transistor is in some cases. Thus, when the transistor is used as a driving transistor of a light-emitting apparatus, for example, the current flowing through a light-emitting element becomes unstable and the emission luminance of the light-emitting element becomes unstable in some cases. For example, a time-related variation might be caused in the current flowing through the light-emitting element, leading to a time-related variation in emission luminance of the light-emitting element even in still image display.

In this specification and the like, a driving transistor in a light-emitting apparatus refers to a transistor having a function of controlling current flowing through a light-emitting element in a pixel included in a display device. For example, one of the source and the drain of the driving transistor can be electrically connected to one electrode of the light-emitting element. In the case where the pixel includes a capacitor, one electrode of the capacitor can be electrically connected to one of the source and the drain of the driving transistor and one electrode of the light-emitting element, and the other electrode of the capacitor can be electrically connected to the gate of the driving transistor.

The transistor of one embodiment of the present invention is provided with a back gate electrode. The back gate electrode is provided in the first opening portion included in the spacer. For example, the back gate electrode is provided to include a region in contact with the side surface of the spacer that is positioned in the first opening portion and a region in contact with the top surface of the lower electrode. Note that the gate electrode may be referred to as a front gate electrode. Alternatively, the gate electrode may be referred to as a first gate electrode, and the back gate electrode may be referred to as a second gate electrode. Alternatively, the back gate electrode may be referred to as a first gate electrode, and the gate electrode may be referred to as a second gate electrode.

The back gate electrode is electrically connected to the lower electrode that is one of the source electrode and the drain electrode of the transistor. Accordingly, when the lower electrode functions as the source electrode of the transistor, generation of a DIBL (Drain-Induced Barrier Lowering) effect, a phenomenon in which a band barrier between the source and the channel of the transistor is lowered due to a drain electric field, is inhibited. This can increase the saturation of the transistor. The display device in which the transistor having high saturation is used, specifically, is used as a driving transistor of a light-emitting apparatus is capable of displaying a high-quality image. Note that in the case where the lower electrode functions as the drain electrode of the transistor in one embodiment of the present invention, the transistor can function as a diode.

In manufacturing such a transistor, first, the lower electrode, the spacer, and the upper electrode are formed in this order. Next, the second opening portion and the first opening portion are formed in the upper electrode and in the spacer, respectively. After that, a conductive film is formed to cover the first opening portion. Specifically, the conductive film is formed to cover the side surface of the spacer that is positioned in the first opening portion and the top surface of the lower electrode exposed by the first opening portion. For example, the conductive film is formed to include a region in contact with the side surface of the spacer that is positioned in the first opening portion and a region in contact with the lower electrode.

After the formation of the conductive film, anisotropic etching is performed on the conductive film. In this manner, the back gate electrode can be formed in the first opening portion to be electrically connected to the lower electrode. The back gate electrode can be formed, along the side surface of the spacer that is positioned in the first opening portion, to include a region in contact with the lower electrode in the first opening portion.

Then, an insulating film is formed to cover the back gate electrode. Then, anisotropic etching is performed on the insulating film to form a back gate insulating layer covering the back gate electrode. Note that the gate insulating layer may be referred to as a front gate insulating layer. Alternatively, the gate insulating layer may be referred to as a first gate insulating layer, and the back gate insulating layer may be referred to as a second gate insulating layer. Alternatively, the back gate insulating layer may be referred to as a first gate insulating layer, and the gate insulating layer may be referred to as a second gate insulating layer.

Then, the semiconductor layer, the gate insulating layer, and the gate electrode are formed. Through the above steps, the transistor of one embodiment of the present invention can be formed.

In the case where the back gate electrode is formed by anisotropic etching, unlike in the case where the back gate electrode is formed by a photolithography method, a mask is not needed, for example. Thus, with the use of anisotropic etching, a back gate electrode can be formed regardless of the alignment accuracy of a mask, for example. This can prevent, even when the first opening portion in which the back gate electrode is formed is miniaturized, the case where the back gate electrode is not formed in the first opening portion, for example. Thus, the transistor of one embodiment of the present invention can have a minute size.

### <Structure Example 1 of Semiconductor Device>

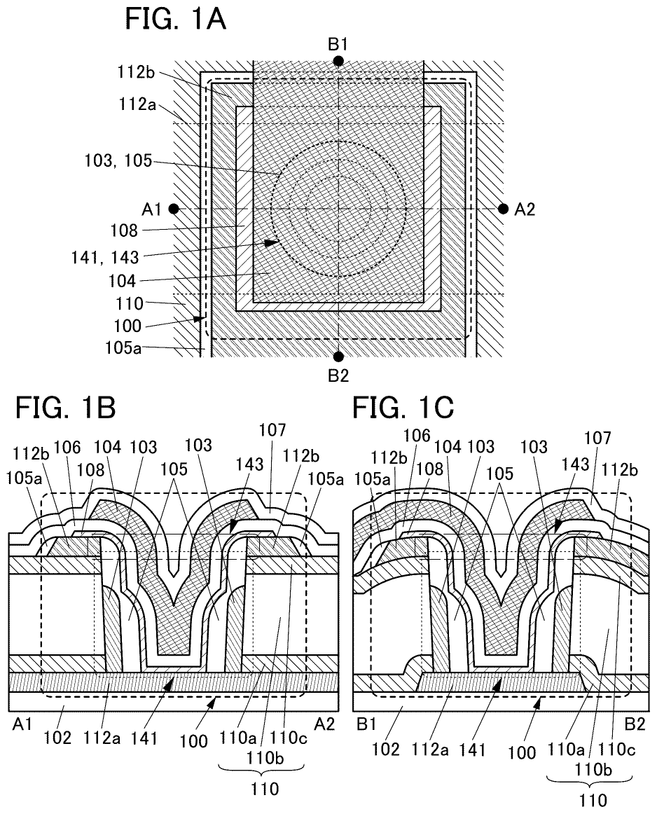

FIG. 1A is a plan view illustrating a structure example of the semiconductor device of one embodiment of the present invention, and illustrates a structure example of a transistor 100. Some components are omitted in FIG. 1A. Some components are omitted also in the following plan views.

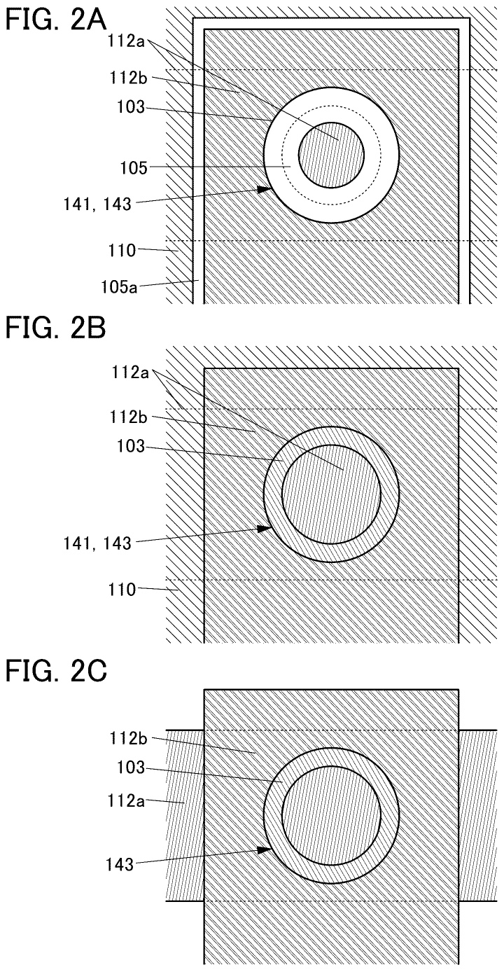

FIG. 1B is a cross-sectional view taken along the dashed-dotted line A1-A2 in FIG. 1A, and FIG. 1C is a cross-sectional view taken along the dashed-dotted line B1-B2 in FIG. 1A. FIG. 2A, FIG. 2B, and FIG. 2C are plan views in which some components in FIG. 1A are omitted.

The semiconductor device of one embodiment of the present invention includes a substrate 102, an insulating layer 110 over the substrate 102, and the transistor 100. The transistor 100 includes a conductive layer 112a, a conductive layer 112b, a conductive layer 103, an insulating layer 105, a semiconductor layer 108, an insulating layer 106, and a conductive layer 104. The layers included in the transistor 100 may each have a single-layer structure or a stacked-layer structure.

The conductive layer 112a is provided over the substrate 102. The conductive layer 112a functions as one of the source electrode and the drain electrode of the transistor 100.

The insulating layer 110 is provided over the substrate 102 and the conductive layer 112a. The insulating layer 110 can include a region in contact with the top surface of the conductive layer 112a and a region in contact with the side surface of the conductive layer 112a. The insulating layer 110 is provided with an opening portion 141 reaching the conductive layer 112a. An insulating layer may be provided between the substrate 102 and both the conductive layer 112a and the insulating layer 110. The insulating layer functions as abase insulating layer, for example.

The conductive layer 112b is provided over the insulating layer 110. The conductive layer 112b can include a region in contact with the top surface of the insulating layer 110. The conductive layer 112b is provided with an opening portion 143 including a region overlapping with the opening portion 141. The conductive layer 112b functions as the other of the source electrode and the drain electrode of the transistor 100.

As described above, the conductive layer 112a is provided under the insulating layer 110, and the conductive layer 112b is provided over the insulating layer 110. Thus, the conductive layer 112a can be referred to as a lower electrode of the transistor 100, and the conductive layer 112b can be referred to as an upper electrode of the transistor 100. As described above, the conductive layer 112a functions as the one of the source electrode and the drain electrode of the transistor 100, and the conductive layer 112b functions as the other of the source electrode and the drain electrode of the transistor 100. Thus, in the transistor 100, the one of the source electrode and the drain electrode is the lower electrode, and the other of the source electrode and the drain electrode is the upper electrode. The insulating layer 110 has a function of a spacer for controlling the distance between the lower electrode and the upper electrode of the transistor 100.

The insulating layer 110 has a stacked-layer structure of an insulating layer 110a over the substrate 102 and the conductive layer 112a, an insulating layer 110b over the insulating layer 110a, and an insulating layer 110c over the insulating layer 110b. That is, the insulating layer 110 has a stacked-layer structure of three layers in the example illustrated in FIG. 1B and FIG. 1C. Note that the insulating layer 110 does not necessarily have a stacked-layer structure of three layers and, for example, may have a single-layer structure.

The insulating layer 110a can include a region in contact with the top surface of the conductive layer 112a and a region in contact with the side surface of the conductive layer 112a. The insulating layer 110c can include a region in contact with the bottom surface of the conductive layer 112b. In other words, the conductive layer 112b can include a region in contact with the top surface of the insulating layer 110c.

The conductive layer 112b is provided with the opening portion 143 in a region overlapping with the conductive layer 112a. It is preferable that the conductive layer 112b not be provided in the opening portion 141. In other words, it is preferable that the conductive layer 112b not include a region in contact with the side surface of the insulating layer 110 that is positioned in the opening portion 141.

The conductive layer 103 is provided to be positioned in the opening portion 141 and to be electrically connected to the conductive layer 112a. The conductive layer 103 includes a region in contact with the conductive layer 112a, for example, and is provided along the side surface of the insulating layer 110 that is positioned in the opening portion 141. The conductive layer 103 can include a region in contact with the side surface of the insulating layer 110 that is positioned in the opening portion 141. Note that in the case where the region where the conductive layer 103 and the conductive layer 112a are in contact with each other is included, the boundary between the conductive layer 103 and the conductive layer 112a cannot be clearly recognized in some cases.

The uppermost portion of the conductive layer 103 is preferably positioned below the end portion of the top surface of the insulating layer 110 on the opening portion 141 side. That is, the conductive layer 103 is preferably not provided in the opening portion 143 included in the conductive layer 112b. This can prevent a short circuit due to contact between the conductive layer 103 and the conductive layer 112b, for example. Although FIG. 1B and FIG. 1C illustrate an example in which the conductive layer 103 is in contact with the side surfaces of the insulating layer 110a and the insulating layer 110b that are positioned in the opening portion 141 and is not in contact with the side surface of the insulating layer 110c that is positioned in the opening portion 141, the conductive layer 103 may include a region in contact with the side surface of the insulating layer 110c that is positioned in the opening portion 141.

The conductive layer 103 can be formed in the following manner: a conductive film is formed to cover the opening portion 141 and the opening portion 143, and then anisotropic etching is performed on the conductive film. In this manner, the conductive layer 112a can be formed in the opening portion 141 to be electrically connected to the conductive layer 112a.

In the case where the conductive layer 103 is formed by anisotropic etching, unlike in the case where the conductive layer 103 is formed by a photolithography method, a mask is not needed, for example. Thus, with the use of anisotropic etching, the conductive layer 103 can be formed regardless of the alignment accuracy of a mask, for example. This can prevent, even when the opening portion 141 in which the conductive layer 103 is formed is miniaturized, the case where the conductive layer 103 is not formed in the opening portion 141, for example. Thus, the transistor 100 can have a minute size.

The insulating layer 105 is provided to cover the conductive layer 103 in the opening portion 141. The insulating layer 105 includes, for example, a region in contact with the conductive layer 103 and a region in contact with the conductive layer 112a in the opening portion 141.

The insulating layer 105 can be formed in the following manner: an insulating film is formed to cover the opening portion 141 and the opening portion 143, and then anisotropic etching is performed on the insulating film. Here, in the case where anisotropic etching is performed until at least part of the top surface of the conductive layer 112b is exposed, for example, the uppermost portion of the insulating layer 105 can be aligned or substantially aligned with the top surface of the conductive layer 112b. In the case where the uppermost portion of the insulating layer 105 is aligned or substantially aligned with the top surface of the conductive layer 112b, the insulating layer 105 can include a region in contact with the side surface of the conductive layer 112b that is positioned in the opening portion 143.

By performing the anisotropic etching on the insulating layer 105, an insulating layer 105a is sometimes provided to cover the side surface of the conductive layer 112b, specifically, at least part of the side surface of the conductive layer 112b on the side opposite to the opening portion 143. The insulating layer 105a can include a region in contact with the side surface of the conductive layer 112b on the side opposite to the opening portion 143. The insulating layer 105a is formed in some cases because of the step of forming the insulating layer 105. For example, in the case where the uppermost portion of the insulating layer 105 is positioned above the top surface of the insulating layer 110, e.g., the end portion of the top surface of the insulating layer 110 on the opening portion 141 side, the insulating layer 105a is sometimes provided. For example, in the case where the insulating layer 105 includes a region in contact with the side surface of the conductive layer 112b that is positioned in the opening portion 143, the insulating layer 105a is sometimes provided. The insulating layer 105a is formed as a residue in forming the insulating layer 105, for example. Note that the insulating layer 105a is sometimes not provided. For example, in the case where the uppermost portion of the insulating layer 105 is aligned with the top surface of the insulating layer 110, e.g., the end portion of the top surface of the insulating layer 110 on the opening portion 141 side, or is positioned below the top surface of the insulating layer 110, the insulating layer 105a is sometimes not provided.

Forming the insulating layer 105 so as to provide the insulating layer 105a can prevent the conductive layer 103 from being exposed by the anisotropic etching. This can prevent a short circuit due to contact between the conductive layer 103 and the semiconductor layer 108.

FIG. 2A is a diagram in which the conductive layer 104 and the semiconductor layer 108 in FIG. 1A are omitted. As illustrated in FIG. 2A, the insulating layer 105 is provided along the outer peripheries of the opening portion 141 and the opening portion 143 in a plan view, in the opening portion 141 and the opening portion 143.

FIG. 2B is a diagram in which the insulating layer 105 in FIG. 2A is further omitted. As illustrated in FIG. 1B, FIG. 1C, and FIG. 2B, the conductive layer 103 is provided along the outer periphery of the opening portion 141, in a plan view in the opening portion 141.

FIG. 2C is a diagram in which the insulating layer 110 in FIG. 2B is further omitted. As illustrated in FIG. 2C, the opening portion 143 included in the conductive layer 112b includes a region overlapping with the conductive layer 103.

The semiconductor layer 108 includes a region positioned in the opening portion 141 and a region positioned in the opening portion 143. The semiconductor layer 108 is provided to cover the insulating layer 105. The semiconductor layer 108 includes a region in contact with the conductive layer 112a, a region in contact with the insulating layer 105, and a region in contact with the conductive layer 112b. The semiconductor layer 108 is provided to include a region facing the conductive layer 103 with the insulating layer 105 therebetween in the opening portion 141. In other words, the semiconductor layer 108 is provided to include a region overlapping with the semiconductor layer 108 with the insulating layer 105 therebetween in the opening portion 141.

The insulating layer 106 is provided over the insulating layer 110 to cover the insulating layer 105a, the conductive layer 112b, and the semiconductor layer 108. The insulating layer 106 is provided over the semiconductor layer 108 to include a region positioned in the opening portion 141 and a region positioned in the opening portion 143. The insulating layer 106 functions as the gate insulating layer of the transistor 100.

In the case where the insulating layer 105a is provided in the semiconductor device of one embodiment of the present invention, the insulating layer 105a is provided between the insulating layer 110 and the insulating layer 106. As described above, the insulating layer 105a can include a region in contact with the side surface of the conductive layer 112b on the side opposite to the opening portion 143.

The conductive layer 104 is provided over the insulating layer 106. The conductive layer 104 includes a region positioned in the opening portion 141 and a region positioned in the opening portion 143. The conductive layer 104 is provided to include a region facing the semiconductor layer 108 with the insulating layer 106 therebetween in the opening portion 141 and in the opening portion 143. In other words, the conductive layer 104 is provided to include a region overlapping with the semiconductor layer 108 with the insulating layer 106 therebetween in the opening portion 141 and the opening portion 143. The conductive layer 104 functions as the gate electrode of the transistor 100.

As described above, the semiconductor layer 108 is provided to include a region facing the conductive layer 103 with the insulating layer 105 therebetween in the opening portion 141. The conductive layer 104 is provided to include a region facing the semiconductor layer 108 with the insulating layer 106 therebetween in the opening portion 141. Thus, the conductive layer 104 is provided to include a region facing the conductive layer 103 with the insulating layer 105, the semiconductor layer 108, and the insulating layer 106 therebetween in the opening portion 141. In other words, the conductive layer 104 includes a region overlapping with the conductive layer 103 with the insulating layer 105, the semiconductor layer 108, and the insulating layer 106 therebetween in the opening portion 141.

Accordingly, not only the conductive layer 104 but also the conductive layer 103 can function as the gate electrode of the transistor 100. In this case, the conductive layer 103 can be referred to as a back gate electrode. In the case where the conductive layer 103 is referred to as a back gate electrode, the conductive layer 104 may be referred to as a front gate electrode. Alternatively, the conductive layer 104 can be referred to as a first gate electrode, and the conductive layer 103 can be referred to as a second gate electrode. Note that the conductive layer 103 may be referred to as a first gate electrode, and the conductive layer 104 may be referred to as a second gate electrode. Hereinafter, the conductive layer 103 is referred to as a back gate electrode.

The back gate electrode of the transistor 100 includes a region in contact with the top surface of the conductive layer 112a in the opening portion 141. Thus, the potential of the conductive layer 112a is supplied to the back gate electrode of the transistor 100. Accordingly, when the conductive layer 112a functions as the source electrode of the transistor 100, generation of the DIBL effect is inhibited. Thus, the saturation of the transistor 100 can be higher than that of a transistor that does not include the conductive layer 103, for example. The display device in which the transistor 100 having high saturation is used, specifically, is used as a driving transistor of a light-emitting apparatus is capable of displaying a high-quality image. Note that in the case where the conductive layer 112a functions as the drain electrode of the transistor 100, the transistor 100 can function as a diode.

As described above, a driving transistor in a light-emitting apparatus refers to a transistor having a function of controlling current flowing through a light-emitting element in a pixel included in a display device. For example, one of the source and the drain of the driving transistor can be electrically connected to one electrode of the light-emitting element.

The conductive layer 112a, the conductive layer 112b, and the conductive layer 104 can function as wirings, and the transistor 100 can be provided in the region where these wirings overlap with each other. That is, the areas occupied by the transistor 100 and the wirings can be reduced in a circuit including the transistor 100 and the wirings. Accordingly, the area occupied by the circuit can be reduced, which makes it possible to provide a small semiconductor device.

An insulating layer 107 is provided over the conductive layer 104 and the insulating layer 106. The insulating layer 107 is provided to cover the conductive layer 104.

The insulating layer 107 functions as a protective layer. The insulating layer 107 is preferably formed using a material that does not easily allow diffusion of impurities. Providing the insulating layer 107 can favorably inhibit diffusion of impurities to the transistor 100 from the outside and increase the reliability of the semiconductor device. Examples of the impurities include water and hydrogen. The insulating layer 107 includes, for example, one or both of an inorganic insulating film and an organic insulating film. The insulating layer 107 may have a stacked-layer structure of an inorganic insulating film and an organic insulating film.

In the case where the insulating layer 107 is formed using an inorganic insulating film, the insulating layer 107 can be formed using a material that can be used for the insulating layer 110. Examples of the inorganic insulating film usable for the insulating layer 107 include an oxide insulating film and a nitride insulating film. Specifically, the insulating layer 107 can be formed using one or more of silicon nitride, silicon nitride oxide, silicon oxynitride, aluminum oxide, aluminum oxynitride, aluminum nitride, hafnium oxide, and hafnium aluminate. In the case where the insulating layer 107 is formed using an organic insulating film, one or both of an acrylic resin and a polyimide resin can be used, for example.

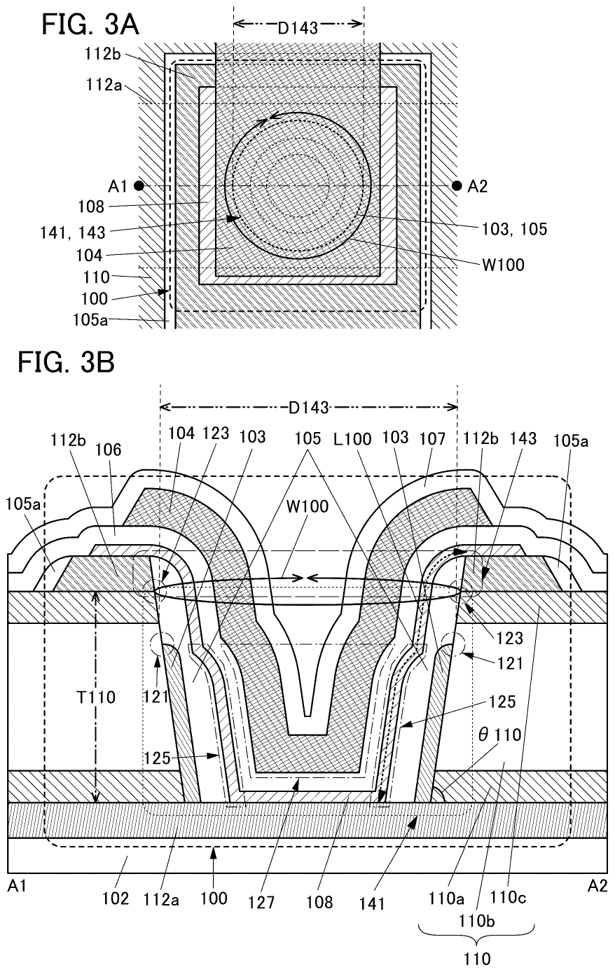

FIG. 3A is a plan view illustrating the structure example of the semiconductor device of one embodiment of the present invention, and illustrates the structure example of the transistor 100. FIG. 3A is the plan view of FIG. 1A where a width D143 and a channel width W100 are shown. FIG. 3B is an enlarged view including the structure illustrated in FIG. 1B and illustrates the structure example of the transistor 100. FIG. 3B is a cross-sectional view taken along the dashed-dotted line A1-A2 in FIG. 3A. In FIG. 3B, the width D143, the channel width W100, a channel length L100, a thickness T 110, and an angle θ110 are shown.

In the semiconductor layer 108, a region in contact with the conductive layer 112a functions as one of a source region and a drain region, a region in contact with the conductive layer 112b functions as the other of the source region and the drain region, and a region between the source region and the drain region functions as a channel formation region.

In FIG. 3B, the channel length L100 of the transistor 100 is indicated by a dotted double-headed arrow. As illustrated in FIG. 3B, in a cross-sectional view, the channel length L100 can be the shortest distance between a portion of the semiconductor layer 108 that is in contact with the conductive layer 112a and a portion of the semiconductor layer 108 that is in contact with the conductive layer 112b.

The channel length L100 of the transistor 100 depends on the thickness T110 of the insulating layer 110 and the angle θ110 formed by the side surface of the insulating layer 110 that is positioned in the opening portion 141 and the formation surface of the insulating layer 110 (which is the top surface of the conductive layer 112a here). Thus, the channel length L100 can have a value smaller than that of the definition limit of a light-exposure apparatus, for example, which enables the transistor to have a minute size. Specifically, it is possible to obtain a transistor with an extremely short channel length that could not be obtained with the use of a conventional light-exposure apparatus for mass production of flat panel displays (the minimum line width: approximately 2 μm or approximately 1.5 μm, for example). Moreover, it is also possible to obtain a transistor with a channel length shorter than 10 nm without using an extremely expensive light-exposure apparatus used in the latest LSI technology.

The channel length L100 is preferably greater than or equal to 0.01 μm and less than 3.0 m, further preferably greater than or equal to 0.05 μm and less than 3.0 μm, further preferably greater than or equal to 0.10 μm and less than 3.0 μm, further preferably greater than or equal to 0.15 μm and less than 3.0 μm, further preferably greater than or equal to 0.20 μm and less than 3.0 μm, further preferably greater than or equal to 0.20 μm and less than 2.5 μm, further preferably greater than or equal to 0.20 μm and less than 2.0 μm, further preferably greater than or equal to 0.20 μm and less than 1.5 μm, further preferably greater than or equal to 0.30 μm and less than 1.5 μm, further preferably greater than or equal to 0.30 μm and less than or equal to 1.2 μm, further preferably greater than or equal to 0.40 μm and less than or equal to 1.2 μm, further preferably greater than or equal to 0.40 μm and less than or equal to 1.0 μm, further preferably greater than or equal to 0.50 μm and less than or equal to 1.0 μm.

When the channel length L100 is small, the transistor 100 can have a high on-state current. With the use of the transistor 100, a circuit capable of high-speed operation can be manufactured. Thus, the use of the semiconductor device of one embodiment of the present invention for a display device can increase the frame frequency of the display device.

By adjusting the thickness T 110 of the insulating layer 110 and the angle θ110, the channel length L100 can be controlled. Note that in FIG. 3B, the thickness T110 of the insulating layer 110 is indicated by the dashed-dotted double-headed arrow.

The thickness T110 of the insulating layer 110 is preferably greater than or equal to 0.01 m and less than 3.0 μm, further preferably greater than or equal to 0.05 μm and less than 3.0 μm, further preferably greater than or equal to 0.10 μm and less than 3.0 μm, further preferably greater than or equal to 0.15 μm and less than 3.0 μm, further preferably greater than or equal to 0.20 μm and less than 3.0 μm, further preferably greater than or equal to 0.20 μm and less than 2.5 μm, further preferably greater than or equal to 0.20 μm and less than 2.0 μm, further preferably greater than or equal to 0.20 μm and less than 1.5 μm, further preferably greater than or equal to 0.30 μm and less than 1.5 μm, further preferably greater than or equal to 0.30 μm and less than or equal to 1.2 μm, further preferably greater than or equal to 0.40 μm and less than or equal to 1.2 μm, further preferably greater than or equal to 0.40 μm and less than or equal to 1.0 μm, further preferably greater than or equal to 0.50 μm and less than or equal to 1.0 μm.

The channel width W100 depends on the plan-view shape of the opening portion 143. In FIG. 3A and FIG. 3B, the width D143 of the opening portion 143 is indicated by the dashed double-dotted double-headed arrow. In the plan view, the width D143 corresponds to the short side of the smallest rectangle that is circumscribed around the opening portion 143. In the case where the opening portion 143 is formed by a photolithography method, the width D143 of the opening portion 143 is larger than or equal to the definition limit of a light-exposure apparatus. For example, the width D143 is preferably greater than or equal to 0.20 μm and less than 5.0 μm, further preferably greater than or equal to 0.20 μm and less than 4.5 μm, further preferably greater than or equal to 0.20 μm and less than 4.0 μm, further preferably greater than or equal to 0.20 μm and less than 3.5 μm, further preferably greater than or equal to 0.20 μm and less than 3.0 μm, further preferably greater than or equal to 0.20 μm and less than 2.5 μm, further preferably greater than or equal to 0.20 μm and less than 2.0 μm, further preferably greater than or equal to 0.20 μm and less than 1.5 μm, further preferably greater than or equal to 0.30 μm and less than 1.5 μm, further preferably greater than or equal to 0.30 μm and less than or equal to 1.2 μm, further preferably greater than or equal to 0.40 μm and less than or equal to 1.2 μm, further preferably greater than or equal to 0.40 μm and less than or equal to 1.0 μm, further preferably greater than or equal to 0.50 μm and less than or equal to 1.0 μm. Note that when the plan-view shape of the opening portion 143 is a circular shape, the width D143 corresponds to the diameter of the opening portion 143, and a channel width W10 can be equal to the length of the outer periphery of the opening portion 143 in the plan view and calculated to be “D143×π”.

The width of the opening portion 141 and the width of the opening portion 143 are sometimes different from each other. Each of the width of the opening portion 141 and the width of the opening portion 143 varies from position to position in the depth direction in some cases. The average value of the following three widths can be used as the width of the opening portion, for example: the width at the highest level of the insulating layer 110 in a cross-sectional view, the width at the lowest level of the insulating layer 110 in a cross-sectional view, and the width at the midpoint between these levels. For another example, any of the width at the highest level of the insulating layer 110 in a cross-sectional view, the width at the lowest level of the insulating layer 110 in a cross-sectional view, and the width at the midpoint between these levels can be used as the width of the opening portion.

For example, the plan-view shapes of the opening portion 141 and the opening portion 143 are preferably circular shapes as illustrated in FIG. 3A. When the plan-view shapes of the opening portions are circular shapes, processing accuracy at the time of formation of the opening portions can be high, whereby the opening portions can be formed to have minute sizes. Note that in this specification and the like, a circle is not necessarily a perfect circular shape.

In this specification and the like, the plan-view shape of the opening portion 141 refers to the shape of the end portion of the top surface of the insulating layer 110 on the opening portion 141 side. The plan-view shape of the opening portion 143 refers to the shape of the end portion of the bottom surface of the conductive layer 112b on the opening portion 143 side.

As illustrated in FIG. 3A, the opening portion 141 and the opening portion 143 can have the same plan-view shape or substantially the same plan-view shapes, for example. In that case, it is preferable that the end portion of the bottom surface of the conductive layer 112b on the opening portion 143 side be aligned with or substantially aligned with the end portion of the top surface of the insulating layer 110 on the opening portion 141 side as illustrated in FIG. 3B, for example. The bottom surface of the conductive layer 112b refers to the surface thereof on the insulating layer 110 side. The top surface of the insulating layer 110 refers to the surface thereof on the conductive layer 112b side.

The side surface of the insulating layer 110 that is positioned in the opening portion 141 preferably has a tapered shape or a vertical shape. The angle θ110 between the side surface of the insulating layer 110 that is positioned in the opening portion 141 and the formation surface of the insulating layer 110 (which is the top surface of the insulating layer 110a here) is preferably less than or equal to 90°. When the angle θ110 is small, the coverage with the layer provided over the insulating layer 110 (e.g., the semiconductor layer 108) can be increased. The smaller the angle θ110 is, the larger the channel length L100 is. The larger the angle θ110 is, the smaller the channel length L100 is. In the example illustrated in FIG. 1B, FIG. 1C, and FIG. 3B, the side surface of the insulating layer 110 that is positioned in the opening portion 141 has a tapered shape (the angle θ110 is less than 90°).

In FIG. 3B, a portion 121 refers to the uppermost portion of the conductive layer 103. A portion 123 refers to the end portion of the top surface of the insulating layer 110 on the opening portion 141 side. As described above, the portion 121 is preferably positioned below the portion 123. This can prevent a short circuit due to contact between the conductive layer 103 and the conductive layer 112b, for example. Although FIG. 3B illustrates an example in which the conductive layer 103 is in contact with the side surfaces of the insulating layer 110a and the insulating layer 110b that are positioned in the opening portion 141 and is not in contact with the side surface of the insulating layer 110c that is positioned in the opening portion 141, the conductive layer 103 may include a region in contact with the side surface of the insulating layer 110c that is positioned in the opening portion 141.

In FIG. 3B, a region 125 refers to a region of the semiconductor layer 108 that faces the conductive layer 103. The region 125 faces the conductive layer 103 with the insulating layer 105 therebetween. In FIG. 3B, a region 127 refers to a region of the conductive layer 104, which functions as the gate electrode of the transistor 100, that faces the conductive layer 103. The region 127 and the conductive layer 103 face each other with the insulating layer 105, the semiconductor layer 108, and the insulating layer 106 therebetween.

The electric field of the conductive layer 103 functioning as the back gate electrode can be applied to the region 125. The electric field of the conductive layer 103 can also be applied to a region in the vicinity of the region 125 in some cases. As described above, the potential of the conductive layer 112a functioning as the one of the source electrode and the drain electrode of the transistor 100 is supplied to the conductive layer 103. Accordingly, when the conductive layer 112a functions as the source electrode of the transistor 100, generation of the DIBL effect in the region 125 and its vicinity is inhibited, for example, as compared with the case where the transistor 100 does not include the conductive layer 103. Thus, as described above, the saturation of the transistor 100 can be higher than that of a transistor that does not include the conductive layer 103, for example.

Here, the shorter the distance between the portion 121 and the portion 123 is, i.e., the smaller the difference between the height of the portion 123 from the surface of the substrate 102 and the height of the portion 121 from the surface of the substrate 102 is, the larger the area of the region 125 can be. This can reduce the area of a region of the channel formation region of the semiconductor layer 108 to which the electric field of the conductive layer 103 is not supplied. Accordingly, generation of the DIBL effect can be favorably inhibited so that the saturation of the transistor 100 can be improved. Meanwhile, the longer the distance between the portion 121 and the portion 123 is, i.e., the larger the difference between the height of the portion 123 from the surface of the substrate 102 and the height of the portion 121 from the surface of the substrate 102 is, the more a short circuit due to contact between the conductive layer 103 and the conductive layer 112b can be inhibited. Thus, the height of the portion 121 from the surface of the substrate 102 is preferably as high as possible in a range where the conductive layer 103 is not in contact with the conductive layer 112b. As the height of the portion 121 from the surface of the substrate 102 is higher, not only the area of the region 125 but also the area of the region 127 can be larger.

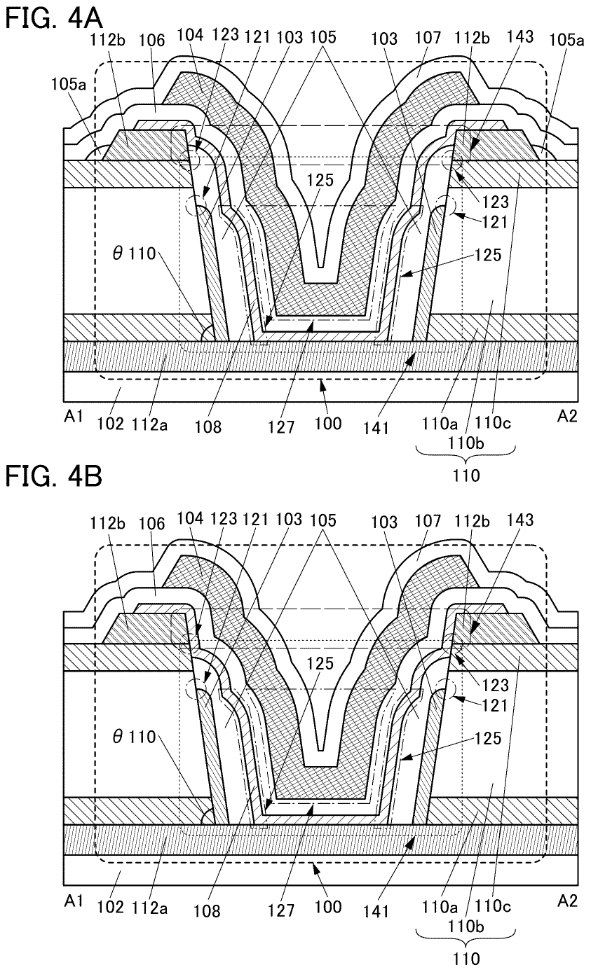

FIG. 3B illustrates an example in which the uppermost portion of the insulating layer 105 and the uppermost portion of the insulating layer 105a are aligned or substantially aligned with the top surface of the conductive layer 112b. Specifically, the uppermost portion of the insulating layer 105 is aligned or substantially aligned with the end portion of the top surface of the conductive layer 112b on the opening portion 143 side and the uppermost portion of the insulating layer 105a is aligned or substantially aligned with the end portion of the top surface of the conductive layer 112b on the side opposite to the opening portion 143; however, one embodiment of the present invention is not limited thereto. FIG. 4A is a cross-sectional view illustrating an example in which the uppermost portion of the insulating layer 105 and the uppermost portion of the insulating layer 105a are positioned between the bottom surface and the top surface of the conductive layer 112b. In the example illustrated in FIG. 4A, the uppermost portion of the insulating layer 105 is positioned between the end portion of the bottom surface and the end portion of the top surface of the conductive layer 112b on the opening portion 143 side. The uppermost portion of the insulating layer 105a is positioned between the end portion of the bottom surface and the end portion of the top surface of the conductive layer 112b on the side opposite to the opening portion 143.

FIG. 4B is a cross-sectional view illustrating an example in which the uppermost portion of the insulating layer 105 is positioned below the bottom surface of the conductive layer 112b. In the example illustrated in FIG. 4B, the uppermost portion of the insulating layer 105 is positioned below the end portion of the bottom surface of the conductive layer 112b on the opening portion 143 side. In the example illustrated in FIG. 4B, the uppermost portion of the insulating layer 105 can be positioned below the portion 123 that is the end portion of the top surface of the insulating layer 110 on the opening portion 141 side.

In the case where the uppermost portion of the insulating layer 105 is positioned below the bottom surface of the conductive layer 112b, a structure in which the insulating layer 105a is not provided can be obtained. Note that the insulating layer 105a is sometimes not provided even when the uppermost portion of the insulating layer 105 is positioned above the bottom surface of the conductive layer 112b.

Although FIG. 4B illustrates an example in which the uppermost portion of the insulating layer 105 is positioned between the bottom surface and the top surface of the insulating layer 110c, one embodiment of the present invention is not limited thereto. For example, the uppermost portion of the insulating layer 105 may be positioned between the bottom surface and the top surface of the insulating layer 110b.

When the transistor 100 has the structure illustrated in FIG. 4A or FIG. 4B, the semiconductor layer 108 can include not only a region in contact with the top surface of the conductive layer 112b but also a region in contact with the side surface of the conductive layer 112b that is positioned in the opening portion 143. Thus, the contact area between the semiconductor layer 108 and the conductive layer 112b can be larger than that in the case where the transistor 100 has the structure illustrated in FIG. 3B, for example. Accordingly, the contact resistance between the semiconductor layer 108 and the conductive layer 112b can be reduced. This can inhibit generation of a defect such as a contact defect in the transistor 100. Meanwhile, when the transistor 100 has the structure illustrated in FIG. 3B, a short circuit due to contact between the semiconductor layer 108 and the conductive layer 103 is easily prevented as compared with the case where the transistor 100 has the structure illustrated in FIG. 4A or FIG. 4B.

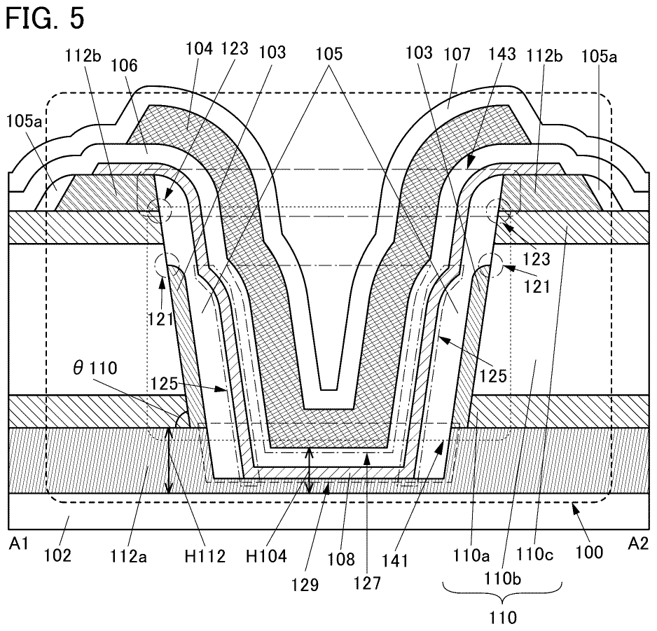

FIG. 5 is a cross-sectional view illustrating an example in which, for the conductive layer 112a illustrated in FIG. 3B, the thickness in a region in contact with the bottom surface of the semiconductor layer 108 or the bottom surface of the insulating layer 105 is smaller than the thickness in a region overlapping with the conductive layer 103 or the insulating layer 110. In the example illustrated in FIG. 5, it can be said that a depressed portion 129 is formed in a region of the conductive layer 112a that is in contact with the bottom surface of the semiconductor layer 108 or the bottom surface of the insulating layer 105.

In FIG. 5, a height H104 refers to the height from the formation surface of the conductive layer 112a (which is the top surface of the substrate 102 here) to the lowest position of the bottom surface of the conductive layer 104. A height H112 refers to the height from the top surface of the substrate 102 to the bottom surface of the insulating layer 110 or the conductive layer 103. The height H112 can be the thickness of the conductive layer 112a in a region other than the depressed portion 129.

When the height H104 is lower than the height H112, the electric field of the gate electrode applied to the channel formation region in the vicinity of the conductive layer 112a can be increased and the on-state current of the transistor 100 can be increased. In addition, the electric field of the gate electrode applied to the channel formation region can be uniform. Even when the height H104 is equal to or substantially equal to the height H112, the electric field of the gate electrode applied to the channel formation region in the vicinity of the conductive layer 112a can be increased. In addition, the electric field of the gate electrode applied to the channel formation region can be uniform.

Here, in the case where the electric field of the gate electrode applied to the channel formation region is not uniform, the electrical characteristics in the case where the conductive layer 112a is the source electrode and the conductive layer 112b is the drain electrode might be different from the electrical characteristics in the case where the conductive layer 112a is the drain electrode and the conductive layer 112b is the source electrode. By making the electric field of the gate electrode applied to the channel formation region of the transistor 100 more uniform, the electrical characteristics in the both cases can be made equivalent to each other. Thus, the transistor 100 can be suitably used in a circuit structure in which a source and a drain are interchanged with each other.

In the transistor 100 illustrated in FIG. 5, not only the conductive layer 103 but also at least part of the conductive layer 112a can also function as the back gate electrode of the transistor 100. For example, a region of the conductive layer 112a that is in contact with the side surface of the insulating layer 105 and its vicinity can function as the back gate electrode of the transistor 100. In FIG. 5, a region to which the electric field of the conductive layer 103 functioning as the back gate electrode can be applied is referred to as the region 125. In the transistor 100 illustrated in FIG. 5, the region 125 includes not only a region of the semiconductor layer 108 that faces the conductive layer 103 with the insulating layer 105 therebetween but also a region of the semiconductor layer 108 that faces the conductive layer 112a with the insulating layer 105 therebetween.

The thickness of the conductive layer 112a may be adjusted as appropriate so that the height H104 is lower than the height H112, for example. The structure of the conductive layer 112a illustrated in FIG. 5 can be used in other structure examples, e.g., structure examples illustrated in other drawings. For example, the conductive layer 112a illustrated in FIG. 4A may include the depressed portion 129. The conductive layer 112a illustrated in FIG. 4B may include the depressed portion 129.

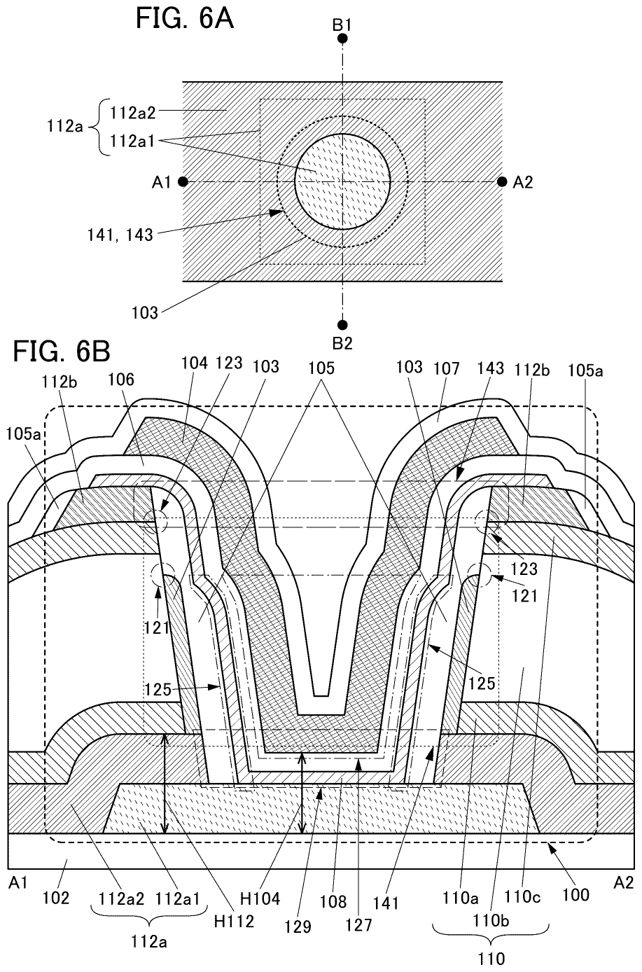

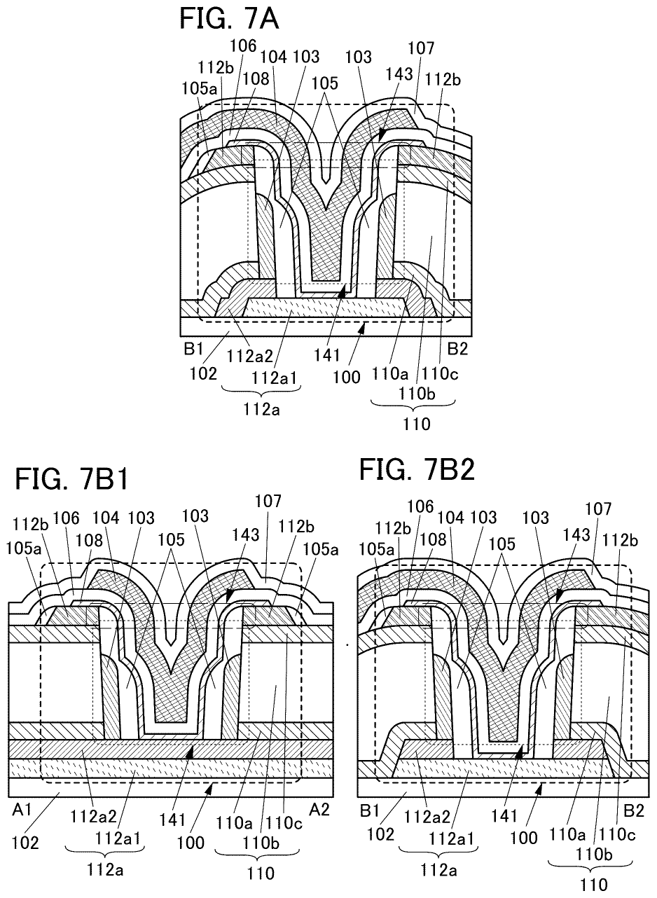

Although the conductive layer 112a has a single-layer structure in FIG. 5, for example, the conductive layer 112a may have a stacked-layer structure of a plurality of layers. FIG. 6A, FIG. 6B, and FIG. 7A are diagrams illustrating an example in which the conductive layer 112a has a stacked-layer structure of two layers of a conductive layer 112a1 and a conductive layer 112a2 including a region over the conductive layer 112a1. FIG. 6A is a plan view illustrating a structure example of the conductive layer 112a1, the conductive layer 112a2, the conductive layer 103, the opening portion 141, and the opening portion 143. Note that the conductive layer 103 is not shown with a hatching pattern in FIG. 6A. FIG. 6B is a cross-sectional view in which the conductive layer 112a illustrated in FIG. 5 corresponds to the plan view illustrated in FIG. 6A. FIG. 6B is a cross-sectional view taken along the dashed-dotted line A1-A2 in FIG. 6A. FIG. 7A is a cross-sectional view taken along the dashed-dotted line B1-B2 in FIG. 6A.

In the example illustrated in FIG. 6A, FIG. 6B, and FIG. 7A, the conductive layer 112a2 is provided to cover the side surface of the conductive layer 112a1. In the depressed portion 129 of the conductive layer 112a, the conductive layer 112a2 is removed. In the depressed portion 129, the bottom surface of the semiconductor layer 108 includes a region in contact with the top surface of the conductive layer 112a1. In the depressed portion 129, the bottom surface of the insulating layer 105 can include a region in contact with the top surface of the conductive layer 112a1, and the side surface of the insulating layer 105 can include a region in contact with the side surface of the conductive layer 112a2. The bottom surface of the conductive layer 103 includes a region in contact with the top surface of the conductive layer 112a2.

Although FIG. 6B illustrates an example in which the thickness of the conductive layer 112a1 in a region overlapping with the depressed portion 129 is equal to the thickness of the conductive layer 112a1 in a region not overlapping with the depressed portion 129, for example, one embodiment of the present invention is not limited thereto. For example, the thickness of the conductive layer 112a1 in a region overlapping with the depressed portion 129 may be smaller than the thickness of the conductive layer 112a1 in a region not overlapping with the depressed portion 129. That is, in the depressed portion 129, not only part of the conductive layer 112a2 but also part of the conductive layer 112a1 may be processed. Furthermore, in the depressed portion 129, the conductive layer 112a2 may be provided with the top surface of the conductive layer 112a1 not exposed. That is, in the depressed portion 129, the conductive layer 112a2 may partly remain without being completely removed. In this case, it can be said that the depressed portion 129 is formed in the conductive layer 112a2. In the case where the conductive layer 112a2 partly remains in the depressed portion 129, the thickness of the conductive layer 112a2 in the depressed portion 129 is smaller than the thickness of the conductive layer 112a2 in a region other than the depressed portion 129.

As illustrated in FIG. 6A and FIG. 6B, the conductive layer 112a2 includes a region extending in the A1-A2 direction. Thus, a material with low electrical resistivity, e.g., a material with lower electrical resistivity than the conductive layer 112a1, is preferably used for the conductive layer 112a2, in which case the wiring resistance of the conductive layer 112a can be reduced. For the conductive layer 112a1, it is possible to use a conductive oxide such as indium oxide, zinc oxide, In—Sn oxide, In—Zn oxide, In—W oxide, In—W—Zn oxide, In—Ti oxide, In—Ti—Sn oxide, In—Sn oxide, In—Sn—Si oxide, or Ga—Zn oxide, for example. For the conductive layer 112a2, it is possible to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like, or an alloy containing any of these metal elements as its component.

Here, a material with low electrical resistivity is preferably used for the conductive layer 103, in which case the wiring resistance of the conductive layer 103 can be reduced. For the conductive layer 103, a material similar to the material that can be used for the conductive layer 112a2 is preferably used, for example. For example, the conductive layer 112a2 and the conductive layer 103 can be formed using materials similar to each other.

In the above case, for example, the etching selectivity between the conductive layer 112a and the conductive layer 103 may be lower than that in the case where a metal is used for one of the conductive layer 112a2 and the conductive layer 103 and a conductive oxide is used for the other of the conductive layer 112a2 and the conductive layer 103. Here, as will be described in detail later, in the method for manufacturing the semiconductor device of one embodiment of the present invention, the conductive layer 103 can be formed by forming a conductive film to be the conductive layer 103 and processing the conductive film by an etching method. At the time of processing the conductive layer, the conductive layer 112a is also processed, and thus the depressed portion 129 is formed in the conductive layer 112a. Even in that case, the use of a material having high etching selectivity with respect to the conductive layer 103, e.g., a conductive oxide, for the conductive layer 112a1 can inhibit the processing of the conductive layer 112a1. Thus, the conductive layer 112a can be prevented from being completely removed in a region overlapping with the bottom surface of the semiconductor layer 108. This can prevent the case where the bottom surface of the semiconductor layer 108 is not in contact with the conductive layer 112a.

As described above, when a material having high etching selectivity with respect to the conductive layer 103 is used for the conductive layer 112a1 and a material with low electrical resistivity is used for the conductive layer 112a2, a semiconductor device having a transistor with favorable electrical characteristics and high reliability can be provided. Furthermore, since the depressed portion 129 can be easily formed in the conductive layer 112a, a transistor having a high on-state current can be easily formed as described with reference to FIG. 5.

FIG. 7B1 and FIG. 7B2 are cross-sectional views illustrating an example in which the conductive layer 112a has a stacked-layer structure of two layers of the conductive layer 112a1 and the conductive layer 112a2 over the conductive layer 112a1 and the end portion of the conductive layer 112a1 and the end portion of the conductive layer 112a2 are aligned or substantially aligned with each other. FIG. 1A can be referred to for a planar structure example of the transistor 100 illustrated in FIG. 7B1 and FIG. 7B2. FIG. 7B1 is a cross-sectional view taken along the dashed-dotted line A1-A2 in FIG. 1A. FIG. 7B2 is a cross-sectional view taken along the dashed-dotted line B1-B2 in FIG. 1A.

In the example illustrated in FIG. 7B1 and FIG. 7B2, the number of steps for forming the conductive layer 112a can be smaller than that in the example illustrated in FIG. 7A. Meanwhile, in the example illustrated in FIG. 7A, since a step on the formation surface of the layer (e.g., the insulating layer 110) formed over the conductive layer 112a is small, coverage with the layer can be improved. This can inhibit generation of a defect such as step disconnection or a void in the layer.

Although FIG. 6A to FIG. 7B2 illustrate an example in which the conductive layer 112a has a stacked-layer structure of two layers, the conductive layer 112a may have a stacked-layer structure of three or more layers. The conductive layer 112a illustrated in each of drawings other than FIG. 6A to FIG. 7B2 may have a stacked-layer structure of two layers or a stacked-layer structure of three or more layers. For example, the conductive layer 112a illustrated in FIG. 6A to FIG. 7B2 can be used as the conductive layer 112a illustrated in FIG. 1A to FIG. 4B. The conductive layer 112a illustrated in FIG. 6A to FIG. 7B2 can also be used as the conductive layer 112a illustrated in each of the following drawings.

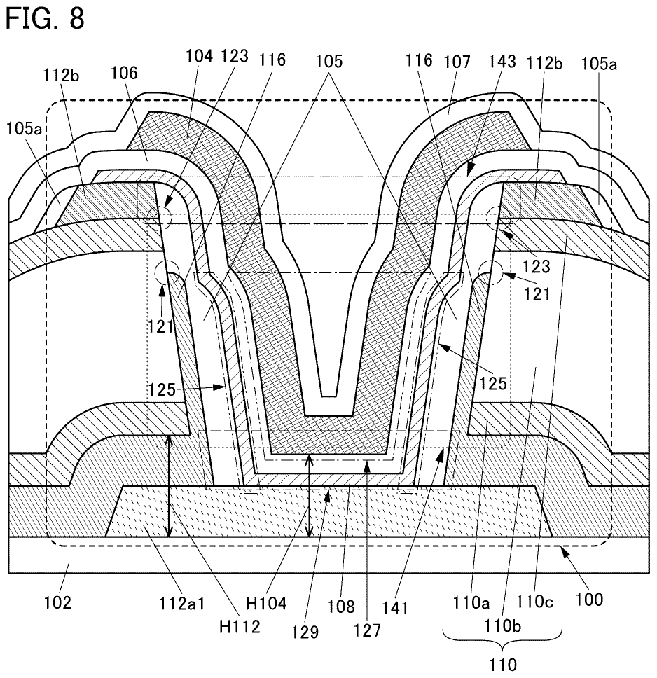

FIG. 8 is a cross-sectional view illustrating an example in which the conductive layer 112a2 and the conductive layer 103 illustrated in FIG. 6B are a conductive layer 116. For example, the boundary between the conductive layer 112a2 and the conductive layer 103 illustrated in FIG. 6B cannot be clearly seen in some cases. For example, in the case where the conductive layer 112a2 and the conductive layer 103 are formed using the same kind of material, the boundary between the conductive layer 112a2 and the conductive layer 103 cannot be seen in some cases. In that case, as illustrated in FIG. 8, the conductive layer 112a2 and the conductive layer 103 may be seen as one conductive layer 116. Note that even when the conductive layer 112a has a single-layer structure, the boundary between the conductive layer 112a2 and the conductive layer 103 cannot be clearly seen in some cases, as described above. In that case, the conductive layer 112a and the conductive layer 103 may be seen as one conductive layer 116.

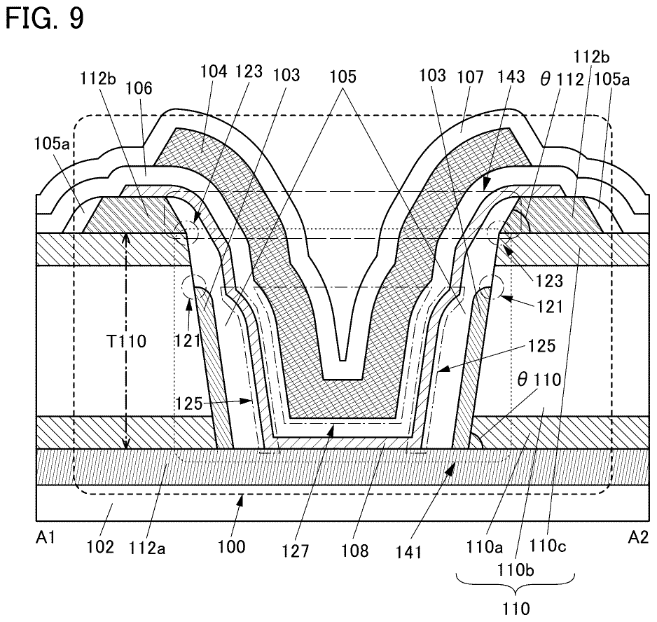

Although FIG. 3B, FIG. 4A, FIG. 4B, and FIG. 5 each illustrate an example in which the angle between the side surface of the conductive layer 112b that is positioned in the opening portion 143 and the formation surface of the conductive layer 112b (the top surface of the insulating layer 110) is equal to the angle θ110 between the side surface of the insulating layer 110 that is positioned in the opening portion 141 and the formation surface of the insulating layer 110 (the top surface of the conductive layer 112a), one embodiment of the present invention is not limited thereto. FIG. 9 is a cross-sectional view illustrating an example in which the above two angles of the transistor 100 illustrated in FIG. 3B are different from each other.

In FIG. 9, the angle between the side surface of the conductive layer 112b that is positioned in the opening portion 143 and the formation surface of the conductive layer 112b (the top surface of the insulating layer 110) is an angle θ112. The angle θ112 is preferably smaller than the angle θ110. This can reduce a step on the formation surface of the layer that is provided to cover at least part of the opening portion 143, such as the semiconductor layer 108. Thus, coverage with the layer can be improved. This can inhibit generation of a defect such as step disconnection or a void in the layer.

For example, by employing different methods for formation of the opening portion 141 and the opening portion 143, the angle θ110 and the angle θ112 can be made different from each other. For example, when a dry etching method is used for the formation of the opening portion 141 and a wet etching method is used for the formation of the opening portion 143, the angle θ112 can be made smaller than the angle θ110.

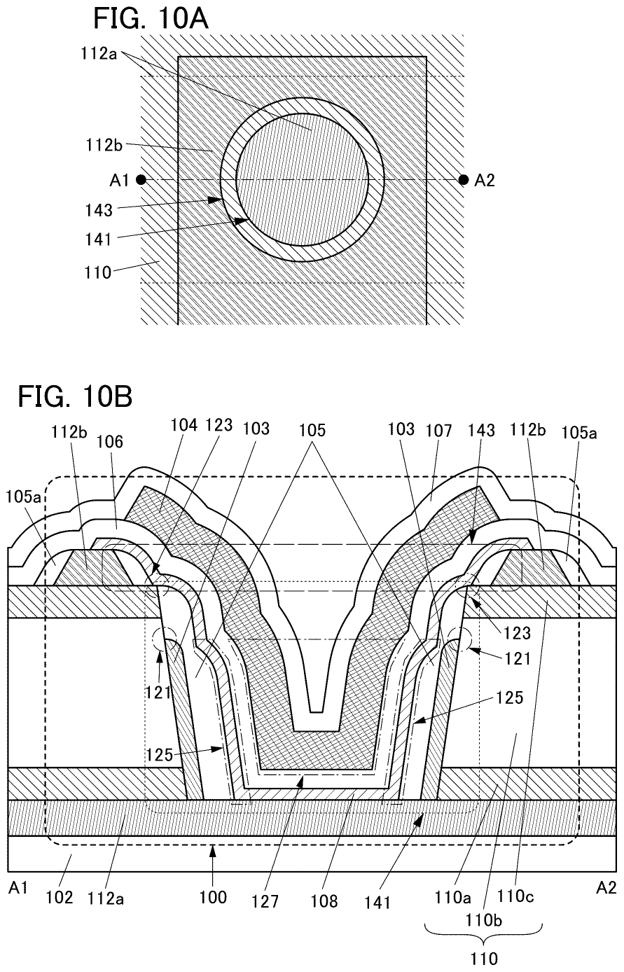

Although FIG. 3A illustrates an example in which the plan-view shape of the opening portion 141 and the plan-view shape of the opening portion 143 are the same, for example, they are not necessarily the same. FIG. 10A is a plan view illustrating an example in which the plan-view shape of the opening portion 141 and the plan-view shape of the opening portion 143 are not the same, and illustrates the conductive layer 112a, the insulating layer 110 including the opening portion 141, and the conductive layer 112b including the opening portion 143. FIG. 10B is a cross-sectional view in which the opening portion 143 illustrated in FIG. 3B corresponds to the plan view illustrated in FIG. 10A. FIG. 10B is a cross-sectional view taken along the dashed-dotted line A1-A2 in FIG. 10A. FIG. 10B illustrates an example in which the portion 123 that is the end portion of the top surface of the insulating layer 110 on the opening portion 141 side is not aligned with the end portion of the bottom surface of the conductive layer 112b on the opening portion 143 side.

FIG. 10A illustrates an example in which the opening portion 143 includes the opening portion 141 in the plan view. FIG. 10B illustrates an example in which the insulating layer 110 includes a region projecting from the conductive layer 112b into the opening portion 141 side in a cross-sectional view. In the example illustrated in FIG. 10B, the semiconductor layer 108 has a shape along the top surface of the conductive layer 112b, the insulating layer 105, and the top surface of the conductive layer 112a. Note that in the case where the plan-view shapes of the opening portion 141 and the opening portion 143 are circular shapes, the opening portion 141 and the opening portion 143 may be concentrically arranged, but not necessarily concentrically arranged.

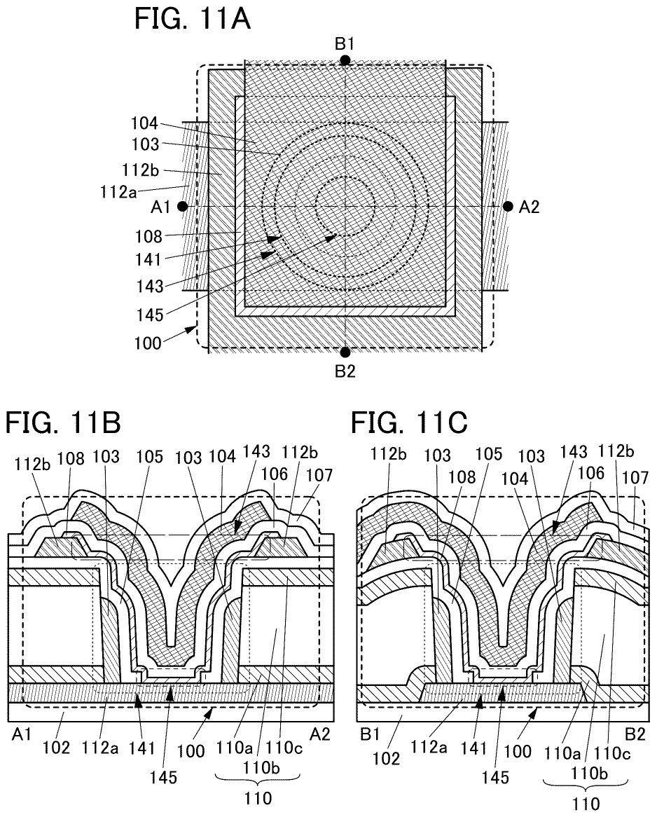

FIG. 11A, FIG. 11B, and FIG. 11C illustrate an example in which the insulating layer 105 illustrated in FIG. 1A, FIG. 1B, and FIG. 1C includes a region positioned over the insulating layer 110 and the conductive layer 112b is provided over the insulating layer 105. In the example illustrated in FIG. 11A, FIG. 11B, and FIG. 11C, an opening portion 145 reaching the conductive layer 112a is provided in the insulating layer 105. The opening portion 145 is provided in the opening portion 141. Note that the insulating layer 105 is not illustrated in FIG. 11A.

The opening portion 145 can be formed in the following manner: after the insulating layer 105 is formed, patterning is performed by photolithography, for example, and then the insulating layer 105 is processed using the pattern. The semiconductor layer 108 is formed after forming the opening portion 145, whereby the conductive layer 112a and the semiconductor layer 108 can be in contact with each other.

In the example illustrated in FIG. 11A, FIG. 11B, and FIG. 11C, etching treatment is performed on only part of the insulating layer 105. This can prevent the insulating layer 105 from having a region thinner than that of the other region even when the thickness of the insulating layer 105 is reduced. Thus, the insulating layer 105 can be thinned and a short circuit due to contact between the conductive layer 103 and the semiconductor layer 108 can be prevented. When the insulating layer 105 has a small thickness, the electric field of the conductive layer 103 functioning as the back gate electrode of the transistor 100 can be easily applied to the semiconductor layer 108.

Meanwhile, in the example illustrated in FIG. 1A, FIG. 1, and FIG. 1C, there is no need to use photolithography, for example, to expose the top surface of the conductive layer 112a. This eliminates the need to consider alignment accuracy of the mask, allowing the opening portion 141 to be miniaturized. Thus, the transistor 100 can have a minute size. Furthermore, even when the opening portion 141 is miniaturized, variation in electrical characteristics, e.g., variation in channel lengths, among the plurality of transistors 100 can be inhibited.

FIG. 11A illustrates an example in which the opening portion 143 includes the opening portion 141 in the plan view. FIG. 11B illustrates an example in which the insulating layer 110 includes a region projecting from the conductive layer 112b into the opening portion 141 side in a cross-sectional view. Note that in the case where the plan-view shapes of the opening portion 141 and the opening portion 143 are circular shapes, the opening portion 141 and the opening portion 143 may be concentrically arranged, but not necessarily concentrically arranged.

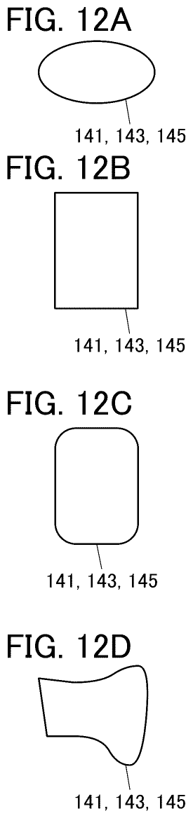

Although the plan-view shapes of the opening portion 141, the opening portion 143, and the opening portion 145 are circular shapes in this embodiment, the plan-view shapes of the opening portion 141, the opening portion 143, and the opening portion 145 are not limited to circular shapes. FIG. 12A, FIG. 12B, FIG. 12C, and FIG. 12D are plan views illustrating examples of the shapes of the opening portion 141, the opening portion 143, and the opening portion 145. The plan-view shapes of the opening portion 141, the opening portion 143, and the opening portion 145 may each be an elliptic shape as illustrated in FIG. 12A, a rectangular shape as illustrated in FIG. 12B, or a rectangular shape with rounded corners as illustrated in FIG. 12C. The plan-view shapes of the opening portion 141, the opening portion 143, and the opening portion 145 may each be a shape with one or both of a linear portion and a curved portion as illustrated in FIG. 12D. The plan-view shapes of the opening portion 141, the opening portion 143, and the opening portion 145 may each be parallelograms, rhombuses, or squares. The plan-view shapes of the opening portion 141, the opening portion 143, and the opening portion 145 may each be a triangle or a polygonal shape such as a pentagon or a star polygon. Note that the polygonal shape may be a concave polygonal shape (a polygonal shape at least one of the interior angles of which is greater than 180°) or a convex polygonal shape (a polygonal shape all the interior angles of which are less than or equal to 180°). Furthermore, the plan-view shapes of the opening portion 141, the opening portion 143, and the opening portion 145 may each be any of above-described shapes with rounded corners.

### <Components of Semiconductor Device>

Components of the semiconductor device of one embodiment of the present invention will be described below. For example, materials that can be used for the components will be described.

### [Semiconductor Layer 108]

The semiconductor layer 108 includes a metal oxide exhibiting semiconductor characteristics (also referred to as an oxide semiconductor).

There is no particular limitation on the crystallinity of the semiconductor material used for the semiconductor layer 108, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The band gap of a metal oxide used for the semiconductor layer 108 is preferably greater than or equal to 2.0 eV, further preferably greater than or equal to 2.5 eV.

Examples of the metal oxide that can be used for the semiconductor layer 108 include indium oxide, gallium oxide, and zinc oxide. The metal oxide preferably contains at least indium or zinc. The metal oxide preferably contains two or three selected from indium, an element M, and zinc. The element Mis a metal element or a metalloid element that has a high binding energy with oxygen, such as a metal element or a metalloid element whose binding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably any one or more of the above elements, further preferably one or more selected from aluminum, gallium, tin, and yttrium, further preferably gallium. In this specification and the like, a metal element and a metalloid element may be collectively referred to as a “metal element”, and a “metal element” described in this specification and the like may encompass a metalloid element.

For example, the semiconductor layer 108 can be formed using indium zinc oxide (also referred to as In—Zn oxide or IZO (registered trademark)), indium tin oxide (In—Sn oxide), indium titanium oxide (In—Ti oxide), indium gallium oxide (In—Ga oxide), indium gallium aluminum oxide (In—Ga—Al oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), indium tin gallium oxide (also referred to as In—Sn—Ga oxide or IGTO), or indium gallium aluminum zinc oxide (also referred to as In—Ga—Al—Zn oxide, IGAZO, IGZAO, or IAGZO). Alternatively, indium tin oxide containing silicon, gallium tin oxide (Ga—Sn oxide), aluminum tin oxide (Al—Sn oxide), or the like can be used. Alternatively, the above-described oxide having an amorphous structure can be used. For example, indium oxide having an amorphous structure, indium tin oxide having an amorphous structure, or the like can be used.

By increasing the proportion of the number of indium atoms in the total number of atoms of all the metal elements included in the metal oxide, the field-effect mobility of the transistor can be increased. In addition, the transistor can have a high on-state current.

Note that the metal oxide may contain, instead of or in addition to indium, one or more metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Thus, a change in electrical characteristics of the transistor can be inhibited and the reliability of the transistor can be improved.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited and the reliability of the transistor can be improved.

The composition of the metal oxide used for the semiconductor layer 108 affects the electrical characteristics and reliability of the transistor. Therefore, by determining the composition of the metal oxide in accordance with the electrical characteristics and reliability required for the transistor, the semiconductor device can have both excellent electrical characteristics and high reliability.

When the metal oxide is an In-M-Zn oxide, the proportion of the number of In atoms is preferably higher than or equal to that of the number of M atoms in the In-M-Zn oxide. Examples of the atomic ratio of the metal elements of such an In-M-Zn oxide include In:M:Zn=1:1:1, In:M:Zn=1:1:1.2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood of any of these atomic ratios. Note that a composition in the neighborhood includes the range of ±30% of an intended atomic ratio. By increasing the proportion of the number of indium atoms in the metal oxide, the on-state current, field-effect mobility, or the like of the transistor can be improved.

The proportion of the number of In atoms may be less than that of the number of M atoms in the In-M-Zn oxide. Examples of the atomic ratio of the metal elements in such an In-M-Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies can be suppressed.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

An atomic layer deposition (ALD) method or a sputtering method can be suitably used to form the metal oxide. Here, an ALD method is a film formation method in which a film is formed by a reaction at a surface of an object. Thus, the semiconductor layer 108 including a metal oxide is preferably formed by an ALD method, in which case damage to the semiconductor layer 108 can be reduced. Note that in the case where the metal oxide is formed by a sputtering method, the composition of the formed metal oxide may be different from the composition of a target. In particular, the zinc content percentage of the formed metal oxide may be reduced to approximately 50% of that of the target.

The semiconductor layer 108 may have a stacked-layer structure of two or more metal oxide layers. The two or more metal oxide layers included in the semiconductor layer 108 may have the same composition or substantially the same compositions.

The two or more metal oxide layers included in the semiconductor layer 108 may have different compositions. For example, a stacked-layer structure of a first metal oxide layer having a composition of In:M:Zn=1:3:4 [atomic ratio] or in the neighborhood thereof and a second metal oxide layer having a composition of In:M:Zn=1:1:1 [atomic ratio] or in the neighborhood thereof and being provided over the first metal oxide layer can be suitably employed. In addition, it is particularly preferable to use gallium, aluminum, or tin as the element M. For another example, a stacked-layer structure of any one selected from indium oxide, indium gallium oxide, and IGZO, and any one selected from IAZO, IAGZO, and ITZO (registered trademark) may be employed.

It is preferable that the semiconductor layer 108 include a metal oxide layer having crystallinity. Examples of the structure of a metal oxide having crystallinity include a CAAC (c-axis aligned crystal) structure, a polycrystalline structure, and a nano-crystal (nc) structure. By using a metal oxide layer having crystallinity as the semiconductor layer 108, the density of defect states in the semiconductor layer 108 can be reduced, which enables the semiconductor device to have high reliability.

The higher the crystallinity of the metal oxide layer used as the semiconductor layer 108 is, the lower the density of defect states in the semiconductor layer 108 can be. By contrast, the use of a metal oxide layer having low crystallinity makes it possible that a high current flows in the transistor.

The semiconductor layer 108 may have a stacked-layer structure of two or more metal oxide layers having different crystallinities. For example, a stacked-layer structure of the first metal oxide layer and the second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

The thickness of the semiconductor layer 108 is preferably greater than or equal to 3 nm and less than or equal to 200 nm, further preferably greater than or equal to 3 nm and less than or equal to 100 nm, further preferably greater than or equal to 5 nm and less than or equal to 100 nm, further preferably greater than or equal to 10 nm and less than or equal to 100 nm, further preferably greater than or equal to 10 nm and less than or equal to 70 nm, further preferably greater than or equal to 15 nm and less than or equal to 70 nm, further preferably greater than or equal to 15 nm and less than or equal to 50 nm, further preferably greater than or equal to 20 nm and less than or equal to 50 nm.

In the case where the semiconductor layer 108 is formed using an oxide semiconductor, hydrogen contained in the oxide semiconductor reacts with oxygen bonded to a metal atom to be water, and thus sometimes forms an oxygen vacancy (Vo) in the oxide semiconductor. In some cases, a defect that is an oxygen vacancy into which hydrogen enters (VoH) functions as a donor and generates an electron serving as a carrier. In other cases, bonding of part of hydrogen to oxygen bonded to a metal atom generates electrons serving as carriers. Thus, a transistor including an oxide semiconductor that contains a large amount of hydrogen is likely to have normally-on characteristics (i.e., a negative threshold voltage value). Moreover, hydrogen in an oxide semiconductor is easily transferred by a stress such as heat or an electric field; thus, a large amount of hydrogen in an oxide semiconductor might reduce the reliability of a transistor.

When an oxide semiconductor is used for the semiconductor layer 108, the carrier concentration of the oxide semiconductor in the region functioning as the channel formation region is preferably lower than or equal to 1×10¹⁸ cm⁻³, further preferably lower than 1×10¹⁷ cm⁻³, further preferably lower than 1×10¹⁶ cm⁻³, further preferably lower than 1×10¹³ cm⁻³, further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be held for a long period. Furthermore, the semiconductor device can have lower power consumption by including the OS transistor.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a neutron beam, and a proton beam).

Other examples of the semiconductor material that can be used for the semiconductor layer 108 include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. These semiconductor materials may contain an impurity as a dopant.

Examples of silicon that can be used for the semiconductor layer 108 include single crystal silicon, polycrystalline silicon, microcrystalline silicon, and amorphous silicon. An example of polycrystalline silicon is low-temperature polysilicon (LTPS).

The transistor including amorphous silicon in the semiconductor layer 108 can be formed over a large-sized glass substrate, thereby reducing the manufacturing cost. The transistor including polycrystalline silicon in the semiconductor layer 108 has high field-effect mobility and can operate at high speed. The transistor including microcrystalline silicon in the semiconductor layer 108 has higher field-effect mobility and can operate at higher speed than the transistor including amorphous silicon.

The semiconductor layer 108 may include a layered substance functioning as a semiconductor. The layered substance generally refers to a group of materials having a layered crystal structure. The layered crystal structure is a structure in which layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layer 110]

The insulating layer 110 is preferably formed using an inorganic insulating film. Examples of the inorganic insulating film include an oxide insulating film and a nitride insulating film. Examples of the oxide insulating film include a silicon oxide film, a silicon oxynitride film, an aluminum oxide film, an aluminum oxynitride film, a magnesium oxide film, a gallium oxide film, a gallium oxynitride film, a germanium oxide film, an yttrium oxide film, an yttrium oxynitride film, a zirconium oxide film, a lanthanum oxide film, a neodymium oxide film, a hafnium oxide film, a hafnium oxynitride film, a tantalum oxide film, a cerium oxide film, a gallium zinc oxide film, and a hafnium aluminate film. Examples of the nitride insulating film include a silicon nitride film, a silicon nitride oxide film, an aluminum nitride film, and an aluminum nitride oxide film.

Each of the insulating layer 110a and the insulating layer 110c can be formed using a material that does not easily allow diffusion of hydrogen. In that case, hydrogen can be inhibited from being diffused from outside the transistor to the semiconductor layer 108 through the insulating layer 110a or the insulating layer 110c. It is thus possible to inhibit a reduction in the channel length of the transistor 100 and a reduction in the threshold voltage of the transistor 100, that is, a negative shift of the threshold voltage. This can reduce a cutoff current, so that the transistor can have normally-off characteristics. Thus, the reliability of the transistor 100 can be increased, and the reliability of the semiconductor device of one embodiment of the present invention can be increased.

The insulating layer 110c can include a material that is the same as the material included in the insulating layer 110a. For example, the insulating layer 110c can be formed using the same material as the insulating layer 110a. In that case, the insulating layer 110a and the insulating layer 110c can be formed under the same conditions. Note that when the film formation time of the insulating layer 110a and the film formation time of the insulating layer 110c are made different from each other, for example, the thickness of the insulating layer 110a and the thickness of the insulating layer 110c can be made different from each other.

For calculation of the diffusion coefficient, thermal desorption spectroscopy (TDS) can be used, for example. Alternatively, secondary ion mass spectrometry (SIMS) may be used.

It is preferable that the insulating layer 110a and the insulating layer 110c be each formed using any one or more of the oxide insulating films and nitride insulating films described above. Specifically, it is preferable to use any one or more of a silicon nitride film, a silicon nitride oxide film, a silicon oxynitride film, an aluminum oxide film, an aluminum oxynitride film, an aluminum nitride film, a hafnium oxide film, and a hafnium aluminate film.

It is preferable that the insulating layer 110a and the insulating layer 110c be each formed using any one or more of the nitride insulating films described above. Specifically, it is preferable that the insulating layer 110a and the insulating layer 110c be each formed using one or both of a silicon nitride film and a silicon nitride oxide film.

A silicon nitride film and a silicon nitride oxide film release fewer impurities (e.g., water and hydrogen), are less likely to transmit hydrogen, and thus can be suitably used for each of the insulating layer 110a and the insulating layer 110c.

The insulating layer 110a and the insulating layer 110c may be formed using any of the above-described aluminum-containing films, for example. The insulating layer 110a and the insulating layer 110c are each preferably formed using, for example, an aluminum oxide film.

The insulating layer 110a and the insulating layer 110c may contain hydrogen. When hydrogen is contained in the insulating layer 110a, a region of the semiconductor layer 108 in the vicinity of the conductive layer 112a can be supplied with hydrogen to have reduced resistance, for example, the region can be an n-type region. When hydrogen is contained in the insulating layer 110c, a region of the semiconductor layer 108 in the vicinity of the conductive layer 112b can be supplied with hydrogen to have reduced resistance. Thus, the transistor having low on-state resistance can be formed.

The thickness of the insulating layer 110a can be, for example, greater than or equal to 3 nm, greater than or equal to 5 nm, greater than or equal to 10 nm, greater than or equal to 20 nm, greater than or equal to 50 nm, or greater than or equal to 70 nm and can be less than 1 μm, less than or equal to 500 nm, less than or equal to 400 nm, less than or equal to 300 nm, less than or equal to 200 nm, less than or equal to 150 nm, or less than or equal to 120 nm. The thickness of the insulating layer 110a can be the shortest distance between the formation surface of the insulating layer 110a (which is the top surface of the conductive layer 112a here) and the top surface of the insulating layer 110a in a cross-sectional view.

The thickness of the insulating layer 110c can be, for example, greater than or equal to 3 nm, greater than or equal to 5 nm, greater than or equal to 10 nm, greater than or equal to 15 nm, or greater than or equal to 20 nm and can be less than or equal to 1 μm, less than or equal to 500 nm, less than or equal to 300 nm, less than or equal to 200 nm, less than or equal to 150 nm, less than or equal to 120 nm, or less than or equal to 100 nm. The thickness of the insulating layer 110c can be the shortest distance between the formation surface of the insulating layer 110c (which is the top surface of the insulating layer 110b here) and the top surface of the insulating layer 110c in a cross-sectional view.

The insulating layer 110b preferably has an extremely low hydrogen content. This can inhibit supply of hydrogen to the channel formation region of the semiconductor layer 108. Consequently, the transistor 100 can be manufactured to have favorable electrical characteristics and high reliability. As described above, when the insulating layer 110a and the insulating layer 110c contain hydrogen and the hydrogen content of the insulating layer 110b is extremely low, supply of hydrogen to the channel formation region can be inhibited while the resistance of the source region and the drain region of the transistor 100 is reduced.

The insulating layer 110b can be an insulating layer containing oxygen. In that case, any one or more of oxide and oxynitride described above can be used for the insulating layer 110b. For example, one or both of silicon oxide and silicon oxynitride can be suitably used. An insulating layer containing nitrogen may be used as the insulating layer 110b. For the insulating layer 110b, materials similar to the above-described materials that can be used for the insulating layer 110a and the insulating layer 110c can be used, for example.

In the case where an insulating layer containing oxygen is used as the insulating layer 110b, a film from which oxygen is released by heating is preferably used as the insulating layer 110b. When the insulating layer 110b releases oxygen by being heated in the manufacturing process of a display device 10, the oxygen can be supplied to the semiconductor layer 108. Supplying oxygen from the insulating layer 110b to the channel formation region of the semiconductor layer 108 can repair oxygen vacancies (Vo), whereby the amount of oxygen vacancies (Vo) can be reduced. Consequently, the transistor can be manufactured to have favorable electrical characteristics and high reliability.

A substance is preferably easily diffused in the insulating layer 110b. In other words, the diffusion coefficient of a substance in the insulating layer 110b is preferably high. For example, in the case where an insulating layer containing oxygen is used as the insulating layer 110b, oxygen is preferably easily diffused in the insulating layer 110b. That is, the diffusion coefficient of oxygen in the insulating layer 110b is preferably high. Oxygen contained in the insulating layer 110b is diffused in the insulating layer 110b and is supplied to the semiconductor layer 108 through the insulating layer 105. The insulating layer 110b in which oxygen is easily diffused contributes to the efficient supply of oxygen contained in the insulating layer 110b to the channel formation region of the semiconductor layer 108.

The diffusion coefficient of oxygen in the insulating layer 110b at 350° C. is preferably higher than or equal to 5×10⁻¹² cm²/sec, further preferably higher than or equal to 1×10⁻¹¹ cm²/sec, further preferably higher than or equal to 5×10⁻¹¹ cm²/sec, further preferably higher than or equal to 1×10⁻¹⁰ cm²/sec. Accordingly, oxygen contained in the insulating layer 110b can be efficiently supplied to the semiconductor layer 108. Since the diffusion coefficient is preferably as high as possible, the upper limit thereof is not set. Note that the oxygen diffusion coefficient of the insulating layer 110b is not limited to the above range.

The thickness of the insulating layer 110b can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm.

### [Conductive Layer 112a, Conductive Layer 112b, Conductive Layer 103, and Conductive Layer 104]

For the conductive layer 112a, the conductive layer 112b, the conductive layer 103, and the conductive layer 104, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like, or an alloy containing any of these metal elements as its component, for example. A nitride or an oxide of any of the above metals or the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having low electrical resistivity, typified by polycrystalline silicon containing an impurity element such as phosphorus, or silicide such as nickel silicide may be used.

For the conductive layer 112a, the conductive layer 112b, the conductive layer 103, and the conductive layer 104, for example, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are less likely to be oxidized or conductive materials that maintain the conductivity even when oxidized.

It is also possible to use a conductive oxide such as indium oxide, zinc oxide, In—Sn oxide, In—Zn oxide, In—W oxide, In—W—Zn oxide, In—Ti oxide, In—Ti—Sn oxide, In—Sn oxide, In—Sn—Si oxide, or Ga—Zn oxide for the conductive layer 112a, the conductive layer 112b, the conductive layer 103, and the conductive layer 104. A conductive oxide containing indium is particularly preferable because of its high conductivity.

Each of the conductive layer 112a and the conductive layer 112b includes a region in contact with the semiconductor layer 108. When the semiconductor layer 108 is a metal oxide layer and the conductive layer 112a or the conductive layer 112b is formed using a metal that is likely to be oxidized, an insulating oxide is formed between the conductive layer 112a or the conductive layer 112b and the semiconductor layer 108, which might inhibit continuity between the conductive layer 112a or the conductive layer 112b and the semiconductor layer 108. Therefore, the conductive layer 112a and the conductive layer 112b are preferably formed using a conductive material that is less likely to be oxidized, a conductive material that maintains the conductivity even when oxidized, or an oxide conductive material.

As each of the conductive layer 112a, the conductive layer 112b, the conductive layer 103, and the conductive layer 104, a stack of a plurality of layers including the above conductive material may be used. Here, in the case where the semiconductor layer 108 is a metal oxide layer, oxygen is sometimes supplied from the semiconductor layer 108 to the conductive layer 112a and the conductive layer 112b, each of which includes a region in contact with the semiconductor layer 108. Thus, a conductive material that is less likely to be oxidized, a conductive material that maintains the conductivity even when oxidized, or an oxide conductive material is preferably used for a layer including a region in contact with the semiconductor layer 108, e.g., a layer having the largest contact area with the semiconductor layer 108.

Note that the conductive layer 112a, the conductive layer 112b, the conductive layer 103, and the conductive layer 104 may be formed using the same material or at least one of the conductive layer 112a, the conductive layer 112b, the conductive layer 103, and the conductive layer 104 may be formed using a material different from the material used for the other layer(s).

### [Insulating Layer 106]

The insulating layer 106 may have a single-layer structure or a stacked-layer structure of two or more layers. The insulating layer 106 preferably includes one or more inorganic insulating films. Examples of the inorganic insulating film include an oxide insulating film and a nitride insulating film. Specific examples of these inorganic insulating films are as described above.

The insulating layer 106 includes a portion that is in contact with the semiconductor layer 108. In the case where the semiconductor layer 108 is formed using an oxide semiconductor, at least the film of the insulating layer 106 that is in contact with the semiconductor layer 108 is preferably any of the above-described oxide insulating films.

Specifically, in the case where the insulating layer 106 has a single-layer structure, the insulating layer 106 is preferably formed using a silicon oxide film or a silicon oxynitride film.

The insulating layer 106 can have a stacked-layer structure of an oxide insulating film on the side that is in contact with the semiconductor layer 108 and a nitride insulating film on the side that is in contact with the conductive layer 104. As the oxide insulating film, for example, a silicon oxide film or a silicon oxynitride film is preferably used. As the nitride insulating film, a silicon nitride film or a silicon nitride oxide film is preferably used.

A silicon nitride film and a silicon nitride oxide film can be suitably used for the insulating layer 106 because they release fewer impurities (e.g., water and hydrogen) and are less likely to transmit hydrogen. Inhibiting diffusion of impurities from the insulating layer 106 to the semiconductor layer 108 results in favorable electrical characteristics and high reliability of the transistor.

A miniaturized transistor including a thin gate insulating layer may have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

### [Substrate 102]

There is no particular limitation on the properties of the material of the substrate 102 as long as the material has heat resistance high enough to withstand at least heat treatment to be performed later. For example, a glass substrate; a quartz substrate; a sapphire substrate; a ceramic substrate; an organic resin substrate; a single crystal semiconductor substrate or a polycrystalline semiconductor substrate including silicon or silicon carbide as a material; a compound semiconductor substrate of silicon germanium or the like; or an SOI (Silicon On Insulator) substrate can be used as the substrate 102. The substrate 102 may be provided with a semiconductor element. Furthermore, a polarizing plate may be used as the substrate 102. Note that the shape of the semiconductor substrate and an insulating substrate may be a circular shape or a shape with corners.

A flexible substrate may be used as the substrate 102, and the transistor 100 may be formed directly on the flexible substrate, for example. Alternatively, a separation layer may be provided between the substrate 102 and the transistor 100 and the like. The separation layer can be used for separation of part or the whole of a semiconductor device completed thereover from the substrate 102 and transferring the part or the whole of the semiconductor device onto another substrate. In that case, for example, the transistor 100 can be transferred onto a substrate having low heat resistance or a flexible substrate as well.

For the substrate 102, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 102.

### <Structure Example of Display Device>

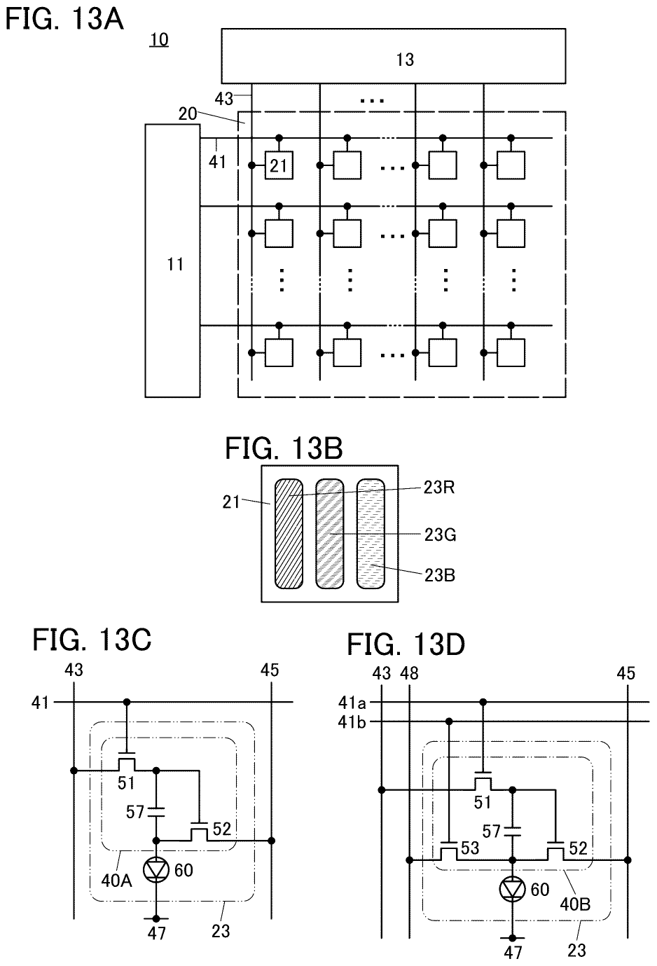

A structure example of a display device in which the transistor 100 can be used is described below. FIG. 13A is a block diagram illustrating a structure example of the display device 10 that is the display device of one embodiment of the present invention. The display device 10 includes a display portion 20, a scan line driver circuit 11, and a signal line driver circuit 13. The display portion 20 includes a plurality of pixels 21 arranged in a matrix.

The scan line driver circuit 11 is electrically connected to the pixels 21 through a wiring 41. The wiring 41 extends in the row direction of the matrix, for example.

The signal line driver circuit 13 is electrically connected to the pixels 21 through a wiring 43. The wiring 43 extends in the column direction of the matrix, for example.

The pixel 21 includes a display element, and an image can be displayed on the display portion 20 with the display element. As the display element, a light-emitting element can be used, for example; specifically, an organic EL element can be used. As the display element, a liquid crystal element (also referred to as a liquid crystal device) may also be used.

The scan line driver circuit 11 has a function of selecting, row by row, the pixel 21 to which image data is to be written, for example. Specifically, the scan line driver circuit 11 can select the pixel 21 to which image data is to be written by outputting a signal to the wiring 41. Here, the scan line driver circuit 11 can select all the pixels 21 by, for example, outputting the signal to the wiring 41 in the first row, outputting the signal to the wiring 41 in the second row, and then outputting the signals to the wirings 41 from the third row to the last row sequentially. Thus, the signal output from the scan line driver circuit 11 to the wiring 41 is a scan signal, and the wiring 41 can be referred to as a scan line.

The signal line driver circuit 13 has a function of generating image data. The image data is supplied to the pixel 21 through the wiring 43. For example, image data can be written to all the pixels 21 included in a row selected by the scan line driver circuit 11. Here, the image data can be represented as a signal (image signal). Thus, the wiring 43 can be referred to as a signal line.

FIG. 13B is a plan view illustrating a structure example of the pixel 21. The pixel 21 includes a plurality of subpixels 23. FIG. 13B illustrates an example in which the pixel 21 includes a subpixel 23R, a subpixel 23G, and a subpixel 23B. Here, in the case where the pixel 21 includes a light-emitting element as a display element, for example, the plan-view shape of the subpixel illustrated in FIG. 13B corresponds to the plan-view shape of a light-emitting region of the light-emitting element. Although FIG. 13B illustrates the subpixel 23R, the subpixel 23G, and the subpixel 23B that have the same or substantially the same aperture ratio (also referred to as size or size of a light-emitting region), one embodiment of the present invention is not limited thereto. The aperture ratio of each of the subpixel 23R, the subpixel 23G, and the subpixel 23B can be determined as appropriate. The subpixel 23R, the subpixel 23G, and the subpixel 23B may have different aperture ratios, or two or more of the subpixels may have the same or substantially the same aperture ratio.

In this specification and the like, for example, description common to the subpixel 23R, the subpixel 23G, and the subpixel 23B is sometimes made using the collective term “subpixel 23” without letters of the alphabet distinguishing them from each other. As for other components that are distinguished from each other using letters of the alphabet, matters common to the components are sometimes described using reference numerals without the letters of the alphabet.

The pixel 21 illustrated in FIG. 13B employs stripe arrangement as the arrangement method of the subpixels 23. Note that S-stripe arrangement, matrix arrangement, delta arrangement, Bayer arrangement, PenTile arrangement, or the like may be employed as the arrangement method of the subpixels 23. Embodiment 2 can be referred to for an example of the plan-view shape of the subpixel, arrangement of the subpixels, and the like.

The subpixel 23R, the subpixel 23G, and the subpixel 23B emit light of different colors. The subpixel 23R, the subpixel 23G, and the subpixel 23B are subpixels of three colors of red (R), green (G), and blue (B) or subpixels of three colors of yellow (Y), cyan (C), and magenta (M), for example. The pixel 21 may include four or more of the subpixels 23. For example, the pixel 21 may include subpixels of four colors of R, G, B, and white (W). In the display device 10, the display portion 20 can display a full-color image by including, in the pixel 21, the plurality of subpixels 23 emitting light of different colors. Note that the pixel 21 may include subpixels of R, G, B, and infrared light (IR).

Note that a sensor may be provided in the display portion 20, for example, in the pixel 21. For example, the display portion 20 may have a function of a fingerprint sensor. For example, the display portion 20 may have a function of an optical or ultrasonic fingerprint sensor.

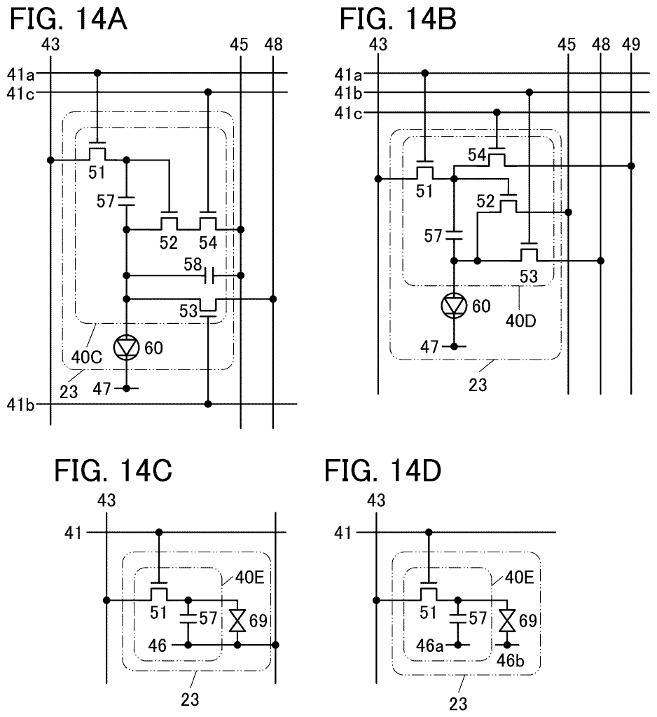

FIG. 13C, FIG. 13D, FIG. 14A, FIG. 14B, FIG. 14C, and FIG. 14D are circuit diagrams illustrating structure examples of the subpixel 23. The subpixel 23 illustrated in FIG. 13C includes a pixel circuit 40A and a light-emitting element 60.

The pixel circuit 40A includes a transistor 51, a transistor 52, and a capacitor 57. That is, the pixel circuit 40A is a 2Tr1C-type pixel circuit.

In the pixel circuit 40A, one of the source and the drain of the transistor 51 is electrically connected to the wiring 43. The other of the source and the drain of the transistor 51 is electrically connected to the gate of the transistor 52. The gate of the transistor 52 is electrically connected to one electrode of the capacitor 57. The gate of the transistor 51 is electrically connected to the wiring 41.

One of the source and the drain of the transistor 52 is electrically connected to a wiring 45. The other of the source and the drain of the transistor 52 is electrically connected to the other electrode of the capacitor 57. The other electrode of the capacitor 57 is electrically connected to one electrode of the light-emitting element 60. The other electrode of the light-emitting element 60 is electrically connected to a wiring 47. Here, the one electrode of the light-emitting element 60 is also referred to as a pixel electrode. The wiring 47 can be shared between all the subpixels 23, for example; thus, the other electrode of the light-emitting element 60 can also be referred to as a common electrode.

As described above, the wiring 41 functions as a scan line, and the wiring 43 functions as a signal line. The wiring 45 and the wiring 47 each function as a power supply line. For example, in the case where a high power supply potential is applied to the wiring 45, a low power supply potential is applied to the wiring 47.

The transistor 51 has a function of a switch and is also referred to as a selection transistor. The transistor 51 has a function of controlling the conducting state and the non-conducting state between the wiring 43 and the gate of the transistor 52 on the basis of the potential of the wiring 41. When the transistor 51 is brought into an on state, image data is written to the pixel circuit 40A, and when the transistor 51 is brought into an off state, the written image data is retained.

The transistor 52 has a function of controlling the amount of current flowing through the light-emitting element 60 and is also referred to as a driving transistor. The capacitor 57 has a function of retaining a gate potential of the transistor 52. The emission luminance of the light-emitting element 60 is controlled in accordance with a potential that corresponds to image data and is supplied to the gate of the transistor 52. Specifically, in the case where the wiring 45 is supplied with a high power supply potential and the wiring 47 is supplied with a low power supply potential, the amount of current flowing from the wiring 45 to the wiring 47 is controlled in accordance with the gate potential of the transistor 52, whereby the emission luminance of the light-emitting element 60 is controlled.

An OS transistor is preferably used as each of the transistor 51 and the transistor 52. An OS transistor has higher field-effect mobility than a transistor using amorphous silicon, for example. Thus, by using an OS transistor as each of the transistor 51 and the transistor 52, the display device 10 can be driven at high speed.

An OS transistor has an extremely low leakage current between a source and a drain in an off state (hereinafter, also referred to as an off-state current). Thus, by using an OS transistor as the transistor 51, charge accumulated in the capacitor 57 can be retained for a long period. Therefore, image data written to the subpixel 23 can be retained for a long period and therefore the frequency of the refresh operation (rewriting image data to the subpixel 23) can be reduced. Thus, power consumption of the display device 10 can be reduced.

To increase the emission luminance of the light-emitting element 60, it is necessary to increase the amount of current flowing through the light-emitting element 60. To increase the current amount, it is necessary to increase the source-drain voltage of the transistor 52 which is a driving transistor. Since an OS transistor has a higher withstand voltage between a source and a drain than a transistor using silicon (also referred to as a Si transistor), a high voltage can be applied between the source and the drain of the OS transistor. Accordingly, when an OS transistor is used as the transistor 52, the amount of current flowing through the light-emitting element 60 can be increased, so that the emission luminance of the light-emitting element 60 can be increased.

In the case where transistors are driven in a saturation region, a change in source-drain current relative to a change in gate-source voltage can be smaller in an OS transistor than in a Si transistor. Thus, when an OS transistor is used as the transistor 52, current flowing between the source and the drain can be set minutely by a change in gate-source voltage. This allows the amount of current flowing through the light-emitting element 60 can be controlled minutely. Accordingly, the luminance of light emitted from the subpixel 23 can be controlled minutely. As a result, the number of gray levels represented by the subpixel 23 can be increased.

Regarding saturation characteristics of current flowing when transistors are driven in a saturation region, even in the case where source-drain voltage of an OS transistor increases gradually, more stable current (saturation current) can be made to flow through an OS transistor than through a Si transistor. Thus, by using an OS transistor as the transistor 52, a stable current can flow through the light-emitting elements 60 even when the current-voltage characteristics vary among the light-emitting elements 60, for example. In other words, when an OS transistor is driven in a saturation region, source-drain current hardly changes with an increase in source-drain voltage; hence, the emission luminance of the light-emitting element 60 can be stable.

As described above, by using an OS transistor as the transistor 52, it is possible to “inhibit black-level degradation”, “increase the emission luminance”, “increase the number of gray levels”, and “inhibit a variation in the emission luminance among the light-emitting elements 60”, for example.

Although the transistor 51 and the transistor 52 are n-channel transistors in FIG. 13C, one or both of the transistor 51 and the transistor 52 may be p-channel transistors. The same applies to other transistors described in this specification and the like.

Examples of the light-emitting element 60 are self-luminous type light-emitting elements such as an LED, an OLED (Organic LED), and a semiconductor laser. Examples of the LED are a mini LED, a micro LED, and the like.

Examples of a light-emitting substance included in the light-emitting element 60 include a substance that emits fluorescent light (a fluorescent material), a substance that emits phosphorescent light (a phosphorescent material), a substance that exhibits thermally activated delayed fluorescence (a thermally activated delayed fluorescence (TADF) material), and an inorganic compound (e.g., a quantum dot material).

The light-emitting element 60 can emit infrared, red, green, blue, cyan, magenta, yellow, or white light, for example. When the light-emitting element has a microcavity structure, higher color purity can be achieved.

One of the pair of electrodes of the light-emitting element 60 functions as an anode, and the other electrode functions as a cathode.

The display device of one embodiment of the present invention can have any of the following structures: a top-emission structure in which light is emitted in a direction opposite to the substrate where the light-emitting element is formed, a bottom-emission structure in which light is emitted toward the substrate where the light-emitting element is formed, and a dual-emission structure in which light is emitted toward both surfaces.

The subpixel 23 illustrated in FIG. 13D includes a pixel circuit 40B and the light-emitting element 60. The pixel circuit 40B has a structure in which a transistor 53 is added to the pixel circuit 40A. The pixel circuit 40B is a 3Tr1C-type pixel circuit.

In the pixel circuit 40B, the gate of the transistor 51 is electrically connected to a wiring 41a. One of the source and the drain of the transistor 53 is electrically connected to the other of the source and the drain of the transistor 52, the other electrode of the capacitor 57, and one electrode of the light-emitting element 60. The other of the source and the drain of the transistor 53 is electrically connected to a wiring 48. The gate of the transistor 53 is electrically connected to a wiring 41b.

The transistor 53 has a function of a switch and has a function of controlling the conducting state and the non-conducting state between the wiring 48 and the one electrode of the light-emitting element 60 on the basis of the potential of the wiring 41b. A reference potential is applied to the wiring 48, for example. A variation in the gate-source potential among the transistors 52 can be inhibited by the reference potential of the wiring 48 supplied through the transistor 53.

A current value that can be used for setting pixel parameters can be obtained on the basis of the current value of the wiring 48. Specifically, the wiring 48 can function as a monitor line for outputting current flowing through the transistor 52 or current flowing through the light-emitting element 60 to the outside of the pixel 21. Current output to the wiring 48 can be converted into a potential by a source follower circuit, for example. Alternatively, the current can be converted into a digital signal by an A/D converter, for example.

As the transistor 53, an OS transistor is preferably used. As described above, an OS transistor has higher field-effect mobility than a transistor including amorphous silicon, for example. Consequently, by using an OS transistor as the transistor 53, the display device 10 can be driven at high speed.

The subpixel 23 illustrated in FIG. 14A includes a pixel circuit 40C and the light-emitting element 60. The pixel circuit 40C has a structure in which a transistor 54 and a capacitor 58 are added to the pixel circuit 40B. The pixel circuit 40C is a 4Tr2C-type pixel circuit.

In the pixel circuit 40C, one of the source and the drain of the transistor 52 is electrically connected to one of the source and the drain of the transistor 54. The other of the source and the drain of the transistor 54 is electrically connected to the wiring 45. The gate of the transistor 54 is electrically connected to a wiring 41c. One electrode of the capacitor 58 is electrically connected to the other of the source and the drain of the transistor 52, the one of the source and the drain of the transistor 53, the other electrode of the capacitor 57, and one electrode of the light-emitting element 60.

The wiring 41c is electrically connected to the scan line driver circuit 11. In other words, in the case where the subpixel 23 included in the pixel 21 has the structure illustrated in FIG. 14A, the wiring 41a, the wiring 41b, and the wiring 41c are provided as the wiring 41 in the display device 10.

The transistor 54 has a function of a switch and has a function of controlling the conducting state and the non-conducting state between the wiring 45 and the one of the source and the drain of the transistor 52 on the basis of the potential of the wiring 41c.

When the transistor 54 is turned on, current having a level corresponding to the gate potential of the transistor 52 flows from the wiring 45 to the wiring 47, for example. Thus, the light-emitting element 60 emits light with luminance corresponding to the gate potential of the transistor 52. Meanwhile, when the transistor 54 is turned off, current can be made not to flow through the light-emitting element 60; thus, the light-emitting element 60 can be made not to emit light.

As the transistor 54, an OS transistor is preferably used. As described above, an OS transistor has higher field-effect mobility than a transistor including amorphous silicon, for example. Consequently, by using an OS transistor as the transistor 54, the display device 10 can be driven at high speed.

The subpixel 23 illustrated in FIG. 14B includes a pixel circuit 40D and the light-emitting element 60. The pixel circuit 40D has a structure in which the transistor 54 is added to the pixel circuit 40B. The pixel circuit 40D is a 4Tr1C-type pixel circuit.

In the pixel circuit 40D, one of the source and the drain of the transistor 54 is electrically connected to the other of the source and the drain of the transistor 51, the gate of the transistor 52, and one electrode of the capacitor 57. The other of the source and the drain of the transistor 54 is electrically connected to a wiring 49. The gate of the transistor 54 is electrically connected to the wiring 41c. In the case where the subpixel 23 has the structure illustrated in FIG. 14B, the wiring 41a, the wiring 41b, and the wiring 41c are provided as the wiring 41 in the display device 10.

When the transistor 54 is brought into an on state, the gate potential of the transistor 52 can be the potential of the wiring 49. Here, a low potential can be supplied to the wiring 49, for example. Accordingly, current does not flow through the light-emitting element 60, for example; thus, the light-emitting element 60 does not emit light.

As described above, the transistor 100 of one embodiment of the present invention has high saturation. Thus, using the transistor 100 as the transistor 52 that is the driving transistor illustrated in each of FIG. 13C, FIG. 13D, FIG. 14A, and FIG. 14B stabilizes the current flowing through the light-emitting element 60. Accordingly, the emission luminance of the light-emitting element 60 is stabilized. For example, a time-related variation in the current flowing through the light-emitting element 60 can be inhibited. Accordingly, the display device 10 is capable of displaying a high-quality image on the display portion 20.

The transistor 100 can have a minute size. Thus, using the transistor 100 as the transistor included in the subpixel 23 enables the miniaturization of the pixel 21. As a result, the display device 10 can be a high-resolution display device. Accordingly, the display device 10 is capable of displaying a high-quality image on the display portion 20. For example, the transistor 100 can be used as each of the transistor 51 to the transistor 54.

The transistor 100 can also be used as the transistor included in the driver circuit of the display device 10. The transistor 100 can also be used as the transistor included in the scan line driver circuit 11 and the transistor included in the signal line driver circuit 13, for example. When the transistor 100 is used as at least one of the transistors included in the driver circuit of the display device 10, the area occupied by the driver circuit can be reduced. Thus, the display device 10 can have a narrow bezel.

The subpixel 23 illustrated in each of FIG. 14C and FIG. 14D includes a pixel circuit 40E and a liquid crystal element 69.

The pixel circuit 40E includes the transistor 51 and the capacitor 57. That is, the pixel circuit 40E is a 1Tr1C-type pixel circuit.

In the pixel circuit 40E, one of the source and the drain of the transistor 51 is electrically connected to the wiring 43. The other of the source and the drain of the transistor 51 is electrically connected to one electrode of the capacitor 57. The one electrode of the capacitor 57 is electrically connected to one electrode of the liquid crystal element 69. The gate of the transistor 51 is electrically connected to the wiring 41. Here, the one electrode of the liquid crystal element 69 is also referred to as a pixel electrode.

In the example illustrated in FIG. 14C, the other electrode of the capacitor 57 and the other electrode of the liquid crystal element 69 are electrically connected to the same wiring 46. In the example illustrated in FIG. 14D, a wiring 46a is electrically connected to the other electrode of the capacitor 57 as the wiring 46, and a wiring 46b is electrically connected to the other electrode of the liquid crystal element 69 as the wiring 46. That is, FIG. 14D illustrates an example in which the wiring 46 electrically connected to the other electrode of the capacitor 57 is different from the wiring 46 electrically connected to the other electrode of the liquid crystal element 69. The wiring 46 functions as a power supply line and can supply a ground potential, for example. Here, the other electrode of the liquid crystal element 69 may be referred to as a common electrode.

In the pixel circuit 40E, the transistor 51 has a function of a switch and has a function of controlling the conducting state and the non-conducting state between the wiring 43 and the one electrode of the liquid crystal element 69 on the basis of the potential of the wiring 41. When the transistor 51 is brought into an on state, image data is written to the pixel circuit 40E, and when the transistor 51 is brought into an off state, the written image data is retained.

The capacitor 57 has a function of retaining the potential of the one electrode of the liquid crystal element 69. The alignment state of the liquid crystal element 69 is controlled in accordance with a potential that corresponds to image data and is supplied to the one electrode of the liquid crystal element 69.

In the case where the liquid crystal element 69 is used as the display element, the display device 10 can employ any of a variety of modes. Examples of the mode include a vertical alignment (VA) mode, an FFS (Fringe Field Switching) mode, an IPS (In-Plane-Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element 69 include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

In the case where the liquid crystal element 69 is used as the display element, the display device 10 can be, for example, a transmissive liquid crystal display device, a reflective liquid crystal display device, or a transflective liquid crystal display device.

As described above, the transistor 100 can have a minute size. Thus, using the transistor 100 as the transistor 51 included in the pixel circuit 40E enables the miniaturization of the pixel 21. As a result, the display device 10 can be a high-resolution display device. Accordingly, the display device 10 is capable of displaying a high-quality image on the display portion 20.

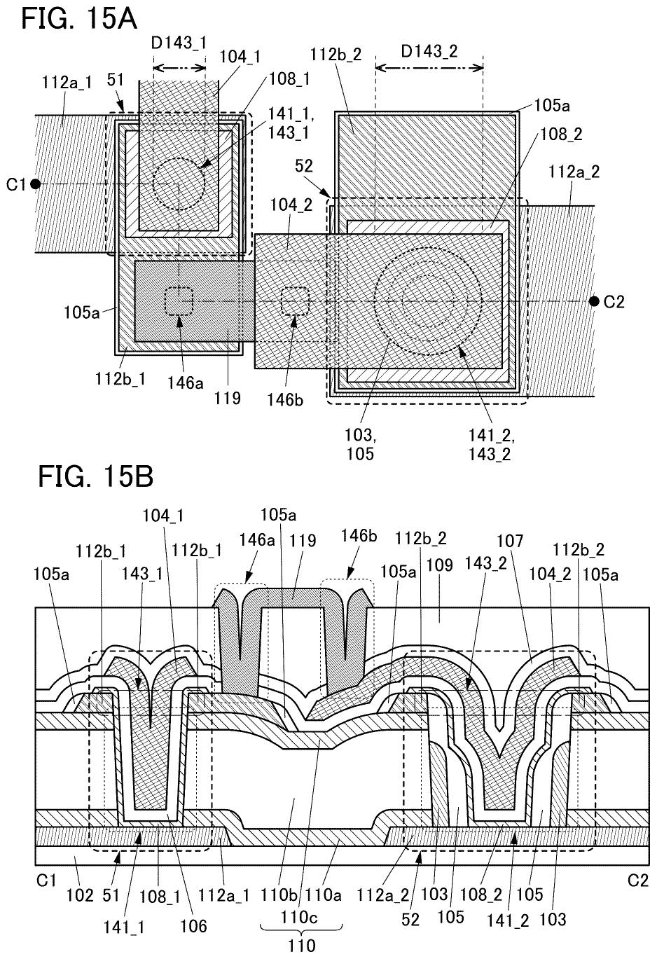

FIG. 15A is a plan view illustrating a structure example of the transistor 51 and the transistor 52. FIG. 15B is a cross-sectional view taken along the dashed-dotted line C1-C2 in FIG. 15A. FIG. 15A and FIG. 15B illustrate an example in which the transistor 51 has a structure where the conductive layer 103 and the insulating layer 105 are eliminated from the transistor 100 illustrated in FIG. 1A to FIG. 1C. FIG. 15A and FIG. 15B illustrate an example in which the transistor 100 illustrated in FIG. 1A to FIG. 1C is used as the transistor 52.

In FIG. 15A and FIG. 15B, the conductive layer 112a, the semiconductor layer 108, the conductive layer 112b, and the conductive layer 104 included in the transistor 51 are referred to as a conductive layer 112a_1, a semiconductor layer 108_1, a conductive layer 112b_1, and a conductive layer 1041, respectively. The opening portion 141 and the opening portion 143 provided in the transistor 51 are referred to as an opening portion 141_1 and an opening portion 143_1, respectively. The conductive layer 112a, the semiconductor layer 108, the conductive layer 112b, and the conductive layer 104 included in the transistor 52 are referred to as a conductive layer 112a_2, a semiconductor layer 108_2, a conductive layer 112b_2, and a conductive layer 1042, respectively. The opening portion 141 and the opening portion 143 provided in the transistor 52 are referred to as an opening portion 141_2 and an opening portion 143_2, respectively.

As illustrated in FIG. 15B, an insulating layer 109 is provided over the insulating layer 107. An opening portion 146a reaching the conductive layer 112b_1 is provided in the insulating layer 106, the insulating layer 107, and the insulating layer 109. An opening portion 146b reaching the conductive layer 1042 is provided in the insulating layer 107 and the insulating layer 109. A conductive layer 119 is provided to include a region positioned in the opening portion 146a, a region positioned in the opening portion 146b, and a region positioned over the insulating layer 109. The conductive layer 119 includes a region in contact with the conductive layer 112b_1 in the opening portion 146a and a region in contact with the conductive layer 104_2 in the opening portion 146b, for example. Thus, the conductive layer 112b_1 functioning as the source electrode or the drain electrode of the transistor 51 and the conductive layer 104_2 functioning as the gate electrode of the transistor 52 are electrically connected to each other.

The insulating layer 109 can have a function of a planarization layer. For the insulating layer 109, a material similar to the material that can be used for the insulating layer 107 can be used; for example, an organic insulating film or an inorganic insulating film can be used. It is particularly preferable to use an organic insulating film as the insulating layer 109, in which case the insulating layer 109 can be easily planarized. Note that the insulating layer 109 is not necessarily provided.

The conductive layer 119 has a function of a lead wiring. For the conductive layer 119, a material similar to the material that can be used for at least one of the conductive layer 112a, the conductive layer 112b, the conductive layer 103, and the conductive layer 104 can be used. It is particularly preferable to use a metal or an alloy as the conductive layer 119, in which case the electrical resistance of the conductive layer 119 can be reduced.

Although the plan-view shapes of the opening portion 146a and the opening portion 146b are rectangular shapes with rounded corners in FIG. 15A, the plan-view shapes of the opening portion 146a and the opening portion 146b are not limited thereto. The plan-view shapes of the opening portion 146a and the opening portion 146b can each be, for example, a shape similar to the shape that the opening portion 141 can have. The plan-view shapes of the opening portion 146a and the opening portion 146b can each be a circular shape, an elliptic shape, or a shape with one or both of a linear portion and a curved portion, for example.

FIG. 15A and FIG. 15B illustrate an example in which the insulating layer 105a is provided to cover the side surface of the conductive layer 112b_1 that is opposite to the opening portion 143_1 and the side surface of the conductive layer 112b_2 that is opposite to the opening portion 143_2. In the example illustrated in FIG. 15A and FIG. 15B, the insulating layer 105 can include a region in contact with the side surface of the conductive layer 112b_1 that is opposite to the opening portion 143_1 and a region in contact with the side surface of the conductive layer 112b_2 that is opposite to the opening portion 143_2. Note that as illustrated in FIG. 15A and FIG. 15B, the insulating layer 105a covering the side surface of the conductive layer 112b_1 that is opposite to the opening portion 143_1 and the insulating layer 105a covering the side surface of the conductive layer 112b_2 that is opposite to the opening portion 143_2 can be separated from each other.

The conductive layer 103 is not provided in the opening portion 141_1. The insulating layer 105 is provided in neither the opening portion 141_1 nor the opening portion 143_1. Thus, as illustrated in FIG. 15A, a width D143_1 of the opening portion 143_1 can be smaller than a width D143_2 of the opening portion 143_2. This enables the miniaturization of the transistor 51 as compared with that of the transistor 100 illustrated in FIG. 1A, for example. Meanwhile, the transistor 52 can have saturation higher than that of the transistor 51. Not providing the conductive layer 103 and the insulating layer 105 in the transistor 51 enables the miniaturization of the pixel 21 while the saturation of the transistor 52 functioning as a driving transistor is maintained. Note that the conductive layer 103 and the insulating layer 105 may be provided in the transistor 51. In this case, the transistor 51 and the transistor 52 can be formed in the same step.

Each of the transistor 53 and the transistor 54 illustrated in FIG. 13D to FIG. 14B has a function of a switch like the transistor 51. Thus, each of the transistor 53 and the transistor 54 preferably has a structure similar to that of the transistor 51. For example, in the case where the transistor 51 includes neither the conductive layer 103 nor the insulating layer 105, the transistor 53 and the transistor 54 preferably include neither the conductive layer 103 nor the insulating layer 105. Note that one or both of the transistor 53 and the transistor 54 may have a structure similar to that of the transistor 52.

### <Structure Example 2 of Semiconductor Device>

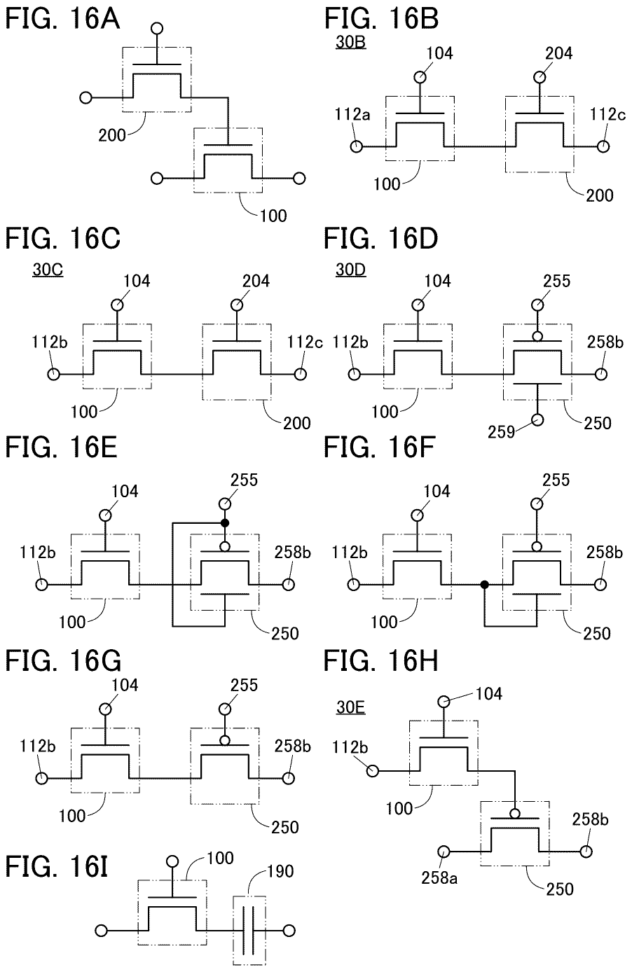

A semiconductor device including a plurality of transistors is described below with reference to FIG. 16A to FIG. 24B. FIG. 16A to FIG. 16I are circuit diagrams illustrating structure examples of the semiconductor device of one embodiment of the present invention.

The semiconductor device illustrated in FIG. 16A includes the transistor 100 and a transistor 200, for example. One of the source and the drain of the transistor 200 is electrically connected to the gate of the transistor 100.

Although the transistor 100 and the transistor 200 are shown as n-channel transistors in FIG. 16A to FIG. 16C, one embodiment of the present invention is not limited to these examples. One or both of the transistor 100 and the transistor 200 may be a p-channel transistor(s).

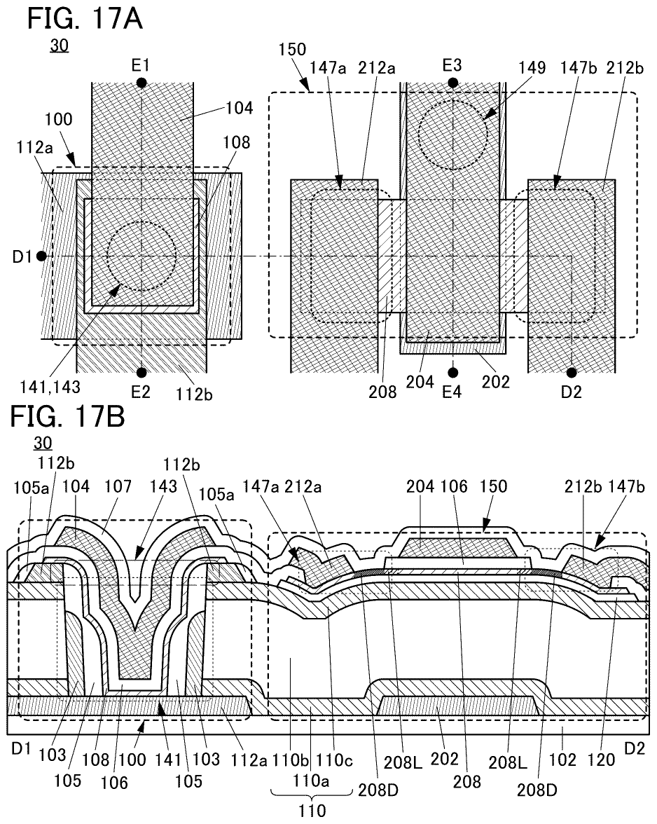

FIG. 17A is a plan view illustrating a structure example of a semiconductor device 30 that is the semiconductor device of one embodiment of the present invention. In FIG. 17A, the conductive layer 103, the insulating layer 105, the insulating layer 105a, and the insulating layer 110 are not illustrated. The same applies to the following plan views.

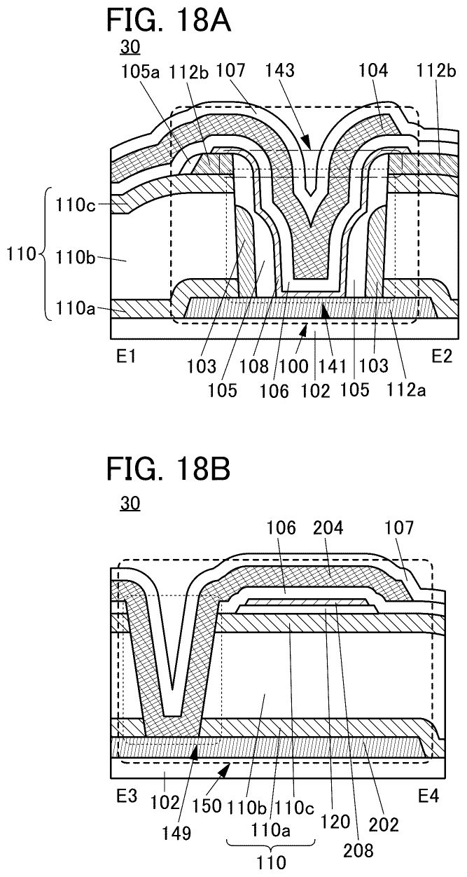

FIG. 17B is a cross-sectional view taken along the dashed-dotted line D1-D2 in FIG. 17A. FIG. 18A is a cross-sectional view taken along the dashed-dotted line E1-E2 in FIG. 17A. FIG. 18B is a cross-sectional view taken along the dashed-dotted line E3-E4 in FIG. 17A.

The semiconductor device 30 includes the transistor 100 and a transistor 150. The transistor 100 and the transistor 150 are provided over the substrate 102.

The above description can be referred to for the transistor 100; thus, the detailed description thereof is omitted.

The transistor 150 includes a conductive layer 202, the insulating layer 110, an insulating layer 120, a semiconductor layer 208, the insulating layer 106, a conductive layer 204, a conductive layer 212a, and a conductive layer 212b. The layers included in the transistor 150 may each have a single-layer structure or a stacked-layer structure.

The conductive layer 202 is provided over the substrate 102. The conductive layer 202 functions as the back gate electrode of the transistor 150. The conductive layer 202 can be formed using the same material as the conductive layer 112a included in the transistor 100. The conductive layer 202 can be formed in the same step as the conductive layer 112a. For example, a film to be the conductive layer 112a and the conductive layer 202 is formed and then processed, whereby the conductive layer 112a and the conductive layer 202 can be formed. Note that the conductive layer 202 may be formed in a step different from that of the conductive layer 112a. By forming in different steps, a material different from that for the conductive layer 112a can be used for the conductive layer 202. The conductive layer 202 includes neither a region in contact with the semiconductor layer 108 nor a region in contact with the semiconductor layer 208, and thus there is no particular limitation on a material used for the conductive layer 202. For example, for the conductive layer 202, a material with lower electrical resistivity than the conductive layer 112a is preferably used. In this case, the electrical resistance of the conductive layer 202 can be reduced. For example, In—Sn—Si oxide (ITSO) can be suitably used for the conductive layer 112a and copper or tungsten can be suitably used for the conductive layer 202. Note that the transistor 150 does not necessarily include a back gate electrode.

The insulating layer 110 is provided to cover the conductive layer 202, and the insulating layer 120 is provided over the insulating layer 110. The insulating layer 110 and the insulating layer 120 function as the back gate insulating layer of the transistor 150. The insulating layer 120 is a layer in contact with the channel formation region of the semiconductor layer 208 and thus is preferably an insulating layer containing oxygen. For the insulating layer 120, for example, a material suitable for the insulating layer 110b can be used.

The semiconductor layer 208 is provided over the insulating layer 120. The semiconductor layer 208 includes a region overlapping with the conductive layer 202 with the insulating layer 110 and the insulating layer 120 therebetween. The semiconductor layer 208 can be formed using the same material as the semiconductor layer 108. The semiconductor layer 208 can be formed in the same step as the semiconductor layer 108.

The insulating layer 106 is provided to cover the insulating layer 120 and the semiconductor layer 208. The insulating layer 106 functions as a gate insulating layer of the transistor 150. The insulating layer 106 includes an opening portion 147a and an opening portion 147b reaching the semiconductor layer 208.

The conductive layer 204, the conductive layer 212a, and the conductive layer 212b are provided over the insulating layer 106. The conductive layer 204, the conductive layer 212a, and the conductive layer 212b can include the same material as the conductive layer 104. The conductive layer 204, the conductive layer 212a, and the conductive layer 212b can be formed in the same step as the conductive layer 104. For example, a film to be the conductive layer 104, the conductive layer 204, the conductive layer 212a, and the conductive layer 212b is formed and processed, whereby the conductive layer 104, the conductive layer 204, the conductive layer 212a, and the conductive layer 212b can be formed.

The conductive layer 212a is provided to cover at least part of the opening portion 147a, and the conductive layer 212b is provided to cover at least part of the opening portion 147b. Each of the conductive layer 212a and the conductive layer 212b includes a region in contact with the semiconductor layer 208. The conductive layer 212a is electrically connected to the semiconductor layer 208 through the opening portion 147a. The conductive layer 212b is electrically connected to the semiconductor layer 208 through the opening portion 147b. The conductive layer 212a functions as one of the source electrode and the drain electrode of the transistor 150. The conductive layer 212b functions as the other of the source electrode and the drain electrode of the transistor 150.

The conductive layer 204 includes a region overlapping with the semiconductor layer 208 with the insulating layer 106 therebetween. The conductive layer 204 functions as the gate electrode of the transistor 150.

As illustrated in FIG. 18B, the conductive layer 204 and the conductive layer 202 may be in contact with each other and electrically connected to each other. In that case, the conductive layer 204 and the conductive layer 202 can be supplied with the same potential. When the same potential is applied to the conductive layer 204 and the conductive layer 202, the amount of current that can flow through the transistor 150 in the on state can be increased. The conductive layer 204 can be electrically connected to the conductive layer 202 through an opening portion 149 provided in the insulating layer 106 and the insulating layer 110.

The conductive layer 212a or the conductive layer 212b may be electrically connected to the conductive layer 202. When the same potential is applied to the source and the back gate, generation of the DIBL effect in the transistor 150 can be inhibited. Thus, the saturation of the transistor 100 can be improved. The conductive layer 212a or the conductive layer 212b can be in contact with the conductive layer 202 through an opening portion provided in the insulating layer 106 and the insulating layer 110.

A structure may be employed in which the conductive layer 202 is not electrically connected to any of the conductive layer 204, the conductive layer 212a, and the conductive layer 212b. For example, a constant potential is applied to the back gate, and a signal for driving the transistor 150 can be supplied to the gate. Accordingly, the potential supplied to the back gate enables control of the threshold voltage in driving the transistor 150.

In the semiconductor layer 208 between the source electrode and the drain electrode, the whole region overlapping with the gate electrode with the gate insulating layer therebetween serves as a channel formation region. The semiconductor layer 208 includes a pair of regions 208L between which a channel formation region is sandwiched and a pair of regions 208D outside the pair of regions 208L.

The region 208D can also be referred to as a region having a higher carrier concentration or a lower resistance than the channel formation region. In the semiconductor layer 208, a region in contact with the conductive layer 212a and the region 208D adjacent to the region serve as one of a source region and a drain region. In the semiconductor layer 208, a region in contact with the conductive layer 212b and the region 208D adjacent to the region serve as the other of the source region and the drain region.

The region 208L can be referred to as a region whose resistance is substantially equal to or lower than that of the channel formation region, a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. The region 208L can also be referred to as a region whose resistance is substantially equal to or higher than that of the region 208D, a region whose carrier concentration is substantially equal to or lower than that of the region 208D, a region whose oxygen vacancy density is substantially equal to or lower than that of the region 208D, or a region whose impurity concentration is substantially equal to or lower than that of the region 208D.

The region 208L serves as a buffer region that relieves a drain electric field. The region 208L is a region not overlapping with the conductive layer 204 and thus is a region where a channel is hardly formed by application of gate voltage to the conductive layer 204. The region 208L preferably has a higher carrier concentration than the channel formation region. Thus, the region 208L can serve as an LDD (Lightly Doped Drain) region. The region 208L functioning as the LDD region provided between the channel formation region and the region 208D enables the transistor 150 to have a high drain breakdown voltage.

For example, after the conductive layer 204, the conductive layer 212a, and the conductive layer 212b are formed, an impurity element is added to the semiconductor layer 208 using these conductive layers as masks, whereby the region 208L and the region 208D can be formed. The region 208L is a region that is of the semiconductor layer 208, overlaps with the insulating layer 106, and does not overlap with the conductive layer 204. The region 208D is a region that is of the semiconductor layer 208 and overlaps with neither the insulating layer 106 nor the conductive layer 204.

As illustrated in FIG. 17A and FIG. 17B, it is preferable that the end portions of the conductive layer 212a and the conductive layer 212b be partly positioned in the opening portion 147a and the opening portion 147b, respectively. In other words, it is preferable that the end portions of the conductive layer 212a and the conductive layer 212b be partly in contact with the semiconductor layer 208 in the opening portion 147a and the opening portion 147b, respectively. Accordingly, the region in contact with the conductive layer 212a can be adjacent to one of the pair of regions 208D, and the region in contact with the conductive layer 212b can be adjacent to the other of the pair of regions 208D. There is no particular limitation on the plan-view shapes of the opening portion 147a and the opening portion 147b.

The region 208L and the region 208D contain an impurity element. Examples of the impurity element include one or more of hydrogen, boron, carbon, nitrogen, fluorine, phosphorus, sulfur, arsenic, aluminum, magnesium, silicon, and a noble gas. Typical examples of the noble gas include helium, neon, argon, krypton, and xenon. It is particularly preferable to use one or more of boron, phosphorus, aluminum, magnesium, and silicon as the impurity element.

When the region 208L and the region 208D are formed by adding the impurity element to the semiconductor layer 208, the impurity element may be supplied to the semiconductor layer 108 through the insulating layer 106 with use of the conductive layer 104 as a mask. Consequently, a region including the impurity element is formed in the region of the semiconductor layer 108 not overlapping with the conductive layer 104. Here, in the transistor 100, a region of the semiconductor layer 108 that is in contact with the conductive layer 112b functions as a source region or a drain region. Thus, the region containing the impurity element is formed in part of the source region or the drain region.

The transistor 150 is what is called a top-gate transistor including the gate electrode above the semiconductor layer 208. For example, when an impurity element is added to the semiconductor layer 208 with the conductive layer 204, which serves as the gate electrode, used as a mask, a source region and a drain region can be formed in a self-aligned manner. The transistor 150 can be referred to as a TGSA (Top Gate Self-Aligned) transistor.

The channel length of the transistor 150 can be controlled by the width of the conductive layer 204 in the channel length direction. Accordingly, the channel length of the transistor 150 is greater than or equal to the definition limit of a light-exposure apparatus used for manufacturing the transistor. The transistor with a large channel length can have high saturation.

The insulating layer 107 is provided to cover the transistor 100 and the transistor 150. The insulating layer 107 functions as a protective layer as described above.

In manufacturing the semiconductor device 30, the transistor 100 with a small channel length and the transistor 150 with a large channel length can be formed over the same substrate by the formation steps some of which are shared. For example, when the transistor 100 is used as the transistor required to have a high on-state current and the transistor 150 is used as the transistor required to have favorable saturation, the semiconductor device can achieve high performance.

Although FIG. 17B illustrates an example in which the conductive layer 212a and the conductive layer 212b are formed in the same step as the conductive layer 104 and the conductive layer 204, one embodiment of the present invention is not limited thereto. For example, the conductive layer 212a and the conductive layer 212b may be formed after the insulating layer 107 is formed. Specifically, a structure in which the conductive layer 212a and the conductive layer 212b are electrically connected to the semiconductor layer 208 may be formed in the following manner: after the insulating layer 107 is provided to cover the conductive layer 104 and the conductive layer 204, an opening portion reaching the semiconductor layer 208 is provided in the insulating layer 107 and the insulating layer 106, and the conductive layer 212a and the conductive layer 212b are provided to cover the opening portion. Note that by adding an impurity element to the semiconductor layer 208 with the conductive layer 204 as a mask after the conductive layer 204 is formed, a low-resistance region can be formed in the semiconductor layer 208.

Structures of a semiconductor device 30A, a semiconductor device 30B, a semiconductor device 30C, a semiconductor device 30D, and a semiconductor device 30E are described below as modification examples of the semiconductor device 30.

### [Semiconductor Device 30A]

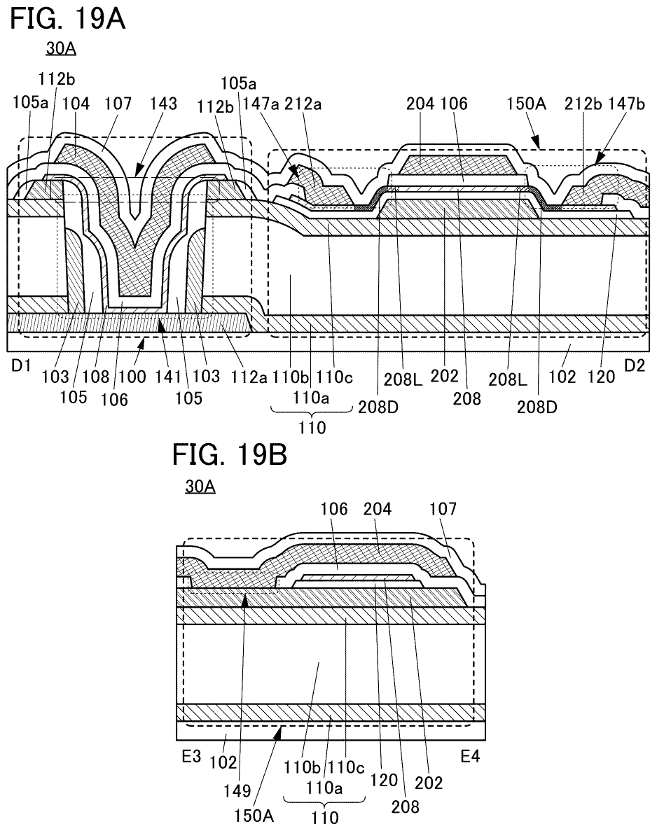

FIG. 19A and FIG. 19B are cross-sectional views illustrating a structure example of the semiconductor device 30A. FIG. 17A can be referred to for a planar structure example of the semiconductor device 30A. FIG. 19A is a cross-sectional view taken along the dashed-dotted line D1-D2 in FIG. 17A. FIG. 19B is a cross-sectional view taken along the dashed-dotted line E3-E4 in FIG. 17A. FIG. 18A can be referred to for a cross-sectional structure example taken along the dashed-dotted line E1-E2 in FIG. 17A.

The semiconductor device 30A includes the transistor 100 and the transistor 150A. The transistor 150A is different from the transistor 150 illustrated in FIG. 17B, for example, mainly in that the conductive layer 202 is provided between the insulating layer 110 and the insulating layer 120.

In the semiconductor device 30A, the conductive layer 202 is provided over the insulating layer 110. The conductive layer 202 can be formed using the same material as the conductive layer 112b. The conductive layer 202 can be formed in the same step as the conductive layer 112b.

The insulating layer 120 is provided over the conductive layer 202. The insulating layer 120 is provided so as to cover the top surface and the side surface of part of the conductive layer 202. The insulating layer 120 is provided at least in a region where the semiconductor layer 208 and the conductive layer 204 overlap with each other. In the transistor 150A, part of the insulating layer 120 functions as a back gate insulating layer. When the conductive layer 202 is provided between the insulating layer 110 and the insulating layer 120, the thickness of the back gate insulating layer of the transistor 150A can be reduced. Thus, the electric field of the back gate electrode can be intensified. Furthermore, the saturation of the transistor 150A can be improved. Moreover, a shift of the threshold voltage can be inhibited; accordingly, the cutoff current of the transistor can be reduced.

The insulating layer 120 preferably has a stacked-layer structure. The insulating layer 120 can have a stacked-layer structure of two layers, for example. In this case, the lower layer of the insulating layer 120 can include a region in contact with the conductive layer 202, and the upper layer of the insulating layer 120 can include a region in contact with the channel formation region of the semiconductor layer 208.

The lower layer of the insulating layer 120 is preferably formed using a material that does not easily allow diffusion of a metal element contained in the conductive layer 202. In that case, a metal element contained in the conductive layer 202 can be inhibited from being diffused to the channel formation region of the semiconductor layer 208. For the lower layer of the insulating layer 120, a material that can be used for the insulating layer 110a and the insulating layer 110c can be suitably used. For the lower layer of the insulating layer 120, silicon nitride can be suitably used, for example.

As the upper layer of the insulating layer 120, an insulating layer containing oxygen is preferably used. For the upper layer of the insulating layer 120, a material suitable for the insulating layer 110b can be used. For the upper layer of the insulating layer 120, silicon oxynitride can be suitably used, for example.

The above description can be referred to for the transistor 100; thus, the detailed description thereof is omitted.

### [Semiconductor Device 30B]

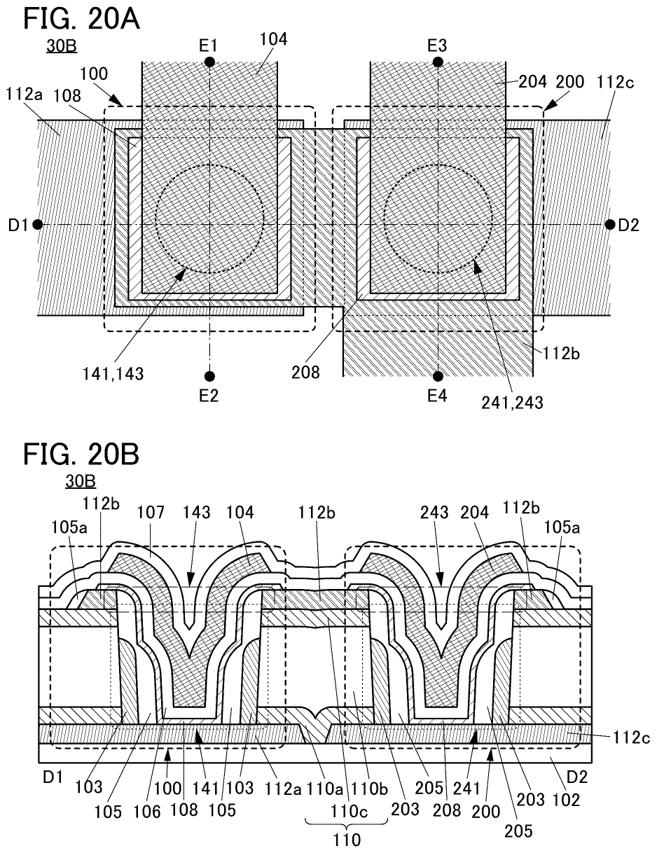

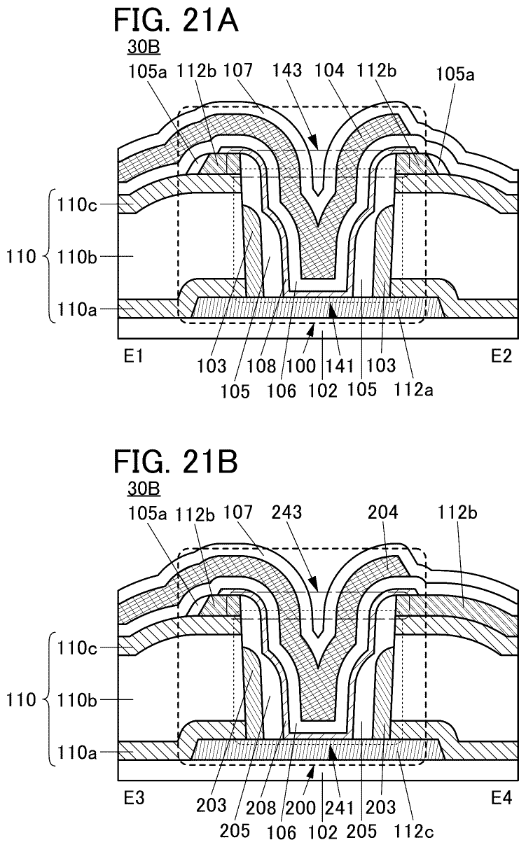

FIG. 16B is a circuit diagram illustrating a structure example of the semiconductor device 30B. FIG. 20A is a plan view illustrating a structure example of the semiconductor device 30B. FIG. 20B is a cross-sectional view taken along the dashed-dotted line D1-D2 in FIG. 20A. FIG. 21A is a cross-sectional view taken along the dashed-dotted line E1-E2 in FIG. 20A. FIG. 21B is a cross-sectional view taken along the dashed-dotted line E3-E4 in FIG. 20A.

The semiconductor device 30B includes the transistor 100 and the transistor 200. The other of the source and the drain of the transistor 200 is electrically connected to the other of the source and the drain of the transistor 100.

The transistor 100 and the transistor 200 are provided over the substrate 102.

The above description can be referred to for the transistor 100; thus, the detailed description thereof is omitted.

The transistor 200 includes the conductive layer 112b, a conductive layer 112c, a conductive layer 203, an insulating layer 205, the semiconductor layer 208, the insulating layer 106, and the conductive layer 204. The transistor 200 can have a structure similar to that of the transistor 100.

The conductive layer 112c functions as one of the source electrode and the drain electrode of the transistor 200. The conductive layer 112b functions as the other of the source electrode and the drain electrode of the transistor 100 and also functions as the other of the source electrode and the drain electrode of the transistor 200. Since the transistor 100 and the transistor 200 share the conductive layer 112b, the semiconductor device occupies a smaller area.

The conductive layer 203 functions as the back gate electrode of the transistor 200. The insulating layer 205 functions as the back gate insulating layer of the transistor 200. Part of the insulating layer 106 functions as a gate insulating layer of the transistor 200. The conductive layer 204 functions as the gate electrode of the transistor 200.

For the conductive layer 112c, the same material as the conductive layer 112a can be used. The conductive layer 112c can be formed in the same step as the conductive layer 112a. The insulating layer 110 includes an opening portion 241 reaching the conductive layer 112c. The opening portion 241 can be formed in the same step as the opening portion 141. The conductive layer 112b includes an opening portion 243 in a region overlapping with the opening portion 241. The opening portion 243 can be formed in the same step as the opening portion 143. The shape of the opening portion 241 can be similar to the shape that the opening portion 141 can have. The shape of the opening portion 243 can be similar to the shape that the opening portion 143 can have.

The width of the opening portion 141 may be different from the width of the opening portion 241. When the opening portions have different widths, two transistors with different channel widths can be manufactured.

The conductive layer 203 is provided to be positioned in the opening portion 241 and to be electrically connected to the conductive layer 112c. The conductive layer 203 includes a region in contact with the conductive layer 112c and a region in contact with the side surface of the insulating layer 110 that is positioned in the opening portion 241, for example. Note that in the case where a region where the conductive layer 203 and the conductive layer 112c are in contact with each other is included, the boundary between the conductive layer 203 and the conductive layer 112c cannot be clearly recognized in some cases.

The conductive layer 203 can be formed using the same material as the conductive layer 103. The conductive layer 203 can be formed in the same step as the conductive layer 103. The conductive layer 103 and the conductive layer 203 can be formed in the following manner, for example: a conductive film is formed to cover the opening portion 141, the opening portion 143, the opening portion 241, and the opening portion 243, and then anisotropic etching is performed on the conductive film. By performing the anisotropic etching on the conductive layer 203, the transistor 200 can have a minute size.

The insulating layer 205 is provided to cover the conductive layer 203 in the opening portion 241. The insulating layer 205 includes, for example, a region in contact with the conductive layer 203 and a region in contact with the conductive layer 112c in the opening portion 241.

The insulating layer 205 can be formed using the same material as the insulating layer 105. The insulating layer 205 can be formed in the same step as the insulating layer 105. The insulating layer 105 and the insulating layer 205 can be formed in the following manner, for example: an insulating film is formed to cover the opening portion 141, the opening portion 143, the opening portion 241, and the opening portion 243, and then anisotropic etching is performed on the insulating film.

The semiconductor layer 208 is provided to cover the opening portion 241 and the opening portion 243. The semiconductor layer 208 can be formed in the same step as the semiconductor layer 108. The insulating layer 106 is provided over the semiconductor layer 208, and the conductive layer 204 is provided over the insulating layer 106. The conductive layer 204 can be formed in the same step as the conductive layer 104.

Although FIG. 20A and FIG. 20B illustrate an example in which the semiconductor layer is separated into the semiconductor layer 108 and the semiconductor layer 208 in the transistor 100 and the transistor 200, respectively, one embodiment of the present invention is not limited thereto. The transistor 100 and the transistor 200 may share a semiconductor layer.

### [Semiconductor Device 30C]

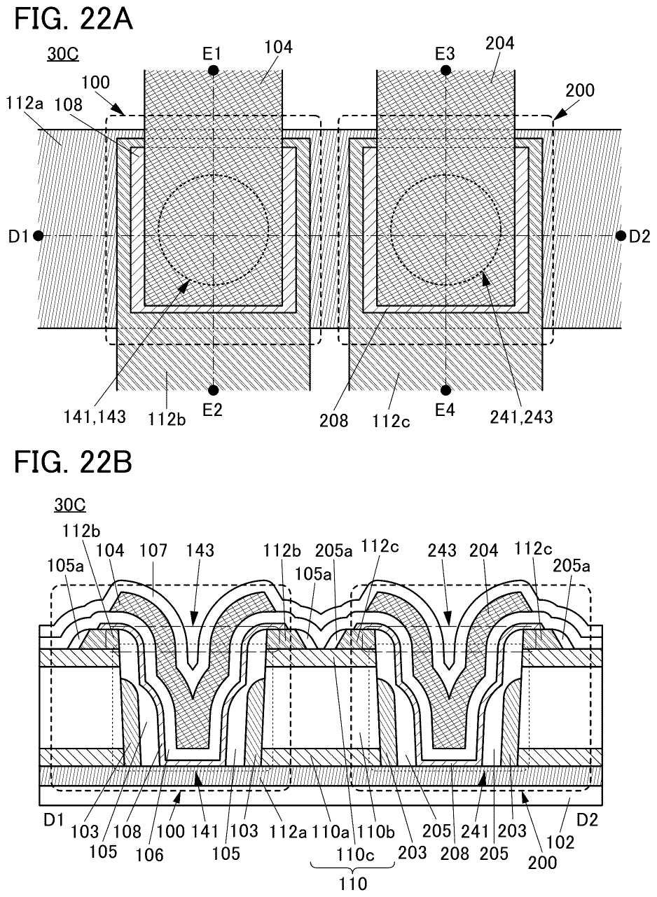

FIG. 16C is a circuit diagram illustrating a structure example of the semiconductor device 30C. FIG. 22A is a plan view illustrating a structure example of the semiconductor device 30C. FIG. 22B is a cross-sectional view taken along the dashed-dotted line D1-D2 in FIG. 22A. FIG. 21A can be referred to for a cross-sectional structure example taken along the dashed-dotted line E1-E2 in FIG. 22A. FIG. 21B can be referred to for a cross-sectional structure example taken along the dashed-dotted line E3-E4 in FIG. 22A.

The semiconductor device 30C includes the transistor 100 and the transistor 200. One of the source and the drain of the transistor 200 is electrically connected to one of the source and the drain of the transistor 100.

The transistor 100 and the transistor 200 are provided over the substrate 102.

The above description can be referred to for the transistor 100; thus, the detailed description thereof is omitted.

The transistor 200 includes the conductive layer 112a, the conductive layer 112c, the conductive layer 203, the insulating layer 205, the semiconductor layer 208, the insulating layer 106, and the conductive layer 204.

The conductive layer 112a functions as one of the source electrode and the drain electrode of the transistor 100 and also functions as one of the source electrode and the drain electrode of the transistor 200. The conductive layer 112c functions as the other of the source electrode and the drain electrode of the transistor 200. Since the transistor 100 and the transistor 200 share the conductive layer 112a, the semiconductor device occupies a smaller area.

For the conductive layer 112c, the same material as the conductive layer 112b can be used. The conductive layer 112c can be formed in the same step as the conductive layer 112b. In the semiconductor device 30C, the opening portion 241 reaching the conductive layer 112a is formed in the insulating layer 110. The opening portion 243 is formed in the conductive layer 112c.

### [Semiconductor Device 30D]

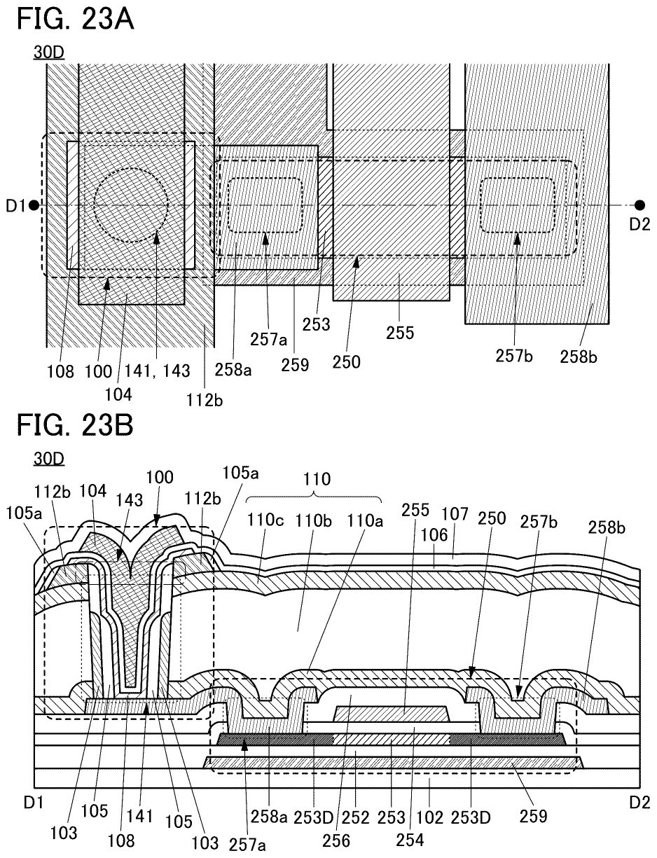

FIG. 16D is a circuit diagram illustrating a structure example of the semiconductor device 30D. FIG. 23A is a plan view illustrating a structure example of the semiconductor device 30D. FIG. 23B is a cross-sectional view taken along the dashed-dotted line D1-D2 in FIG. 23A.

The semiconductor device 30D includes the transistor 100 and a transistor 250. One of the source and the drain of the transistor 250 is electrically connected to one of the source and the drain of the transistor 100.

The transistor 100 and the transistor 250 are provided over the substrate 102.

The semiconductor device 30D includes a conductive layer 259 over the substrate 102, an insulating layer 252 over the substrate 102 and the conductive layer 259, and a semiconductor layer 253 over the insulating layer 252. Furthermore, an insulating layer 254 is provided over the insulating layer 252 and the semiconductor layer 253, and a conductive layer 255 is provided over the insulating layer 254. The semiconductor layer 253 and the conductive layer 255 overlap with each other in a region. The conductive layer 259 functions as the back gate electrode of the transistor 250, and the insulating layer 252 functions as a back gate insulating layer. The insulating layer 254 functions as a gate insulating layer, and the conductive layer 255 functions as a gate electrode.

An insulating layer 256 is provided over the insulating layer 254 and the conductive layer 255. The insulating layer 254 and the insulating layer 256 are provided with an opening portion 257a in a region overlapping with part of the semiconductor layer 253. The insulating layer 254 and the insulating layer 256 are provided with an opening portion 257b in a region overlapping with another part of the semiconductor layer 253.

A conductive layer 258a is provided to include a region positioned over the insulating layer 256 and a region positioned in the opening portion 257a. A conductive layer 258b is provided to include a region positioned over the insulating layer 256 and a region positioned in the opening portion 257b. The conductive layer 258a includes a region in contact with the semiconductor layer 253 in the opening portion 257a. The conductive layer 258b includes a region in contact with the semiconductor layer 253 in the opening portion 257b.

The region of the semiconductor layer 253 that overlaps with the conductive layer 255 functions as a channel formation region. The semiconductor layer 253 includes a pair of regions 253D between which the channel formation region is interposed. One of the pair of regions 253D functions as one of a source region and a drain region and is electrically connected to the conductive layer 258a. The other of the pair of regions 253D functions as the other of the source region and the drain region and is electrically connected to the conductive layer 258b.

The insulating layer 110 is provided over the insulating layer 256, the conductive layer 258a, and the conductive layer 258b, and the conductive layer 112b is provided over the insulating layer 110.

It is preferable that the conductive layer 259 overlap with the channel formation region of the transistor 250 and extend beyond the end portion of the channel formation region of the transistor 250. That is, the conductive layer 259 is preferably larger than the channel formation region of the transistor 250. It is preferable that the conductive layer 259 extend beyond the end portion of the semiconductor layer 253. That is, the conductive layer 259 is preferably larger than the semiconductor layer 253.

The gate electrode and the back gate electrode are placed so that the channel formation region of the semiconductor layer is sandwiched therebetween. By changing the potential of the back gate electrode, the threshold voltage of a transistor can be changed. The potential of the back gate electrode may be a ground potential or a given potential.

The back gate electrode can be formed using a material and a method similar to those used for the gate electrode, the source electrode, the drain electrode, or the like. The gate electrode and the back gate electrode are conductive layers and thus each have a function of preventing an electric field generated outside the transistor from affecting the semiconductor layer in which the channel is formed (in particular, an electric field blocking function against static electricity). That is, a change in electrical characteristics of the transistor due to the influence of an external electric field such as static electricity can be prevented. By providing the back gate electrode, the amount of change in threshold voltage of the transistor in a BT (Bias Temperature) stress test can be reduced. By providing the back gate electrode, the variation in the characteristics of the transistor can be reduced and the reliability of a semiconductor device can be increased.

As illustrated in FIG. 16E, the back gate and the gate of the transistor 250 may be electrically connected to each other. As illustrated in FIG. 16F, the back gate of the transistor 250 and the source or the drain thereof may be electrically connected to each other. As illustrated in FIG. 16G, the transistor 250 does not necessarily include a back gate.

Although the transistor 100 is shown as an n-channel transistor and the transistor 250 is shown as a p-channel transistor in FIG. 16D to FIG. 16H, one embodiment of the present invention is not limited to these examples. Both the transistor 100 and the transistor 250 may be n-channel transistors or p-channel transistors. Alternatively, the transistor 100 may be a p-channel transistor and the transistor 250 may be an n-channel transistor.

Like the transistor 100, the transistor 250 may be an OS transistor.

Here, for the semiconductor layer 108 and the semiconductor layer 253, the same material or different materials may be used. For the structures of the semiconductor layer 108 and the semiconductor layer 253, the description of the semiconductor layer 108 and the semiconductor layer 208 of the semiconductor device 30 can be referred to.

A transistor including silicon in a channel formation region (hereinafter also referred to as a Si transistor) may be used as the transistor 250.

As silicon, single crystal silicon, polycrystalline silicon, amorphous silicon, and the like can be given. In particular, a transistor including LTPS in a semiconductor layer (hereinafter also referred to as an LTPS transistor) can be used. The LTPS transistor has high field-effect mobility and favorable frequency characteristics.

The structure of the transistor 100 included in the semiconductor device 30D is the same as the above-described structure except that the conductive layer 258a is provided instead of the conductive layer 112a.

The conductive layer 258a functions as one of the source electrode and the drain electrode of the transistor 100 and also functions as one of the source electrode and the drain electrode of the transistor 250. Since the transistor 100 and the transistor 250 share the conductive layer 258a, the semiconductor device occupies a smaller area.

As described above, the transistor 100 is a vertical channel-type transistor. Meanwhile, in the semiconductor layer of the transistor 250, current flows in the lateral direction, i.e., the direction parallel or substantially parallel to the surface of the substrate 102. Such a transistor is also referred to as a lateral transistor, a lateral channel-type transistor, a lateral-channel transistor, or the like.

As described above, the semiconductor device of one embodiment of the present invention may include not only a vertical channel-type transistor but also a lateral channel-type transistor.

Note that the transistor 100 may be formed in a region overlapping with the opening portion 257a. Specifically, the opening portion 141 and the opening portion 143 are provided in a region overlapping with the opening portion 257a, and the conductive layer 258a can be in contact with the semiconductor layer 108 and the conductive layer 103 in the opening portion 257a. Furthermore, a structure may be employed in which the conductive layer 258a is not provided and the region 253D is in contact with the semiconductor layer 108 and the conductive layer 103 in the opening portion 257a. With such a structure, a semiconductor device that occupies a smaller area can be provided.

### [Semiconductor Device 30E]

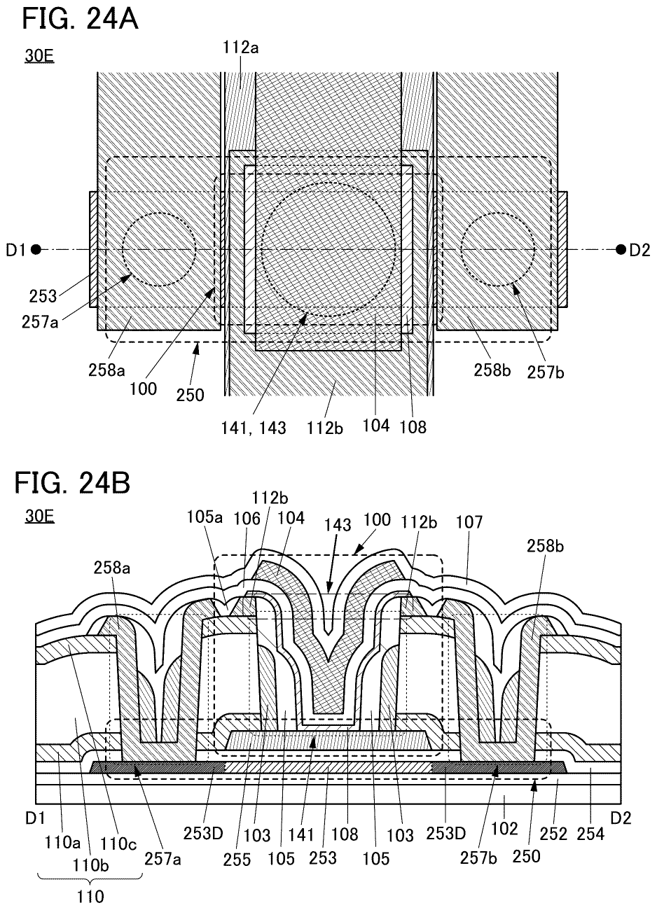

FIG. 16H is a circuit diagram illustrating a structure example of the semiconductor device 30E. FIG. 24A is a plan view illustrating a structure example of the semiconductor device 30E. FIG. 24B is a cross-sectional view taken along the dashed-dotted line D1-D2 in FIG. 24A.

The semiconductor device 30E includes the transistor 100 and the transistor 250. The gate of the transistor 250 is electrically connected to one of the source and the drain of the transistor 100.

The semiconductor device 30E is different from the semiconductor device 30D mainly in that the opening portion 141 and the opening portion 143 are provided to overlap with the conductive layer 255 functioning as the gate electrode of the transistor 250. Accordingly, in the semiconductor device 30D, the transistor 100 is provided over the gate electrode of the transistor 250 to overlap therewith.

Although the opening portion 141 and the opening portion 143 are provided to overlap with the channel formation region of the transistor 250 in FIG. 24A and FIG. 24B, one embodiment of the present invention is not limited thereto. The opening portion 141 and the opening portion 143 may be provided so as not to overlap with the channel formation region of the transistor 250 but to overlap with the conductive layer 255. In the semiconductor device 30E, the conductive layer 255 functions as one of the source electrode and the drain electrode of the transistor 100 and also functions as the gate electrode of the transistor 250.

When the transistor 100 and the transistor 250 are provided to overlap with each other, a semiconductor device that occupies a smaller area can be provided.

The semiconductor device 30E is different from the semiconductor device 30D in the structures of the opening portion 257a, the opening portion 257b, the conductive layer 258a, and the conductive layer 258b.

Each of the opening portion 257a and the opening portion 257b is formed by selectively removing part of the insulating layer 254 and part of the insulating layer 110 in a region overlapping with the region 253D of the semiconductor layer 253. The conductive layer 258a and the conductive layer 258b that are provided over the insulating layer 110 are electrically connected to the regions 253D through the respective opening portion 257a and opening portion 257b.

In the semiconductor device 30E, the conductive layer 258a and the conductive layer 258b can be formed in the same step as the conductive layer 112b. Formation processes of the conductive layers 258a and 258b and the conductive layer 112b are not necessarily separate; thus, the manufacturing process of the semiconductor device can be shortened and the productivity of the semiconductor device can be increased.

The semiconductor device of one embodiment of the present invention includes at least one transistor and at least one capacitor, and the source and the drain of the transistor are electrically connected to one of the pair of electrodes of the capacitor. FIG. 16I illustrates an example in which the source or the drain of the transistor 100 is electrically connected to one electrode of a capacitor 190.

In the transistor of one embodiment of the present invention, which is a kind of vertical transistor, a source electrode, a semiconductor layer, and a drain electrode can be provided to overlap with each other; thus, the area occupied by the transistor can be significantly smaller than the area occupied by a planar transistor. When a planar transistor is used as a p-channel Si transistor and a vertical transistor is used as an n-channel OS transistor, a CMOS (Complementary Metal Oxide Semiconductor) circuit can be formed. When the planar transistor and the vertical transistor are provided to overlap with each other in this structure, the area occupied by the CMOS circuit can be reduced.

### <Manufacturing Method Example 1 of Semiconductor Device>

An example of a method for manufacturing the semiconductor device of one embodiment of the present invention will be described below with reference to drawings.

Thin films included in the semiconductor device (e.g., insulating films, semiconductor films, and conductive films) can be formed by a sputtering method, a CVD method, a vacuum evaporation method, a pulsed laser deposition (PLD) method, an ALD method, or the like. Examples of a CVD method include a PECVD method and a thermal CVD method. An example of the thermal CVD method is a metal organic chemical vapor deposition (MOCVD: Metal Organic CVD) method.

Thin films included in the semiconductor device (e.g., insulating films, semiconductor films, and conductive films) can be formed by a wet film-formation method such as a spin coating method, a dip coating method, a spray coating method, an inkjet method, dispensing, screen printing, offset printing, a doctor knife method, slit coating, roll coating, curtain coating, or knife coating.

The thin films can be processed by, for example, etching of the thin films in accordance with a pattern of a resist mask that has been formed by a photolithography method. Alternatively, a nanoimprinting method, a sandblasting method, a lift-off method, or the like may be used for the processing of the thin films. Alternatively, island-shaped thin films may be directly formed by a film formation method using a shielding mask such as a metal mask. A photosensitive thin film can be processed by light exposure and development. That is, the photosensitive thin film can be processed by a photolithography method.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. EUV light, X-rays, or an electron beam is preferably used to enable extremely minute processing. Note that a photomask is not needed when light exposure is performed by scanning with a beam such as an electron beam.

For etching of thin films, a dry etching method, a wet etching method, or the like can be used.

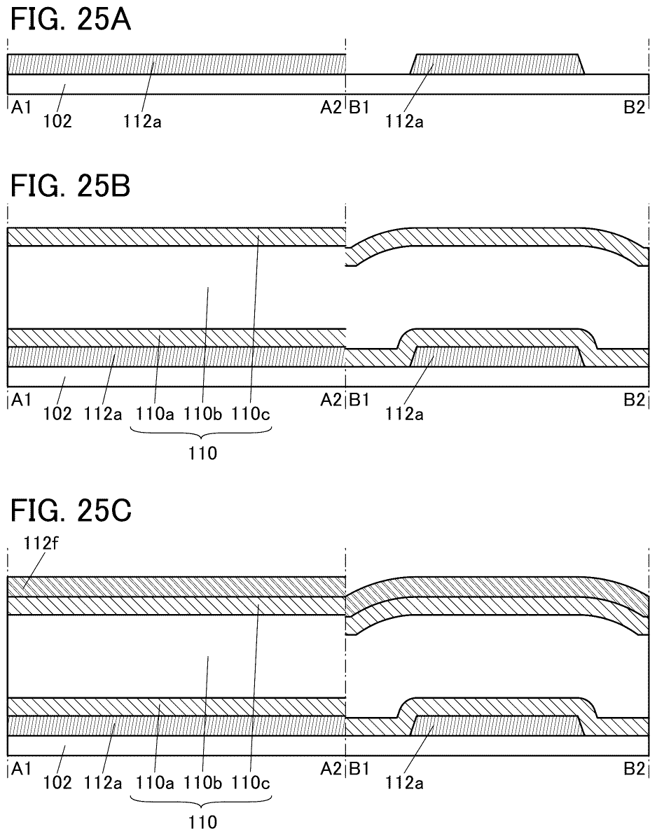

An example of a method for manufacturing the semiconductor device illustrated in FIG. 1B and FIG. 1C is described here with reference to FIG. 25A to FIG. 29B. FIG. 25A to FIG. 29B each illustrate a cross-sectional view taken along the dashed-dotted line A1-A2 in FIG. 1B and a cross-sectional view taken along the dashed-dotted line B1-B2 in FIG. 1C side by side.

First, the conductive layer 112a is formed over the substrate 102 (FIG. 25A). For example, a conductive film to be the conductive layer 112a is formed over the substrate 102 and processed, whereby the conductive layer 112a can be formed. The conductive film to be the conductive layer 112a can be formed by a sputtering method, for example. After a resist mask is formed over the conductive film by a photolithography step, the metal film is processed using one or both of a wet etching method and a dry etching method, for example, whereby the conductive layer 112a can be formed. The conductive layer 112a can be formed using a conductive oxide such as In—Sn oxide, a metal element such as titanium, or an alloy containing a plurality of kinds of metal elements, for example.

For example, in the case where the conductive layer 112a illustrated in FIG. 6B and FIG. 7A is formed, first, a conductive film to be the conductive layer 112a1 is formed over the substrate 102 and processed, whereby the conductive layer 112a1 is formed. Next, a conductive film to be the conductive layer 112a2 is formed over the conductive layer 112a1 and the substrate 102 and processed, whereby the conductive layer 112a2 is formed. Through the above steps, the conductive layer 112a1 and the conductive layer 112a2 covering the conductive layer 112a1 can be formed. In the case where the conductive layer 112a illustrated in FIG. 7B1 and FIG. 7B2 is formed, the conductive film to be the conductive layer 112a1 and the conductive film to be the conductive layer 112a2 are formed in this order over the substrate 102 and processed, whereby the conductive layer 112a2 and the conductive layer 112a1 can be formed. The conductive layer 112a1 can be formed using a conductive oxide, for example. The conductive layer 112a2 can be formed using a metal element such as titanium or an alloy containing a plurality of kinds of metal elements.

Next, the insulating layer 110 is formed over the conductive layer 112a and the substrate 102. As the insulating layer 110, the insulating layer 110a, the insulating layer 110b over the insulating layer 110a, and the insulating layer 110c over the insulating layer 110b are formed in this order, for example (FIG. 25B).

The insulating layer 110a, the insulating layer 110b, and the insulating layer 110c can be formed by a PECVD method or a sputtering method, for example. The insulating layer 110a, the insulating layer 110b, and the insulating layer 110c are preferably formed successively in a vacuum, for example, in which case impurities derived from the air can be inhibited from attaching to the surface of the insulating layer 110a and the surface of the insulating layer 110b. Examples of the impurities include water and organic substances.

The insulating layer 110a and the insulating layer 110c can be formed in a hydrogen-containing atmosphere. For example, in the case where an insulating film containing nitrogen is formed as each of the insulating layer 110a and the insulating layer 110c, the insulating layer 110a and the insulating layer 110c can be formed in a hydrogen-containing atmosphere. For example, a PECVD method using ammonia as a nitrogen source is used, whereby the insulating layer 110a and the insulating layer 110c can be formed in a hydrogen-containing atmosphere. Through the above steps, the insulating layer 110a and the insulating layer 110c can contain hydrogen. Accordingly, the source region and the drain region of the semiconductor layer 108 that is formed in a later step can have reduced resistance. Thus, the transistor having low on-state resistance can be formed.

The insulating layer 110b is preferably formed by a method that does not use a hydrogen-containing gas. For example, in the case where an oxide insulating film is formed as the insulating layer 110b by a PECVD method, the insulating layer 110b can be formed without using a hydrogen-containing gas. Thus, a film with an extremely low hydrogen content can be formed as the insulating layer 110b. This can inhibit supply of hydrogen to the channel formation region of the semiconductor layer 108 that is formed in a later step. Consequently, the transistor can be manufactured to have favorable electrical characteristics and high reliability. Note that even in the case where an oxide insulating film is formed as the insulating layer 110b by a sputtering method, the insulating layer 110b can be formed without using a hydrogen-containing gas.

As described above, when the insulating layer 110a and the insulating layer 110c are formed in a hydrogen-containing atmosphere and the insulating layer 110b is formed by a method that does not use a hydrogen-containing gas, the source region and the drain region can have reduced resistance and the channel formation region can be inhibited from being supplied with hydrogen in the semiconductor layer 108 that is formed in a later step.

The substrate temperature at the time of forming the insulating layer 110a, the insulating layer 110b, and the insulating layer 110c is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. When the substrate temperature at the time of forming the insulating layer 110a, the insulating layer 110b, and the insulating layer 110c is in the above range, impurities (e.g., water and hydrogen) released from the insulating layer 110a, the insulating layer 110b, and the insulating layer 110c themselves can be reduced, which can inhibit diffusion of the impurities to the semiconductor layer 108 that is formed in a later step. Consequently, the transistor included in the semiconductor device of one embodiment of the present invention can be manufactured to have favorable electrical characteristics and high reliability.

Note that since the insulating layer 110a, the insulating layer 110b, and the insulating layer 110c are formed earlier than the semiconductor layer 108, there is no need to consider the probability of oxygen release from the semiconductor layer 108 due to heat applied thereto at the time of forming the insulating layer 110a, the insulating layer 110b, and the insulating layer 110c.

After the formation of the insulating layer 110b and before the formation of the insulating layer 110c, oxygen may be supplied to the insulating layer 110b. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is brought into a plasma state by high-frequency power include a PECVD apparatus, a plasma etching apparatus, and a plasma ashing apparatus. The plasma treatment is preferably performed in an atmosphere containing oxygen. For example, the plasma treatment is preferably performed in an atmosphere containing one or more of oxygen, dinitrogen monoxide (N₂O), nitrogen dioxide (NO₂), carbon monoxide, and carbon dioxide.

After the formation of the insulating layer 110b, the plasma treatment may be performed without exposure of the surface of the insulating layer 110b to the air. For example, in the case where a PECVD apparatus is used to form the insulating layer 110b, the plasma treatment is preferably performed with the PECVD apparatus. Accordingly, the productivity can be increased. Specifically, after the insulating layer 110b is formed with the PECVD apparatus, N₂O plasma treatment can be successively performed.

When a film of an insulating film, a semiconductor film, a conductive film, or the like is formed over the insulating layer 110b in an oxygen-containing atmosphere, oxygen can be supplied to the insulating layer 110b. For the film, aluminum oxide, hafnium oxide, hafnium aluminate, indium oxide, indium tin oxide (ITO), or indium tin oxide containing silicon (ITSO) can be used, for example.

An oxide material containing one or more elements contained in the semiconductor layer 108 is preferably used for the film. It is particularly preferable to use an oxide semiconductor material that can be used for the semiconductor layer 108.

At the time of forming the film, the amount of oxygen supplied into the insulating layer 110b can be increased with a higher oxygen flow rate ratio of the film formation gas introduced into a treatment chamber of a film formation apparatus or with a higher oxygen partial pressure in the treatment chamber. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, further preferably higher than or equal to 90% and lower than or equal to 100%. It is particularly preferable that the oxygen flow rate ratio be 100% and the oxygen partial pressure be as close to 100% as possible.

When the film is formed by a sputtering method in an oxygen-containing atmosphere in the above manner, oxygen can be supplied to the insulating layer 110b and release of oxygen from the insulating layer 110b can be prevented during the formation of the film. As a result, a large amount of oxygen can be enclosed in the insulating layer 110b. Moreover, a large amount of oxygen can be supplied to the semiconductor layer 108 by heat treatment performed later. Thus, the amounts of oxygen vacancies and VoH in the semiconductor layer 108 can be reduced, whereby the transistor can have favorable electrical characteristics and high reliability.

Heat treatment may be performed after the film is formed. By the heat treatment performed after the formation of the film, oxygen can be effectively supplied from the film to the insulating layer 110b.

The temperature of the heat treatment is preferably higher than or equal to 150° C. and lower than the strain point of the substrate, further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of each of hydrogen, water, and the like in the atmosphere is preferably as low as possible. As the atmosphere, a high-purity gas with a dew point lower than or equal to −60° C. is preferably used, and a high-purity gas with a dew point lower than or equal to −100° C. is further preferably used. With use of an atmosphere where the content of each of hydrogen, water, and the like is as low as possible, entry of hydrogen, water, and the like into the insulating layer 110a and the insulating layer 110b can be prevented as much as possible. An oven, a rapid thermal annealing (RTA) apparatus, or the like can be used for the heat treatment. With the RTA apparatus, the heat treatment time can be shortened.

After the formation of the film or the above-described heat treatment, oxygen may be further supplied to the insulating layer 110b through the film. Oxygen can be supplied by, for example, an ion implantation method, an ion doping method, a plasma immersion ion implantation method, or plasma treatment. The above description can be referred to for the plasma treatment; thus, the detailed description thereof is omitted.

Next, the film is removed. There is no particular limitation on a method for removing the film, and a wet etching method can be suitably used. When a wet etching method is used, the insulating layer 110b can be inhibited from being etched at the time of the removal of the film. In that case, a reduction in the thickness of the insulating layer 110b can be inhibited and the thickness of the insulating layer 110b can be uniform.

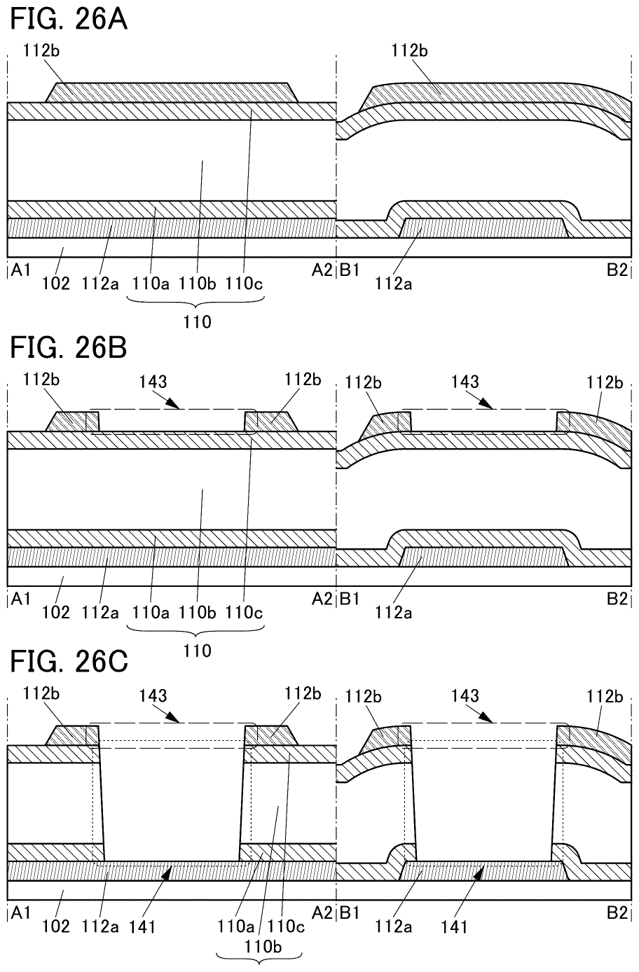

Next, a conductive film 112f to be the conductive layer 112b is formed over the insulating layer 110 (FIG. 25C). For example, the conductive film 112f is formed to include a region in contact with the top surface of the insulating layer 110c. For the formation of the conductive film 112f, for example, a sputtering method can be used. Then, the conductive film 112f is processed into a desired shape, so that the conductive layer 112b is formed over the insulating layer 110 (FIG. 26A). For example, the conductive layer 112b is formed to include a region in contact with the top surface of the insulating layer 110c. For the conductive layer 112b, a conductive oxide such as In—Sn oxide is preferably used, for example. In the case where the conductive layer 112b has a stacked-layer structure of two or more layers, a conductive oxide such as In—Sn oxide is preferably used for the uppermost layer in contact with the semiconductor layer 108 that is formed in a later step.

Then, the conductive layer 112b is processed to form the opening portion 143 (FIG. 26B). The opening portion 143 is formed to include a region overlapping with the conductive layer 112a. Note that the conductive layer 112b provided with the opening portion 143 may be formed in the following manner: the opening portion 143 is formed in the conductive film 112f, and then, the conductive film 112f is processed into a desired shape. That is, the steps illustrated in FIG. 26A and FIG. 26B may be interchanged with each other.

Next, the insulating layer 110 is processed to form the opening portion 141 (FIG. 26C). The opening portion 141 is formed to include a region overlapping with the opening portion 143 and to reach the conductive layer 112a. The formation of the opening portion 141 exposes the region of the conductive layer 112a that overlaps with the opening portion 141 and the opening portion 143.

For the formation of the opening portion 143 and the opening portion 141, one or both of a wet etching method and a dry etching method can be used. For the formation of the opening portion 143, a wet etching method can be suitably used, for example. For the formation of the opening portion 141, a dry etching method can be suitably used, for example. Note that a wet etching method can be a processing method with higher isotropy than a dry etching method. Thus, when the opening portion 143 and the opening portion 141 are formed by a wet etching method and a dry etching method, respectively, the end portion of the bottom surface of the conductive layer 112b on the opening portion 143 side is not aligned with the portion 123 in some cases, as illustrated in FIG. 10A and FIG. 10B. For example, the insulating layer 110 includes a region projecting from the conductive layer 112b into the opening portion 141 side in a cross-sectional view.

The opening portion 141 can be formed using, for example, the resist mask used for the formation of the opening portion 143. For example, after the conductive layer 112b is formed, a resist mask is formed over the conductive layer 112b. Then, the conductive layer 112b is partly removed using the resist mask to form the opening portion 143. Then, the insulating layer 110 is partly removed using the resist mask, so that the opening portion 141 can be formed. The opening portion 141 and the opening portion 143 may be formed using different resist masks.

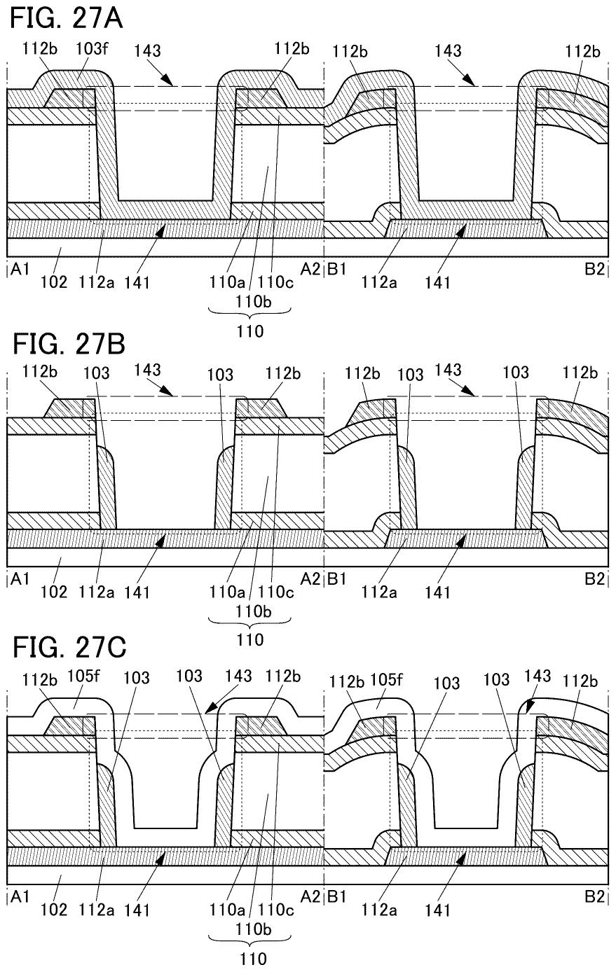

Subsequently, a conductive film 103f to be the conductive layer 103 is formed to cover the opening portion 141 and the opening portion 143 (FIG. 27A). The conductive film 103f is formed over the insulating layer 110 to cover the side surface of the insulating layer 110 that is positioned in the opening portion 141 and the top surface of the conductive layer 112a exposed by the opening portion 141. The conductive film 103f can be formed to include a region in contact with the top surface of the conductive layer 112a, a region in contact with the side surface of the insulating layer 110, a region in contact with the side surface of the conductive layer 112b, a region in contact with the top surface of the conductive layer 112b, and a region in contact with the top surface of the insulating layer 110. The conductive film 103f can be formed by a sputtering method, a thermal CVD method (including an MOCVD method), or an ALD method, for example.

Next, anisotropic etching is performed on the conductive film 103f. Thus, the conductive layer 103 is formed in the opening portion 141 to be electrically connected to the conductive layer 112a (FIG. 27B). Specifically, the conductive layer 103 is formed, along the side surface of the insulating layer 110 that is positioned in the opening portion 141, to include a region in contact with the conductive layer 112a in the opening portion 141. The conductive layer 103 can be formed to include a region in contact with the side surface of the insulating layer 110 that is positioned in the opening portion 141.

It is preferable to perform anisotropic etching on the conductive film 103f such that the uppermost portion of the conductive layer 103 is positioned below the end portion of the top surface of the insulating layer 110 on the opening portion 141 side. In other words, it is preferable to perform anisotropic etching on the conductive film 103f such that the conductive layer 103 is not provided in the opening portion 143. For example, it is preferable that the rate and time of the anisotropic etching be adjusted so that the conductive layer 103 is provided in the opening portion 141 and not provided in the opening portion 143. This can prevent a short circuit due to contact between the conductive layer 103 and the conductive layer 112b, for example.

Anisotropic etching on the conductive film 103f is preferably performed under the condition where the selectivity with respect to the conductive layer 112a and the conductive layer 112b is high. That is, the anisotropic etching is preferably performed under the condition where the etching rate of the conductive film 103f is higher than those of the conductive layer 112a and the conductive layer 112b. This can inhibit unintentional etching of the conductive layer 112a and the conductive layer 112b in the anisotropic etching on the conductive film 103f. Accordingly, the manufacturing yield of the semiconductor device can be increased. Moreover, a highly reliable semiconductor device can be manufactured.

The conductive film 103f is preferably formed using a metal element such as titanium or an alloy containing a plurality of kinds of metal elements. Thus, the conductive layer 103 with low electrical resistance can be formed, for example. When a metal such as titanium is used for the conductive film 103f and a conductive oxide such as In—Sn oxide is used for the conductive layer 112a and the conductive layer 112b, the etching selectivity of the conductive film 103f with respect to the conductive layer 112a and the conductive layer 112b can be increased.

Here, the depressed portion 129 illustrated in FIG. 5, for example, is formed in the conductive layer 112a in some cases because of the anisotropic etching on the conductive film 103f. For example, when the etching selectivity of the conductive film 103f with respect to the conductive layer 112a is lower than the etching selectivity of the conductive film 103f with respect to the conductive layer 112b, the depressed portion 129 is formed in some cases.

In the case where the conductive layer 112a has the structure illustrated in each of FIG. 6B to FIG. 7B2, for example, the conductive layer 112a1 is formed using a material whose etching selectivity with respect to the conductive film 103f is higher than that of the conductive layer 112a2, whereby the conductive layer 112a1 can be inhibited from being processed when the depressed portion 129 is formed in the conductive layer 112a. Thus, the conductive layer 112a can be prevented from being completely removed in a region overlapping with the opening portion 141 and not overlapping with the conductive layer 103. This can prevent the case where the bottom surface of the semiconductor layer 108 that is formed in a later step is not in contact with the conductive layer 112a.

The conductive layer 112a2 is formed using a material whose etching selectivity with respect to the conductive film 103f is lower than that of the conductive layer 112a1, whereby the depressed portion 129 can be easily formed in the conductive layer 112a. Thus, a transistor having a high on-state current can be easily formed as described above.

As described above, a conductive oxide can be used for the conductive layer 112a1, for example. For the conductive layer 112a2, a material similar to the material that can be used for the conductive film 103 is preferably used, for example. For example, the conductive layer 112a2 and the conductive film 103f can be formed using materials similar to each other.

In the case where the conductive layer 103 is formed by performing anisotropic etching on the conductive film 103f, unlike in the case where the conductive layer 103 is formed by processing the conductive film 103f after patterning by photolithography, a mask is not needed, for example. Thus, in the method for manufacturing the semiconductor device of one embodiment of the present invention, the conductive layer 103 can be formed regardless of the alignment accuracy of a mask, for example. This can prevent, even when the opening portion 141 in which the conductive layer 103 is formed is miniaturized, the case where the conductive layer 103 is not formed in the opening portion 141, for example. Thus, in the method for manufacturing the semiconductor device of one embodiment of the present invention, the transistor having a minute size can be manufactured.

Subsequently, an insulating film 105f is formed to cover the conductive layer 103 and the conductive layer 112b (FIG. 27C). The insulating film 105f can be formed to include a region in contact with the top surface of the conductive layer 112a, a region in contact with the conductive layer 103, a region in contact with the side surface of the insulating layer 110, a region in contact with the top surface of the insulating layer 110, a region in contact with the side surface of the conductive layer 112b, and a region in contact with the top surface of the conductive layer 112b. The insulating film 105f can be formed by a PECVD method or an ALD method, for example.

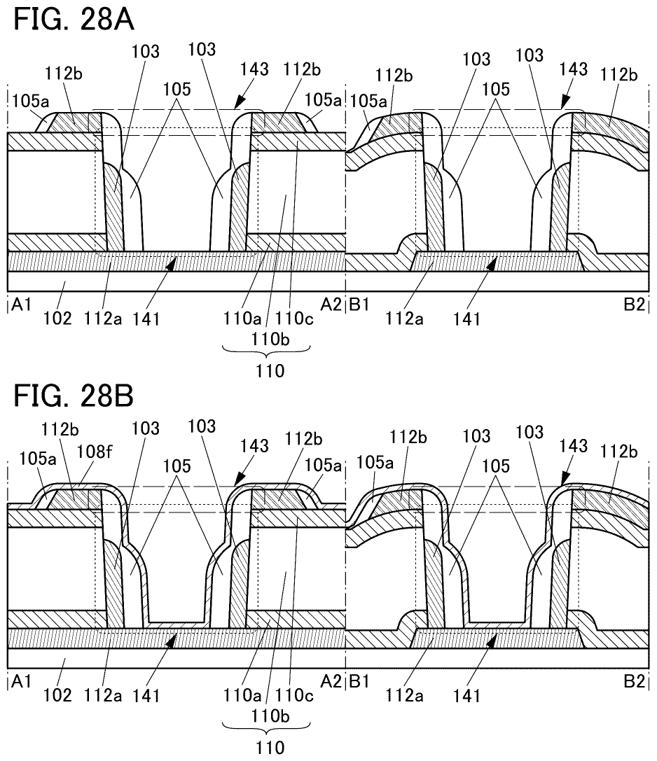

Next, anisotropic etching is performed on the insulating film 105f. For example, the anisotropic etching is performed on the insulating film 105f until at least part of the top surface of the conductive layer 112b is exposed. By performing the anisotropic etching on the insulating film 105f, the insulating layer 105 is formed to cover the conductive layer 103 (FIG. 28A). The insulating layer 105 can be formed to include a region in contact with the conductive layer 103 and a region in contact with the conductive layer 112a in the opening portion 141. The insulating layer 105 can be formed to include a region in contact with the side surface of the conductive layer 112b in the opening portion 143.

The uppermost portion of the insulating layer 105 can be aligned or substantially aligned with the top surface of the conductive layer 112b. As illustrated in FIG. 4A, the uppermost portion of the insulating layer 105 and the uppermost portion of the insulating layer 105a are positioned between the bottom surface and the top surface of the conductive layer 112b in some cases. Furthermore, as illustrated in FIG. 4B, the uppermost portion of the insulating layer 105 is positioned below the bottom surface of the conductive layer 112b in some cases. The position of the uppermost portion of the insulating layer 105 can be changed depending on the rate and time of the anisotropic etching, for example.

By performing the anisotropic etching on the insulating film 105f, the insulating layer 105a is sometimes formed to cover the side surface of the conductive layer 112b, specifically, at least part of the side surface of the conductive layer 112b on the side opposite to the opening portion 143. The insulating layer 105a is formed as a residue in forming the insulating layer 105.

The insulating layer 105a can be formed to include a region in contact with the side surface of the conductive layer 112b on the side opposite to the opening portion 143. For example, in the case where anisotropic etching is performed on the insulating film 105f such that the uppermost portion of the insulating layer 105 is positioned above the top surface of the insulating layer 110, e.g., the end portion of the top surface of the insulating layer 110 on the opening portion 141 side, the insulating layer 105a is sometimes formed. For example, in the case where the insulating layer 105 is formed to include a region in contact with the side surface of the conductive layer 112b that is positioned in the opening portion 143, the insulating layer 105a is sometimes formed. Note that the insulating layer 105a is sometimes not formed. In the case where the insulating layer 105 is formed such that the uppermost portion is aligned with the top surface of the insulating layer 110, e.g., the end portion of the top surface of the insulating layer 110 on the opening portion 141 side, or is positioned below the top surface of the insulating layer 110, the insulating layer 105a is sometimes not formed. Even in the case where the insulating layer 105 is formed such that the uppermost portion is positioned above the top surface of the insulating layer 110, e.g., the end portion of the top surface of the insulating layer 110 on the opening portion 141 side, the insulating layer 105a is sometimes not formed.

Performing anisotropic etching on the insulating film 105f so as to form the insulating layer 105a can prevent the conductive layer 103 from being exposed. For example, with a lowered anisotropic etching rate, the insulating layer 105 can be formed such that conductive layer 103 is prevented from being exposed. This can prevent a short circuit due to contact between the semiconductor layer 108 that is formed in a later step and the conductive layer 103. Accordingly, the manufacturing yield of the semiconductor device of one embodiment of the present invention can be increased. On the other hand, since throughput decreases as the anisotropic etching rate with respect to the insulating film 105f is lowered, the anisotropic etching rate is preferably adjusted in consideration of the throughput and the manufacturing yield of the semiconductor device.

Here, the insulating layer 110 is sometimes partly processed because of the anisotropic etching on the insulating film 105f. In this case, the thickness of the insulating layer 110 in a region overlapping with neither the conductive layer 112b nor the insulating layer 105a is sometimes smaller than the thickness of the insulating layer 110 in a region overlapping with the conductive layer 112b or the insulating layer 105a. That is, a depressed portion is sometimes formed in the region of the insulating layer 110 overlapping with neither the conductive layer 112b nor the insulating layer 105a. For example, in the case where the etching selectivity between the insulating film 105f and the insulating layer 110c is low, the depressed portion is sometimes formed in the insulating layer 110. Note that in the case where the insulating layer 110 has a stacked-layer structure of three layers of the insulating layer 110a, the insulating layer 110b, and the insulating layer 110c, for example, when the etching selectivity between the insulating film 105f and the insulating layer 110c is high, formation of the depressed portion in the insulating layer 110 can be inhibited even when the etching selectivity between the insulating film 105f and the insulating layer 110b is low. For the insulating film 105f, a material similar to that for the insulating layer 110b can be used, for example.

One or both of the conductive layer 112a and the conductive layer 112b are sometimes partly processed because of the anisotropic etching on the insulating film 105f. When the conductive layer 112a is partly processed, a depressed portion is sometimes formed in the region of the conductive layer 112a that overlaps with the opening portion 141 and does not overlap with the conductive layer 103. For example, in the case where the etching selectivity between the insulating film 105f and the conductive layer 112a is low, the depressed portion is sometimes formed in the conductive layer 112a. When the conductive layer 112b is partly processed, the thickness of the conductive layer 112b is sometimes reduced. Specifically, the thickness of the conductive layer 112b after the formation of the insulating layer 105 is sometimes smaller than the thickness of the conductive layer 112b before the formation of the insulating layer 105. For example, when the etching selectivity between the insulating film 105f and the conductive layer 112b is low, the thickness of the conductive layer 112b is sometimes reduced.

Subsequently, a semiconductor film 108f to be the semiconductor layer 108 is formed to cover the opening portion 141 and the opening portion 143 (FIG. 28B). The semiconductor film 108f is formed to include a region in contact with the top surface of the conductive layer 112a, a region in contact with the insulating layer 105, a region in contact with the insulating layer 105a, a region in contact with the top surface of the conductive layer 112b, and a region in contact with the top surface of the insulating layer 110.

The semiconductor film 108f is preferably formed by an ALD method. As described above, an ALD method is a film formation method in which a film is formed by a reaction at a surface of an object. Thus, when the semiconductor film 108f is formed by an ALD method, damage to the semiconductor film 108f can be reduced.

Damage to the semiconductor film 108f might generate oxygen vacancies in the semiconductor film 108f, for example. For repairing oxygen vacancies, a method of supplying oxygen to the semiconductor layer 108 including oxygen vacancies can be used. For example, one or both of the insulating layer 105 and the insulating layer 106 that is formed in a later step is made to contain excess oxygen and is subjected to heat treatment or the like, whereby oxygen can be supplied to the semiconductor layer 108. However, when the insulating layer 105 contains excess oxygen, the conductive layer 103, the conductive layer 112a, and the conductive layer 112b might be oxidized and have increased electrical resistance. When the insulating layer 106 contains excess oxygen, the conductive layer 104 and the conductive layer 112b might be oxidized and have increased electrical resistance.

In this specification and the like, excess oxygen refers to oxygen that exists in a layer and is not bonded to (is free from) the layer or oxygen with low bonding energy with the layer.

Thus, when the semiconductor film 108f is formed by a film formation method that causes less damage, such as an ALD method, generation of oxygen vacancies can be inhibited as compared with the case where the semiconductor film 108f is formed by a film formation method that causes great damage. This eliminates the need for the treatment for repairing oxygen vacancies in the semiconductor layer 108. Accordingly, it is possible to inhibit both generation of oxygen vacancies in the semiconductor layer 108 and oxidation of the conductive layer included in the transistor of one embodiment of the present invention. Thus, a highly reliable semiconductor device can be manufactured.

In the case of employing an ALD method to form the semiconductor film 108f, a film formation method such as a thermal ALD method or PEALD (Plasma Enhanced ALD) is preferably employed. A thermal ALD method is preferable because it offers extremely high step coverage. A PEALD method is preferable because it can form a film at low temperatures in addition to offering high step coverage.

The semiconductor film 108f can be formed by an ALD method using an oxidizing agent and a precursor that contains a metal element to constitute the semiconductor film 108f, for example.

Examples of a precursor containing indium include trimethylindium, triethylindium, tris(2,2,6,6-tetramethyl-3,5-heptanedionato)indium, cyclopentadienylindium, indium(III) chloride, and (3-(dimethylamino)propyl)dimethylindium.

Examples of the precursor containing gallium include trimethylgallium, triethylgallium, tris(dimethylamido)gallium, gallium(III) acetylacetonate, tris(2,2,6,6-tetramethyl-3,5-heptanedionato)gallium, dimethylchlorogallium, diethylchlorogallium, and gallium(III) chloride.

Examples of a precursor containing tin include tetramethyltin, tetraethyltin, tetraethenyltin, tetraallyltin, tributylvinyltin, allyltributyltin, tributylstannylacetylene, tributylphenyltin, chlorotrimethyltin, chlorotriethyltin, and tin(IV) chloride.

Examples of a precursor containing zinc include dimethylzinc, diethylzinc, bis(2,2,6,6-tetramethyl-3,5-heptanedionato)zinc, and zinc chloride.

In the case of forming an In—Ga—Zn oxide, for example, three precursors of a precursor containing indium, a precursor containing gallium, and a precursor containing zinc can be used. Alternatively, two precursors of a precursor containing indium and a precursor containing gallium and zinc may be used.

Examples of the oxidizing agent include ozone, oxygen, and water.

As an example of a method for controlling the composition of a film to be formed, adjusting the flow rate ratio between the source gases, the flowing time of the source gases, the order in which the source gases flow, or the like is given. By adjusting such conditions, a film whose composition is continuously changed can be formed. Furthermore, films having different compositions can be formed successively.

Note that the semiconductor film 108f may be formed by a film formation method other than an ALD method. For example, the semiconductor film 108f may be formed by a sputtering method. In the case where the semiconductor film 108f has a stacked-layer structure of two or more layers, all the layers may be formed by the same film formation method or the layers may be formed by different film formation methods. For example, in the case where the semiconductor film 108f has a stacked-layer structure of two layers, one layer may be formed by an ALD method and the other layer may be formed by a sputtering method. Here, in the case where the semiconductor film 108f is formed by a film formation method other than an ALD method, oxygen is preferably supplied to the insulating layer 110b by the above-described method after the formation of the insulating layer 110b and before the formation of the insulating layer 110c. Accordingly, oxygen vacancies in the semiconductor film 108f can be repaired.

Before the formation of the semiconductor film 108f, at least one of treatment for desorbing water, hydrogen, an organic substance, and the like adsorbed on the surface of the insulating layer 110, and treatment for supplying oxygen into the insulating layer 110 is preferably performed. For example, heat treatment can be performed at a temperature higher than or equal to 70° C. and lower than or equal to 200° C. in a reduced-pressure atmosphere. Alternatively, plasma treatment in an oxygen-containing atmosphere may be performed. Alternatively, oxygen may be supplied to the insulating layer 110 by performing plasma treatment in an atmosphere containing an oxidizing gas such as dinitrogen monoxide (N₂O). When plasma treatment is performed using a dinitrogen monoxide gas, an organic substance on the surface of the insulating layer 110 can be favorably removed and oxygen can be supplied to the insulating layer 110. The semiconductor film 108f is preferably formed successively after such treatment without exposure of the surface of the insulating layer 110 to the air.

In the case where the semiconductor layer 108 has a stacked-layer structure, it is preferable that after the metal oxide film formed earlier is formed, the next metal oxide film be formed successively without exposure of the surface of the metal oxide film formed earlier to the air.

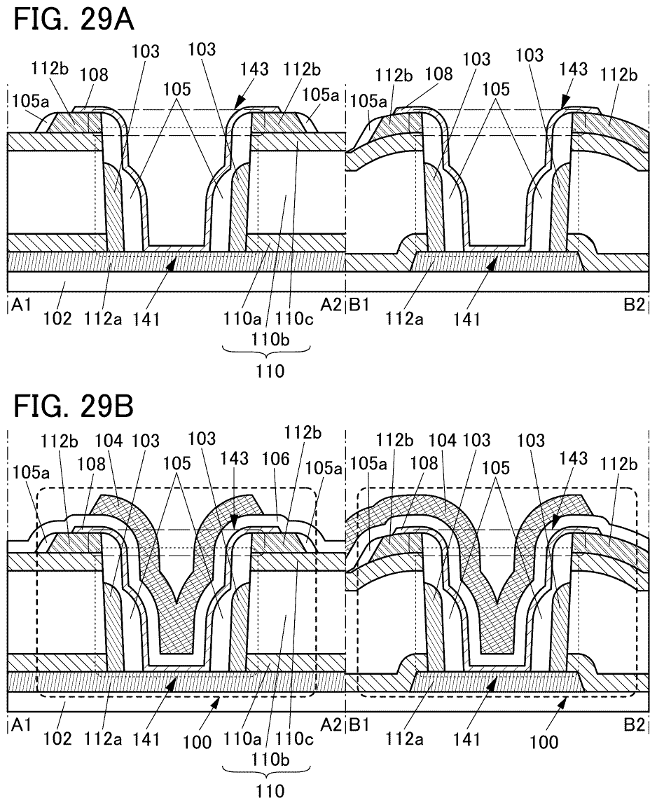

Next, the semiconductor film 108f is processed into an island shape to form the semiconductor layer 108 (FIG. 29A). The semiconductor layer 108 can be formed to include a region positioned in the opening portion 141 and a region positioned in the opening portion 143. The semiconductor layer 108 can be formed to include a region in contact with the top surface of the conductive layer 112a, a region in contact with the insulating layer 105, and a region in contact with the top surface of the conductive layer 112b.

For the formation of the semiconductor layer 108, one or both of a wet etching method and a dry etching method can be used, and for example, a wet etching method can be suitably used. At this time, part of the conductive layer 112b in the region not overlapping with the semiconductor layer 108 is etched and thinned in some cases. In addition, part of the insulating layer 105a is etched and thinned in some cases. Furthermore, part of the insulating layer 110 in a region overlapping with neither the semiconductor layer 108, the conductive layer 112b, nor the insulating layer 105a is etched and thinned in some cases.

It is preferable that heat treatment be performed after the semiconductor film 108f is formed or after the semiconductor film 108f is processed into the semiconductor layer 108. By the heat treatment, hydrogen or water contained in the semiconductor film 108f or the semiconductor layer 108 or adsorbed on the surface of the semiconductor film 108f or the semiconductor layer 108 can be removed. Furthermore, the film quality of the semiconductor film 108f or the semiconductor layer 108 is improved (e.g., the number of defects is reduced or the crystallinity is increased) by the heat treatment in some cases. It is further preferable that the heat treatment be performed before the semiconductor film 108f is processed into the semiconductor layer 108.

The temperature of the heat treatment is preferably higher than or equal to 150° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., and is typically 350° C. For the other heat treatment conditions, the description of the heat treatment after the formation of a metal oxide layer 149 can be referred to.

Note that the heat treatment is not necessarily performed when not needed. The heat treatment is not necessarily performed in this step, and heat treatment performed in a later step may also serve as the heat treatment in this step. In some cases, treatment at high temperatures (e.g., a film formation step) in a later step serves as the heat treatment in this step.

Then, the insulating layer 106 is formed to cover the semiconductor layer 108, the conductive layer 112b, the insulating layer 105a, and the insulating layer 110 (FIG. 29B). The insulating layer 106 can be formed over the semiconductor layer 108 to include a region positioned in the opening portion 141 and a region positioned in the opening portion 143. The insulating layer 106 can be formed along the side wall of the opening portion 141 and the side wall of the opening portion 143 with the semiconductor layer 108 between the insulating layer 106 and the side walls. For the formation of the insulating layer 106, for example, a PECVD method or an ALD method can be used.

In the case where the semiconductor layer 108 is a metal oxide layer, the insulating layer 106 preferably functions as a barrier film that inhibits diffusion of oxygen. The insulating layer 106 having a function of inhibiting diffusion of oxygen inhibits diffusion of oxygen to the conductive layer 104 from above the insulating layer 106 and thus can inhibit oxidation of the conductive layer 104. Consequently, the transistor can have favorable electrical characteristics and high reliability.

Note that in this specification and the like, a barrier film refers to a film having a barrier property. For example, an insulating layer having a barrier property can be referred to as a barrier insulating layer. In this specification and the like, a barrier property means one or both of a function of inhibiting diffusion of a particular substance (or low permeability) and a function of capturing or fixing (also referred to as gettering) a particular substance.

When the temperature at the time of forming the insulating layer 106 functioning as the gate insulating layer is increased, defects in the insulating layer 106 can be reduced. However, a high temperature at the time of forming the insulating layer 106 sometimes allows release of oxygen from the semiconductor layer 108, which increases the amounts of oxygen vacancies and VoH in the semiconductor layer 108. The substrate temperature at the time of forming the insulating layer 106 is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C. When the substrate temperature at the time of forming the insulating layer 106 is in the above range, release of oxygen from the semiconductor layer 108 can be inhibited while the defects in the insulating layer 106 can be reduced. Consequently, the transistor can be manufactured to have favorable electrical characteristics and high reliability.

Before the formation of the insulating layer 106, the surface of the semiconductor layer 108 may be subjected to plasma treatment. By the plasma treatment, impurities such as water adsorbed on the surface of the semiconductor layer 108 can be reduced. Accordingly, impurities at the interface between the semiconductor layer 108 and the insulating layer 106 can be reduced, enabling formation of a highly reliable transistor. The plasma treatment is particularly favorable in the case where the surface of the semiconductor layer 108 is exposed to the air after the formation of the semiconductor layer 108 but before the formation of the insulating layer 106. The plasma treatment can be performed in an atmosphere of oxygen, ozone, nitrogen, dinitrogen monoxide, argon, or the like. The plasma treatment and the formation of the insulating layer 106 are preferably performed successively without exposure to the air.

Then, the conductive layer 104 is formed over the insulating layer 106. Thus, the transistor 100 is formed (FIG. 29B). The conductive layer 104 can be formed to include a region positioned in the opening portion 141, a region positioned in the opening portion 143, and a region facing the semiconductor layer 108 with the insulating layer 106 between the region and the semiconductor layer 108.

For example, a conductive film to be the conductive layer 104 is formed over the insulating layer 106 and processed, whereby the conductive layer 104 can be formed. For the formation of the conductive film to be the conductive layer 104, a sputtering method, a thermal CVD method (including an MOCVD method), or an ALD method is suitable, for example. A resist mask is formed over the conductive film by a photolithography step and then, the conductive film is processed, whereby the conductive layer 104 with an island shape, which functions as the gate electrode, can be formed.

Next, the insulating layer 107 is formed to cover the conductive layer 104 and the insulating layer 106 (FIG. 1B and FIG. 1C). The insulating layer 107 can be formed by a CVD method, for example, or specifically, a PECVD method. Note that the insulating layer 107 can also be formed by a sputtering method, for example.

Through the above steps, the semiconductor device illustrated in FIG. 1B and FIG. 1C can be manufactured.

In the above method for manufacturing the semiconductor device, the conductive layer 103 functioning as the back gate electrode of the transistor 100 and the insulating layer 105 functioning as the back gate insulating layer of the transistor 100 are formed by anisotropic etching without using a mask. Thus, in the method for manufacturing the semiconductor device of one embodiment of the present invention, the conductive layer 103 and the insulating layer 105 can be formed regardless of the alignment accuracy of a mask, for example. This can prevent, even when the opening portion 141 in which the conductive layer 103 and the insulating layer 105 are formed is miniaturized, the case where the conductive layer 103 and the insulating layer 105 are not formed in the opening portion 141, for example. Thus, in the method for manufacturing the semiconductor device of one embodiment of the present invention, the transistor having a minute size can be manufactured.

### <Manufacturing Method Example 2 of Semiconductor Device>

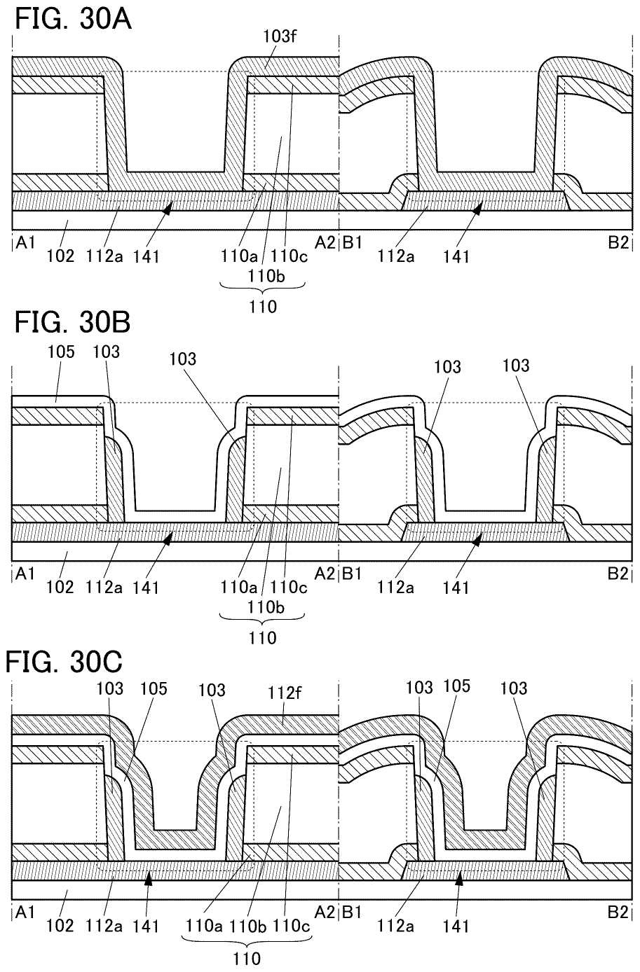

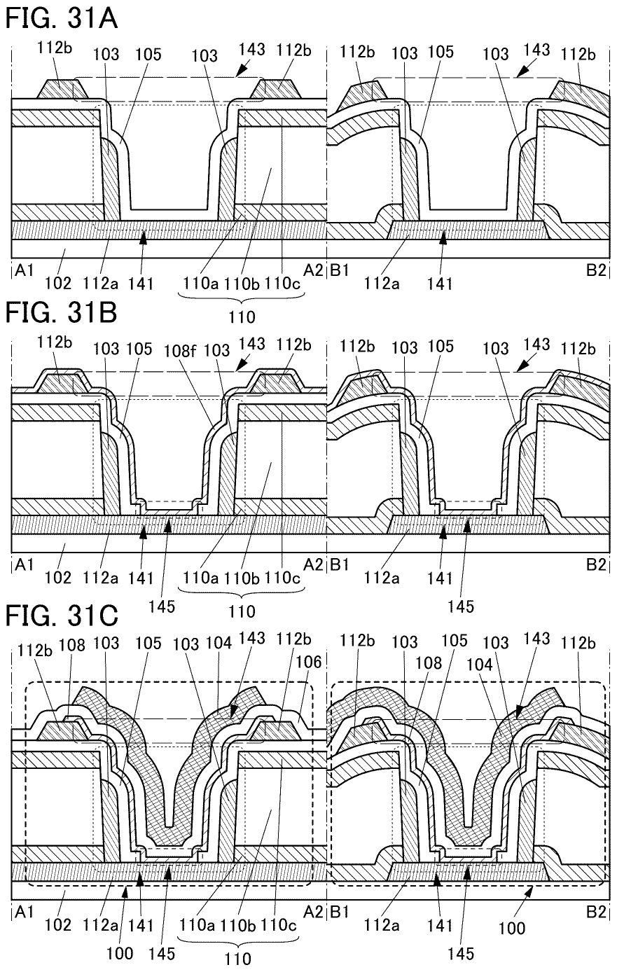

An example of a method for manufacturing the semiconductor device illustrated in FIG. 11B and FIG. 11C will be described below with reference to FIG. 30A to FIG. 31C. FIG. 30A to FIG. 31C each illustrate a cross-sectional view taken along the dashed-dotted line A1-A2 in FIG. 11B and a cross-sectional view taken along the dashed-dotted line B1-B2 in FIG. 11C side by side.

First, through steps similar to those illustrated in FIG. 25A and FIG. 25B, the conductive layer 112a and the insulating layer 110 are formed in this order over the substrate 102. Next, the opening portion 141 reaching the conductive layer 112a is formed in the insulating layer 110 (FIG. 30A). For example, a resist mask is formed over the insulating layer 110 and a portion of the insulating layer 110 that does not overlap with the resist mask is removed by an etching method, whereby the opening portion 141 can be formed. As described above, for the removal of the insulating layer 110, an etching method can be used; for example, a dry etching method can be suitably used.

Subsequently, through steps similar to those illustrated in FIG. 27A, the conductive film 103f is formed to cover the opening portion 141 (FIG. 30A). The conductive film 103f can be formed to include a region in contact with the top surface of the conductive layer 112a, a region in contact with the side surface of the insulating layer 110, and a region in contact with the top surface of the insulating layer 110.

Subsequently, through steps similar to those illustrated in FIG. 27B and FIG. 27C, the conductive layer 103 and the insulating layer 105 are formed in this order (FIG. 30B). Here, the insulating film 105f illustrated in FIG. 27C corresponds to the insulating layer 105 illustrated in FIG. 30B. The conductive layer 112b is not formed in this step.

Subsequently, through steps similar to those illustrated in FIG. 25C, the conductive film 112f is formed to cover the opening portion 141 (FIG. 30C). The conductive film 112f is formed over the insulating layer 105.

Next, the conductive film 112f is processed to form the conductive layer 112b including the opening portion 143 (FIG. 31A). The opening portion 143 is formed to include a region overlapping with the opening portion 141.

The conductive layer 112b including the opening portion 143 can be formed by a photolithography method and an etching method, for example. Specifically, a resist mask is formed over the conductive film 112f and a portion of the conductive film 112f that does not overlap with the resist mask is removed by an etching method, whereby the conductive layer 112b including the opening portion 143 can be formed. Here, the formation of the conductive layer 112b by processing the conductive film 112f and the formation of the opening portion 143 in the conductive layer 112b can be performed in the same step. That is, the formation of the conductive layer 112b and the formation of the opening portion 143 in the conductive layer 112b can be performed using the same resist mask. Note that the formation of the conductive layer 112b and the formation of the opening portion 143 in the conductive layer 112b may be performed in different steps. For example, after the formation of the conductive layer 112b is performed by forming a resist mask and processing the conductive film 112f using the resist mask, the resist mask is removed and then a resist mask is formed again. After that, the formation of the opening portion 143 can be performed by processing the conductive layer 112b using the resist mask. Note that after the formation of the opening portion 143 in the conductive film 112f, the conductive layer 112b may be formed by processing the conductive film 112f including the opening portion 143.

Next, the insulating layer 105 is processed to form the opening portion 145 (FIG. 31B). The opening portion 145 is formed to be positioned in the opening portion 141 and to reach the conductive layer 112a. The formation of the opening portion 145 exposes the region of the conductive layer 112a that overlaps with the opening portion 145.

The opening portion 145 can be formed by a photolithography method and an etching method, for example. Specifically, a resist mask is formed over the insulating layer 105 and a portion of the insulating layer 105 that does not overlap with the resist mask is removed by an etching method, whereby the opening portion 145 can be formed. In particular, using a dry etching method to remove the insulating layer 105 enables the miniaturization of the opening portion 145. This is preferable because a short circuit due to contact between the semiconductor layer 108 that is formed in a later step and the conductive layer 103 can be prevented.

Subsequently, through steps similar to those illustrated in FIG. 28B, the semiconductor film 108f is formed to cover the opening portion 141, the opening portion 143, and the opening portion 145 (FIG. 31B). The semiconductor film 108f is formed to include a region in contact with the top surface of the conductive layer 112a, a region in contact with the insulating layer 105, a region in contact with the side surface of the conductive layer 112b, a region in contact with the top surface of the conductive layer 112b, and a region in contact with the top surface of the insulating layer 110.

Subsequently, through steps similar to those illustrated in FIG. 29A and FIG. 29B, the semiconductor layer 108, the insulating layer 106, and the conductive layer 104 are formed in this order. Thus, the transistor 100 is formed (FIG. 31C). The semiconductor layer 108 can be formed to include a region positioned in the opening portion 141, a region positioned in the opening portion 143, and a region positioned in the opening portion 145. The semiconductor layer 108 can be formed to include a region in contact with the top surface of the conductive layer 112a, a region in contact with the insulating layer 105, a region in contact with the top surface of the conductive layer 112b, and a region in contact with the side surface of the conductive layer 112b.

Next, the insulating layer 107 is formed to cover the conductive layer 104 and the insulating layer 106 (FIG. 11B and FIG. 11C). As described above, the insulating layer 107 can be formed by a CVD method, for example, or specifically, a PECVD method. Note that the insulating layer 107 can also be formed by a sputtering method, for example.

Through the above steps, the semiconductor device of one embodiment of the present invention can be manufactured.

In the method for manufacturing the semiconductor device illustrated in FIG. 30A to FIG. 31C, without performing anisotropic etching in forming the insulating layer 105, etching treatment is performed on only part of the insulating layer 105. This can prevent the insulating layer 105 from having a region thinner than that of the other region even when the thickness of the insulating layer 105 is reduced. Thus, the insulating layer 105 can be thinned and a short circuit due to contact between the conductive layer 103 and the semiconductor layer 108 can be prevented. When the insulating layer 105 has a small thickness, the electric field of the conductive layer 103 functioning as the back gate electrode of the transistor 100 can be easily applied to the semiconductor layer 108.

Meanwhile, in the method for manufacturing the semiconductor device illustrated in FIG. 25A to FIG. 29B, there is no need to use photolithography, for example, to expose the top surface of the conductive layer 112a. This eliminates the need to consider alignment accuracy of the mask, allowing the opening portion 141 to be miniaturized. Thus, the transistor having a minute size can be manufactured. Furthermore, in the case of manufacturing a semiconductor device including the plurality of transistors 100, even when the opening portion 141 is miniaturized, variation in electrical characteristics, e.g., variation in channel lengths, among the plurality of transistors 100 can be inhibited.

### <Manufacturing Method Example 3 of Semiconductor Device>

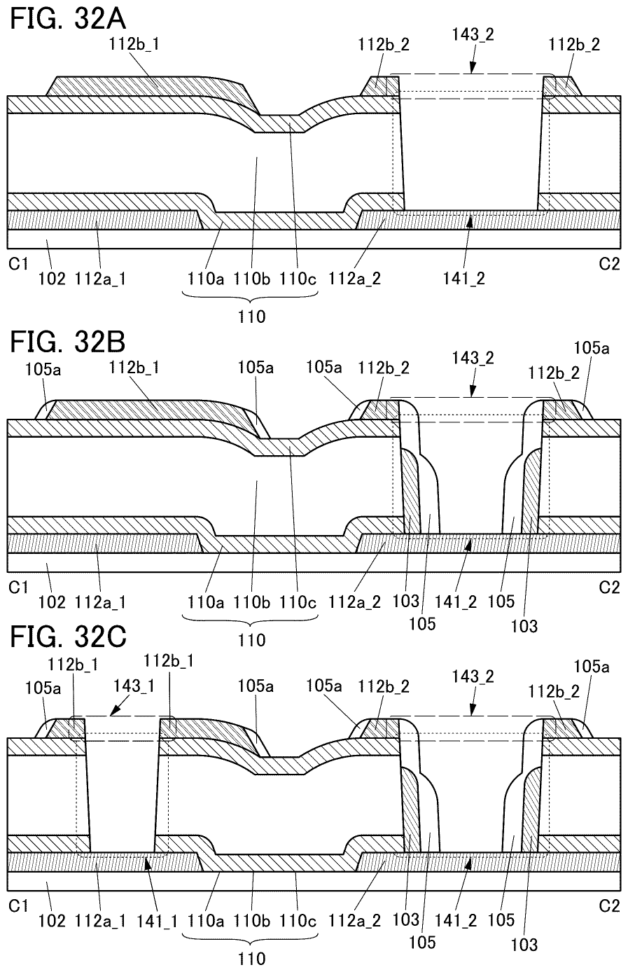

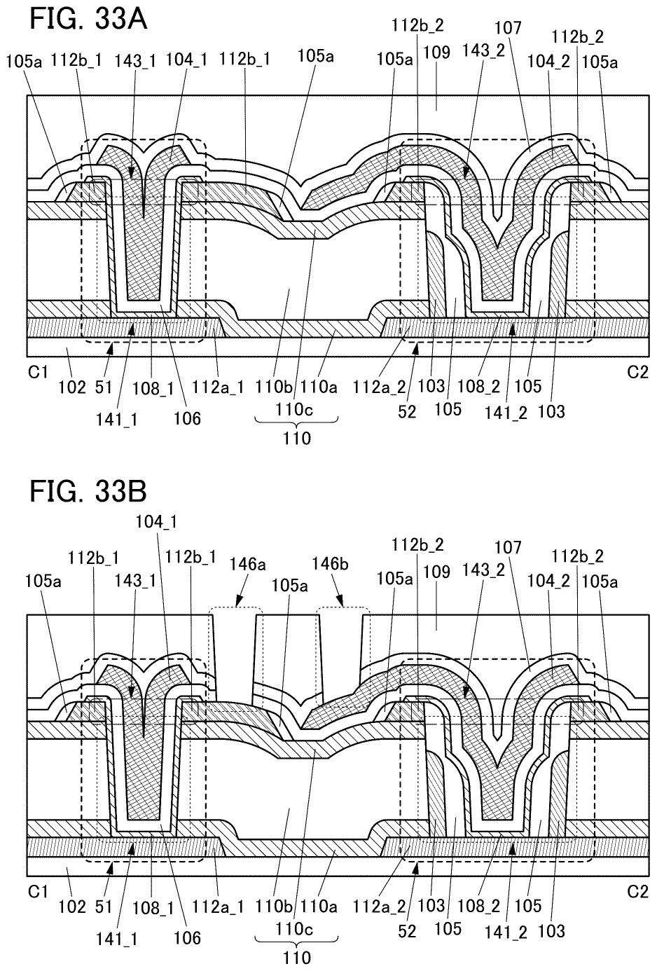

An example of a method for manufacturing the semiconductor device illustrated in FIG. 15B will be described below with reference to FIG. 32A to FIG. 33B. FIG. 32A to FIG. 33B each illustrate a cross-sectional view taken along the dashed-dotted line C1-C2 in FIG. 15B.

First, through steps similar to those illustrated in FIG. 25A to FIG. 26A, the conductive layer 112a_1 and the conductive layer 112a_2, the insulating layer 110, the conductive layer 112b_1, and the conductive layer 112b_2 are formed in this order over the substrate 102 (FIG. 32A). Here, the conductive layer 112a_1 and the conductive layer 112a_2 can be formed by processing the same conductive film. The conductive layer 112b_1 and the conductive layer 112b_2 can be formed by processing the same conductive film.

Then, the conductive layer 112b_2 is processed to form the opening portion 1432 (FIG. 32A). The opening portion 143_2 can be formed by a method similar to that for forming the opening portion 143 illustrated in FIG. 26B.

Then, the insulating layer 110 is processed to form the opening portion 141_2 (FIG. 32A). The opening portion 141_2 can be formed by a method similar to that for forming the opening portion 141 illustrated in FIG. 26C.

Subsequently, through steps similar to those illustrated in FIG. 27A to FIG. 28A, the conductive layer 103 and the insulating layer 105 are formed in the opening portion 1412 (FIG. 32B). Here, the depressed portion 129 illustrated in FIG. 5 is formed in the conductive layer 112a_2 in some cases because of the step of forming the conductive layer 103, specifically, the anisotropic etching on the conductive film 103f illustrated in FIG. 27A.

The insulating layer 105 is sometimes formed to include a region positioned in the opening portion 143_2. The insulating layer 105a is sometimes formed to cover at least part of the side surface of the conductive layer 112b_1 and at least part of the side surface of the conductive layer 112b_2 that is opposite to the opening portion 143_2. For example, the insulating layer 105a is sometimes formed to include a region in contact with the side surface of the conductive layer 112b_1 and a region in contact with the side surface of the conductive layer 112b_2 that is opposite to the opening portion 143_2.

Then, the conductive layer 112b_1 and the insulating layer 110 are processed to form the opening portion 143_1 and the opening portion 141_1, respectively (FIG. 32C). The opening portion 143_1 can be formed by a method similar to that for forming the opening portion 143 illustrated in FIG. 26B. The opening portion 141_1 can be formed by a method similar to that for forming the opening portion 141 illustrated in FIG. 26C.

Subsequently, through steps similar to those illustrated in FIG. 28B to FIG. 29B, the semiconductor layer 108_1, the semiconductor layer 108_2, the insulating layer 106, the conductive layer 104_1, and the conductive layer 1042 are formed in this order (FIG. 33A). Here, the semiconductor layer 108_1 and the semiconductor layer 108_2 can be formed by processing the semiconductor film 108f illustrated in FIG. 28B. The conductive layer 104_1 and the conductive layer 104_2 can be formed by processing the same conductive film.

Next, the insulating layer 107 is formed to cover the conductive layer 104 and the insulating layer 106 (FIG. 33A). As described above, the insulating layer 107 can be formed by a CVD method, for example, or specifically, a PECVD method. Note that the insulating layer 107 can also be formed by a sputtering method, for example.

Next, the insulating layer 109 is formed over the insulating layer 107 (FIG. 33A). In the case where an organic insulating film is used as the insulating layer 109, the insulating layer 109 can be formed by a wet film-formation method such as a spin coating method, a dip coating method, a spray coating method, an inkjet method, dispensing, screen printing, offset printing, a doctor knife method, slit coating, roll coating, curtain coating, or knife coating, for example. In the case where an inorganic insulating film is used as the insulating layer 109, the insulating layer 109 can be formed by a CVD method or a sputtering method, for example.

Next, the opening portion 146a reaching the conductive layer 112b_1 is formed in the insulating layer 109, the insulating layer 107, and the insulating layer 106. In addition, the opening portion 146b reaching the conductive layer 112b_2 is formed in the insulating layer 109 and the insulating layer 107 (FIG. 33B). The opening portion 146a and the opening portion 146b can be formed in parallel.

The opening portion 146a and the opening portion 146b can be formed by a photolithography method and an etching method, for example. Specifically, a resist mask is formed over the insulating layer 109 and portions of the insulating layer 109, the insulating layer 107, and the insulating layer 105 that do not overlap with the resist mask are removed by an etching method, whereby the opening portion 146a and the opening portion 146b can be formed. In particular, a dry etching method is preferably used to remove the insulating layer 109, the insulating layer 107, and the insulating layer 105, in which case the opening portion 146a and the opening portion 146b can be miniaturized.

Next, the conductive layer 119 is formed to include a region positioned in the opening portion 146a and a region positioned in the opening portion 146b (FIG. 15B). The conductive layer 119 can be formed to include a region in contact with the conductive layer 112b_1 in the opening portion 146a and a region in contact with the conductive layer 104_2 in the opening portion 146b.

For example, a conductive film to be the conductive layer 119 is formed over the insulating layer 109 to include a region positioned in the opening portion 146a and a region positioned in the opening portion 146b and the conductive film is processed, whereby the conductive layer 119 can be formed. For the formation of the conductive film to be the conductive layer 119, a sputtering method, a thermal CVD method (including an MOCVD method), or an ALD method is suitable, for example. A resist mask is formed over the conductive film by a photolithography step and then, the conductive film is processed, whereby the conductive layer 119, which functions as the lead wiring, can be formed.

Through the above steps, the semiconductor device illustrated in FIG. 15B can be manufactured. Note that the conductive layer 103 is not formed in the opening portion 141_1 and formed in the opening portion 141_2. Thus, even in the case where a depressed portion is formed in the conductive layer 112a_2, a depressed portion is not formed in the conductive layer 112a_1 in some cases.

This embodiment can be combined with any of the other embodiments as appropriate. In this specification, in the case where a plurality of structure examples are described in one embodiment, the structure examples can be combined as appropriate.

### Embodiment 2

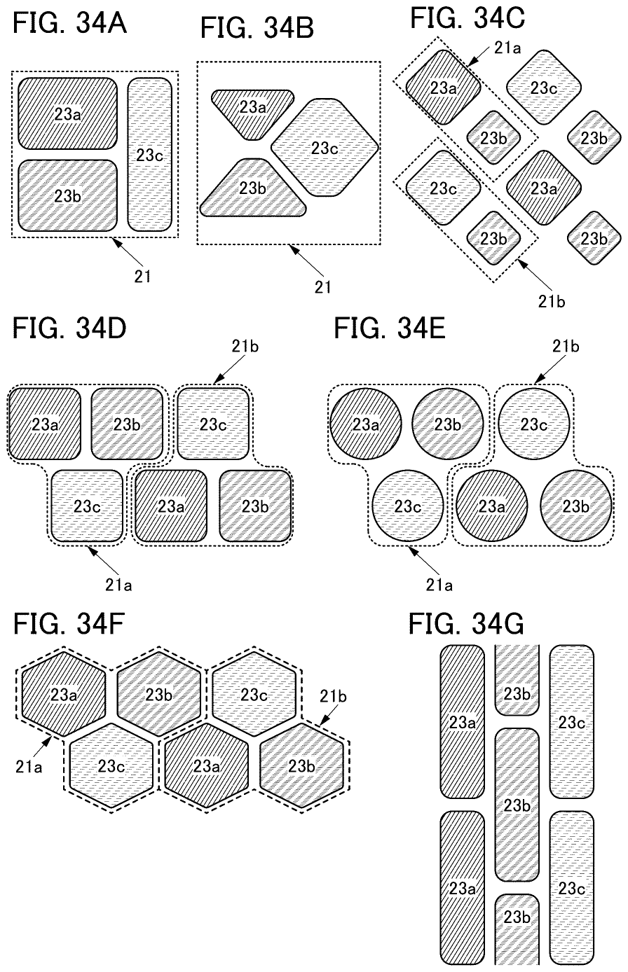

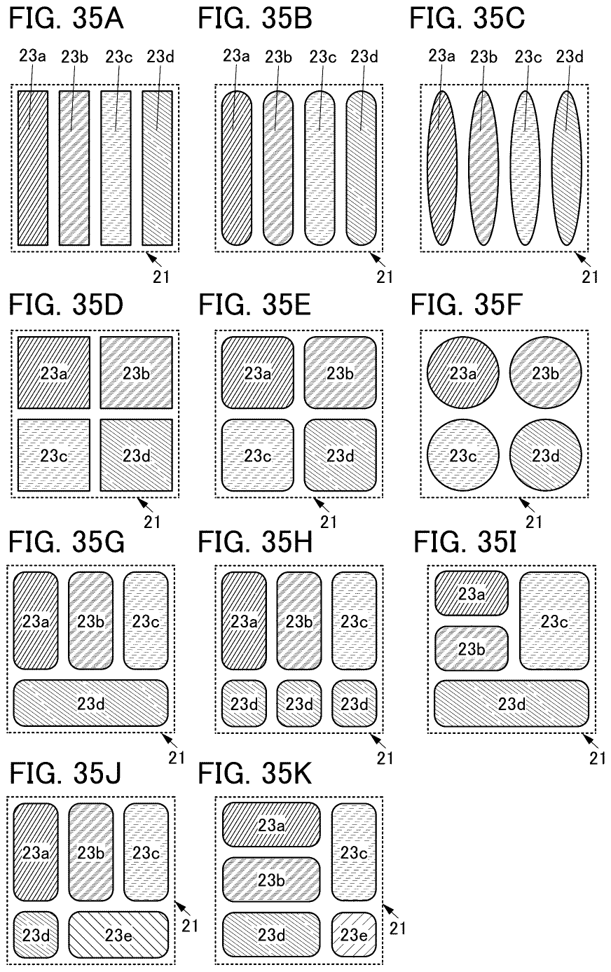

In this embodiment, a display device of one embodiment of the present invention is described with reference to FIG. 34A to FIG. 34G and FIG. 35A to FIG. 35K.

There is no particular limitation on the arrangement of subpixels, and a variety of methods can be employed. Examples of the arrangement of the subpixels include stripe arrangement, S-stripe arrangement, matrix arrangement, delta arrangement, Bayer arrangement, and PenTile arrangement.

The plan-view shape of a subpixel illustrated in a diagram in this embodiment corresponds to the plan-view shape of a display region (or light-receiving region).

Examples of the plan-view shape of the subpixel include polygonal shapes such as a triangle, a tetragon (including a rectangle and a square), and a pentagon; polygonal shapes with rounded corners; an elliptic shape; and a circular shape.

The range of the circuit layout for forming the subpixel is not limited to the range of the subpixel illustrated in a diagram and may be placed outside the range of the subpixel.

The pixel 21 illustrated in FIG. 34A employs S stripe arrangement. The pixel 21 illustrated in FIG. 34A is composed of three kinds of subpixels: a subpixel 23a, a subpixel 23b, and a subpixel 23c.

The pixel 21 illustrated in FIG. 34B includes the subpixel 23a and the subpixel 23b whose plan-view shapes have a rough trapezoidal or rough triangle shape with rounded corners and the subpixel 23c whose plan-view shape has a rough tetragonal or rough hexagonal shape with rounded corners. The subpixel 23b has a larger area of the display region than the subpixel 23a. In this manner, the shapes and sizes of the subpixels can be determined independently. For example, the size of a subpixel including a display element with higher reliability can be smaller.

A pixel 21a and a pixel 21b illustrated in FIG. 34C employ PenTile arrangement. FIG. 34C illustrates an example in which the pixel 21a including the subpixel 23a and the subpixel 23b and the pixel 21b including the subpixel 23b and the subpixel 23c are alternately arranged.

The pixel 21a and the pixel 21b illustrated in FIG. 34D to FIG. 34F employ delta arrangement. The pixel 21a includes two subpixels (the subpixel 23a and the subpixel 23b) in the upper row (first row) and one subpixel (the subpixel 23c) in the lower row (second row). The pixel 21b includes one subpixel (the subpixel 23c) in the upper row (first row) and two subpixels (the subpixel 23a and the subpixel 23b) in the lower row (second row).

FIG. 34D illustrates an example in which each subpixel has a rough tetragonal plan-view shape with rounded corners, FIG. 34E illustrates an example in which each subpixel has a circular plan-view shape, and FIG. 34F illustrates an example in which each subpixel has a rough hexagonal plan-view shape with rounded corners.

In FIG. 34F, each of the subpixels is placed inside one of the closest-packed hexagonal regions. Focusing on one of the subpixels, the subpixel is placed so as to be surrounded by six subpixels. The subpixels are arranged such that subpixels that emit light of the same color are not adjacent to each other. For example, focusing on the subpixel 23a, three of the subpixels 23b and three of the subpixels 23c are arranged to surround the subpixel 23a, and the subpixel 23b and the subpixel 23c are alternately arranged.

FIG. 34G illustrates an example in which subpixels of different colors are arranged in a zigzag manner. Specifically, the positions of the top sides of two subpixels arranged in the row direction (e.g., the subpixel 23a and the subpixel 23b or the subpixel 23b and the subpixel 23c) are not aligned in a plan view.

For example, in each pixel illustrated in FIG. 34A to FIG. 34G, it is preferable that the subpixel 23a be a subpixel R emitting red light, the subpixel 23b be a subpixel G emitting green light, and the subpixel 23c be a subpixel B emitting blue light. Note that the structure of the subpixels is not limited to this, and the colors and arrangement order of the subpixels can be determined as appropriate. For example, the subpixel 23b may be the subpixel R emitting red light and the subpixel 23a may be the subpixel G emitting green light.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the plan-view shape of a subpixel may have a polygonal shape with rounded corners, an elliptic shape, a circular shape, or the like.

To obtain a desired plan-view shape of the subpixel, a technique of correcting a mask pattern in advance so that a transferred pattern matches with a design pattern (an optical proximity correction (OPC) technique) may be used. Specifically, with the OPC technique, a pattern for correction is added to a corner portion of a figure on a mask pattern, for example.

As illustrated in FIG. 35A to FIG. 35I, the pixel can include four types of subpixels.

The pixels 21 illustrated in FIG. 35A to FIG. 35C employ stripe arrangement.

FIG. 35A illustrates an example in which each subpixel has a rectangular plan-view shape, FIG. 35B illustrates an example in which each subpixel has a plan-view shape formed by combining two half circles and a rectangle, and FIG. 35C illustrates an example in which each subpixel has an elliptical plan-view shape.

The pixels 21 illustrated in FIG. 35D to FIG. 35F employ matrix arrangement.

FIG. 35D illustrates an example in which each subpixel has a square plan-view shape, FIG. 35E illustrates an example in which each subpixel has a substantially square plan-view shape with rounded corners, and FIG. 35F illustrates an example in which each subpixel has a circular plan-view shape.

FIG. 35G and FIG. 35H each illustrate an example in which one pixel 21 is composed of two rows and three columns.

The pixel 21 illustrated in FIG. 35G includes three subpixels (the subpixel 23a, the subpixel 23b, and the subpixel 23c) in the upper row (first row) and one subpixel (a subpixel 23d) in the lower row (second row). In other words, the pixel 21 includes the subpixel 23a in the left column (first column), the subpixel 23b in the center column (second column), the subpixel 23c in the right column (third column), and the subpixel 23d across these three columns.

The pixel 21 illustrated in FIG. 35H includes three subpixels (the subpixel 23a, the subpixel 23b, and the subpixel 23c) in the upper row (first row) and three subpixels 23d in the lower row (second row). In other words, the pixel 21 includes the subpixel 23a and the subpixel 23d in the left column (first column), the subpixel 23b and the subpixel 23d in the center column (second column), and the subpixel 23c and the subpixel 23d in the right column (third column). Matching the positions of the subpixels in the upper row and the lower row as illustrated in FIG. 35H enables efficient removal of dust that would be produced in the manufacturing process, for example. Thus, a display device with high display quality can be provided.

FIG. 35I illustrates an example in which one pixel 21 is composed of three rows and two columns.

The pixel 21 illustrated in FIG. 35I includes the subpixel 23a in the upper row (first row), the subpixel 23b in the center row (second row), the subpixel 23c across the first and second rows, and one subpixel (the subpixel 23d) in the lower row (third row). In other words, the pixel 21 includes the subpixel 23a and the subpixel 23b in the left column (first column), the subpixel 23c in the right column (second column), and the subpixel 23d across these two columns.

The pixels 21 illustrated in FIG. 35A to FIG. 35I are each composed of four subpixels: the subpixel 23a, the subpixel 23b, the subpixel 23c, and the subpixel 23d.

The subpixel 23a, the subpixel 23b, the subpixel 23c, and the subpixel 23d can emit light of different colors. The subpixel 23a, the subpixel 23b, the subpixel 23c, and the subpixel 23d are subpixels of four colors of R, G, B, and white (W), subpixels of four colors of R, G, B, and Y, or subpixels of R, G, B, and infrared light (IR).

In the pixels 21 illustrated in FIG. 35A to FIG. 35I, for example, it is preferable that the subpixel 23a be the subpixel R emitting red light, the subpixel 23b be the subpixel G emitting green light, the subpixel 23c be the subpixel B emitting blue light, and the subpixel 23d be any of a subpixel W emitting white light, a subpixel Y emitting yellow light, and a subpixel IR emitting near-infrared light. In the case of such a structure, stripe arrangement is employed as the layout of R, G, and B in the pixels 21 illustrated in FIG. 35G and FIG. 35H, leading to higher display quality. In the pixel 21 illustrated in FIG. 35I, what is called S stripe arrangement is employed as the layout of R, G, and B, leading to higher display quality.

The pixel 21 may include a subpixel including a light-receiving element.

In the pixels 21 illustrated in FIG. 35A to FIG. 35I, any one of the subpixel 23a to the subpixel 23d may be a subpixel including a light-receiving element.

In the pixels 21 illustrated in FIG. 35A to FIG. 35I, for example, it is preferable that the subpixel 23a be the subpixel R emitting red light, the subpixel 23b be the subpixel G emitting green light, the subpixel 23c be the subpixel B emitting blue light, and the subpixel 23d be a subpixel S including a light-receiving element. In the case of such a structure, stripe arrangement is employed as the layout of R, G, and B in the pixels 21 illustrated in FIG. 35G and FIG. 35H, leading to higher display quality. In the pixel 21 illustrated in FIG. 35I, what is called S stripe arrangement is employed as the layout of R, G, and B, leading to higher display quality.

There is no particular limitation on the wavelength of light detected by the subpixel S including a light-receiving element. The subpixel S can have a structure in which one or both of visible light and infrared light are detected.

As illustrated in FIG. 35J and FIG. 35K, the pixel can include five types of subpixels.

FIG. 35J illustrates an example in which one pixel 21 is composed of two rows and three columns.

The pixel 21 illustrated in FIG. 35J includes three subpixels (the subpixel 23a, the subpixel 23b, and the subpixel 23c) in the upper row (first row) and two subpixels (the subpixel 23d and a subpixel 23e) in the lower row (second row). In other words, the pixel 21 includes the subpixel 23a and the subpixel 23d in the left column (first column), the subpixel 23b in the center column (second column), the subpixel 23c in the right column (third column), and the subpixel 23e across the second column and the third column.

FIG. 35K illustrates an example in which one pixel 21 is composed of three rows and two columns.

The pixel 21 illustrated in FIG. 35K includes the subpixel 23a in the upper row (first row), the subpixel 23b in the center row (second row), the subpixel 23c across the first row and the second row, and two subpixels (the subpixel 23d and the subpixel 23e) in the lower row (third row). In other words, the pixel 21 includes the subpixel 23a, the subpixel 23b, and the subpixel 23d in the left column (first column), and the subpixel 23c and the subpixel 23e in the right column (second column).

In the pixels 21 illustrated in FIG. 35J and FIG. 35K, for example, it is preferable that the subpixel 23a be the subpixel R emitting red light, the subpixel 23b be the subpixel G emitting green light, and the subpixel 23c be the subpixel B emitting blue light. In the case of such a structure, stripe arrangement is employed as the layout of R, G, and B in the pixel 21 illustrated in FIG. 35J, leading to higher display quality. In addition, what is called S stripe arrangement is employed as the layout of R, G, and B in the pixel 21 illustrated in FIG. 35K, leading to higher display quality.

In the pixels 21 illustrated in FIG. 35J and FIG. 35K, for example, it is preferable to use the subpixel S including a light-receiving element as at least one of the subpixel 23d and the subpixel 23e. In the case where light-receiving elements are used in both the subpixel 23d and the subpixel 23e, the light-receiving elements may have different structures. For example, the wavelength ranges of detected light may be different at least partly. Specifically, one of the subpixel 23d and the subpixel 23e may include a light-receiving element mainly detecting visible light and the other may include a light-receiving element mainly detecting infrared light.

In the pixel 21 illustrated in FIG. 35J and FIG. 35K, for example, it is preferable that the subpixel S including a light-receiving element be used as one of the subpixel 23d and the subpixel 23e and a subpixel including a light-emitting element that can be used as a light source be used as the other. For example, it is preferable that one of the subpixel 23d and the subpixel 23e be the subpixel IR emitting infrared light and the other be the subpixel S including a light-receiving element detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, the pixel composed of the subpixels each including the display element can employ any of a variety of layouts in the display device of one embodiment of the present invention. The display device of one embodiment of the present invention can have a structure in which the pixel includes both a light-emitting element and a light-receiving element. Also in this case, any of various layouts can be employed.

This embodiment can be combined with any of the other embodiments as appropriate. In this specification, in the case where a plurality of structure examples are described in one embodiment, the structure examples can be combined as appropriate.

### Embodiment 3

In this embodiment, display devices of embodiments of the present invention will be described.

The display device of this embodiment can be a high-definition display device or a large-sized display device. Accordingly, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or notebook computer, a monitor of a computer or the like, digital signage, and a large game machine such as a pachinko machine.

The display device of this embodiment can be a high-resolution display device. Accordingly, the display device of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

The display device of this embodiment may have a function of a touch panel. For example, the display device can employ any of a variety of sensing elements (also referred to as sensor elements) that can sense proximity or touch of a sensing target such as a finger.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The mutual capacitive type is preferably used, in which case multiple points can be detected simultaneously.

Examples of a touch panel include an out-cell touch panel, an on-cell touch panel, and an in-cell touch panel. Note that an in-cell touch panel has a structure in which an electrode included in a sensing element is provided on one or both of a substrate supporting a display element and a counter substrate.

### [Display Device 10A]

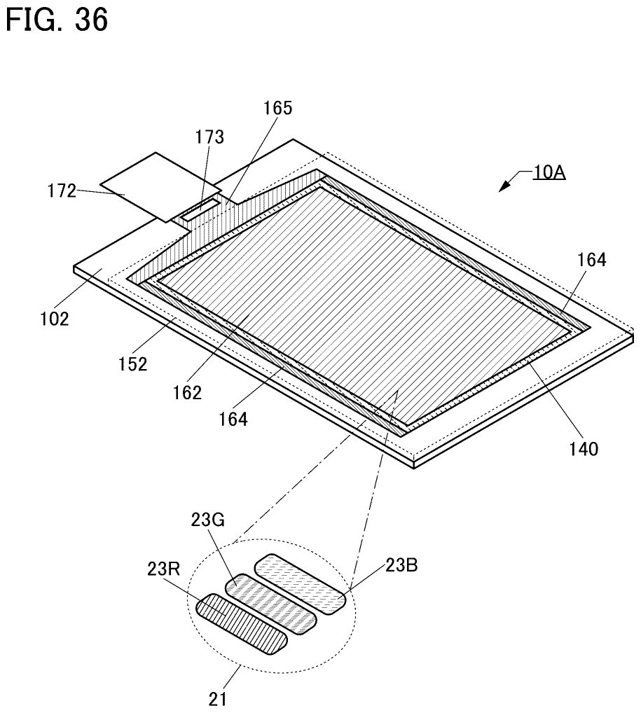

FIG. 36 is a perspective view illustrating a structure example of a display device 10A.

In the display device 10A, a substrate 152 and the substrate 102 are bonded to each other. In FIG. 36, the substrate 152 is indicated by the dashed line.

The display device 10A includes a display portion 162, a connection portion 140, a circuit portion 164, a conductive layer 165, and the like. FIG. 36 illustrates an example in which an IC 173 and an FPC 172 are implemented onto the display device 10A. Thus, the structure illustrated in FIG. 36 can be regarded as a display module including the display device 10A, the IC, and the FPC.

The connection portion 140 is provided outside the display portion 162. The connection portion 140 can be provided along one or more sides of the display portion 162. The number of connection portions 140 may be one or more. FIG. 36 illustrates an example in which the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or from the IC 173.

FIG. 36 illustrates an example in which the IC 173 is provided on the substrate 102 by a COG method, a COF method, or the like. An IC including one or both of a scan line driver circuit and a signal line driver circuit can be used as the IC 173, for example. Note that the display device 10A and the display module are not necessarily provided with an IC. The IC may be mounted on the FPC by a COF method, for example.

The semiconductor device of one embodiment of the present invention can be used for one or both of the display portion 162 and the circuit portion 164 of the display device 10A, for example. An oxide semiconductor (OS) can be suitably used for a channel formation region of a transistor included in the display device. By using an OS transistor, a display device can have low power consumption. The semiconductor device of one embodiment of the present invention can be used for both the display portion 162 and the circuit portion 164; that is, all the transistors included in the display device can be OS transistors. When all the transistors included in the display device are OS transistors as described above, an effect of reducing the manufacturing cost can be obtained.

When the semiconductor device of one embodiment of the present invention is used for a pixel circuit of a display device, the area occupied by the pixel circuit can be reduced and a high-resolution display device can be provided, for example. When the semiconductor device of one embodiment of the present invention is used for a driver circuit of a display device, the area occupied by the driver circuit can be reduced and the display device can have a narrow bezel, for example. Since the semiconductor device of one embodiment of the present invention has favorable electrical characteristics, a display device can have increased reliability by including the semiconductor device.

The display portion 162 of the display device 10A is a region where an image is to be displayed, and includes a plurality of pixels 21 that are periodically arranged. FIG. 36 illustrates an enlarged view of one of the pixels 21.

There is no particular limitation on the arrangement of the pixels in the display device of this embodiment, and any of a variety of arrangements can be employed. Examples of the arrangement of the pixels include stripe arrangement, S-stripe arrangement, matrix arrangement, delta arrangement, Bayer arrangement, and PenTile arrangement.

The pixel 21 illustrated in FIG. 36 includes the subpixel 23R that emits red light, the subpixel 23G that emits green light, and the subpixel 23B that emits blue light. There is no particular limitation on the number of subpixels included in one pixel.

The subpixel 23R, the subpixel 23G, and the subpixel 23B each include a display element and a circuit for controlling the driving of the display element.

Any of a variety of elements can be used as the display element, and a light-emitting element or a liquid crystal element can be used, for example. Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

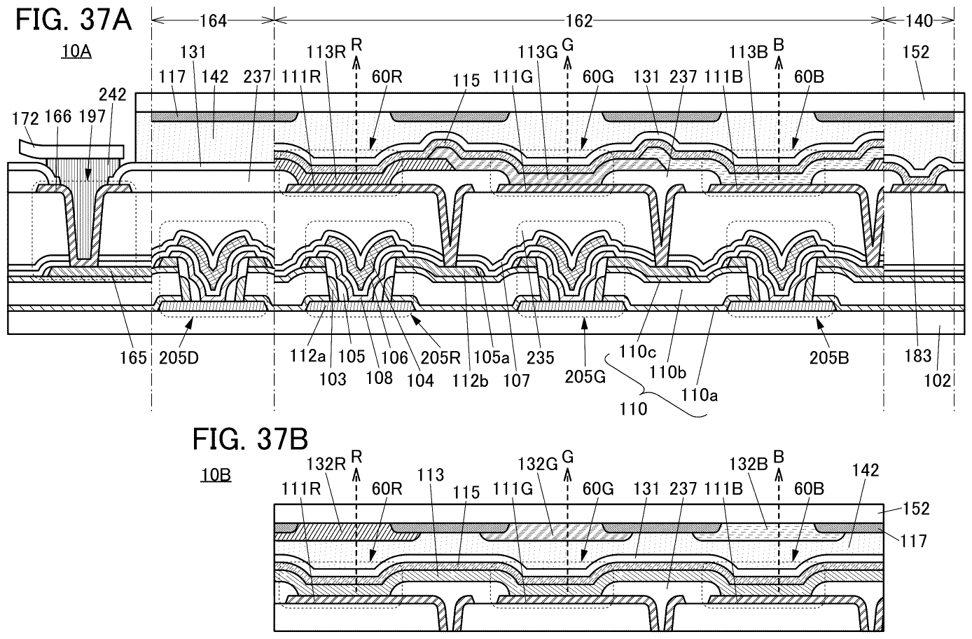

FIG. 37A illustrates an example of cross sections of part of a region including the FPC 172, part of the circuit portion 164, part of the display portion 162, part of the connection portion 140, and part of a region including the end portion of the display device 10A.

The display device 10A illustrated in FIG. 37A includes a transistor 205D, a transistor 205R, a transistor 205G, a transistor 205B, a light-emitting element 60R, a light-emitting element 60G, a light-emitting element 60B, and the like between the substrate 102 and the substrate 152. The light-emitting element 60R is a display element included in the subpixel 23R that emits red light. The light-emitting element 60G is a display element included in the subpixel 23G that emits green light. The light-emitting element 60B is a display element included in the subpixel 23B that emits blue light. Note that the description of the light-emitting element 60 in Embodiment 1 can be applied to the light-emitting element 60R, the light-emitting element 60G, and the light-emitting element 60B.

The display device 10A employs an SBS structure. The SBS structure can optimize materials and structures of light-emitting elements and thus can extend the freedom of choice of materials and structures, whereby the luminance and the reliability can be easily improved.

The display device 10A has atop-emission structure. The aperture ratio of pixels in atop-emission structure can be higher than that of pixels in a bottom-emission structure because, for example, a transistor can be provided to overlap with a light-emitting region of a light-emitting element in the top-emission structure.

The transistor 205D, the transistor 205R, the transistor 205G, and the transistor 205B are each formed over the substrate 102. These transistors can be formed using the same material in the same step. Note that the transistor 205D, the transistor 205R, the transistor 205G, and the transistor 205B may have different structures.

This embodiment describes an example in which OS transistors are used as the transistor 205D, the transistor 205R, the transistor 205G, and the transistor 205B. Any of the transistors of embodiments of the present invention can be used as the transistor 205D, the transistor 205R, the transistor 205G, and the transistor 205B. In other words, the display device 10A includes any of the transistors of embodiments of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

Specifically, the transistor 205D, the transistor 205R, the transistor 205G, and the transistor 205B each include the conductive layer 104 functioning as a gate, the insulating layer 106 functioning as a gate insulating layer, the conductive layer 103 functioning as a back gate, the insulating layer 105 functioning as a back gate insulating layer, the conductive layer 112a and the conductive layer 112b functioning as a source and a drain, the semiconductor layer 108 including a metal oxide, and the insulating layer 110. The insulating layer 105a is provided to cover at least part of the side surface of the conductive layer 112b in some cases. The insulating layer 105a can include a region in contact with the side surface of the conductive layer 112b. FIG. 37A illustrates an example in which the insulating layer 110 has a stacked-layer structure of three layers of the insulating layer 110a, the insulating layer 110b over the insulating layer 110a, and the insulating layer 110c over the insulating layer 110b. The following drawings each illustrate an example in which the insulating layer 110 has the stacked-layer structure of three layers.

In FIG. 37A, a plurality of layers obtained by processing the same conductive film are illustrated with the same hatching pattern. The same applies to the following drawings. The insulating layer 110 is provided to cover the end portion of the conductive layer 112a. The conductive layer 112b is provided over the insulating layer 110. The insulating layer 106 is provided between the conductive layer 104 and the semiconductor layer 108.

Note that the transistor included in the display device of this embodiment is not limited to the transistor of one embodiment of the present invention. For example, the display device of this embodiment may include the transistor of one embodiment of the present invention and a transistor having another structure in combination.

The display device of this embodiment may include one or more of a planar transistor, a staggered transistor, and an inverted staggered transistor. A transistor included in the display device of this embodiment may have a top-gate structure or a bottom-gate structure. Gates may be provided above and below a semiconductor layer where a channel is formed. A Si transistor may be included in the display device of this embodiment.

The transistor included in the circuit portion 164 and the transistor included in the display portion 162 may have the same structure or different structures. One structure or two or more kinds of structures may be employed for a plurality of transistors included in the circuit portion 164. Similarly, one structure or two or more kinds of structures may be employed for a plurality of transistors included in the display portion 162.

The insulating layer 107 is provided to cover the transistor 205D, the transistor 205R, the transistor 205G, and the transistor 205B, and an insulating layer 235 is provided over the insulating layer 107.

As described in Embodiment 1, the insulating layer 107 preferably functions as a protective layer of the transistor. A material that does not easily allow diffusion of impurities such as water and hydrogen is preferably used for the insulating layer 107. This allows the insulating layer 107 to function as a barrier layer. Such a structure can effectively inhibit diffusion of impurities to the transistors from the outside and increase the reliability of the display device.

The insulating layer 235 preferably has a function of a planarization layer, and an organic insulating film is suitably used. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 235 may have a stacked-layer structure of an organic insulating film and an inorganic insulating film. The outermost layer of the insulating layer 235 preferably functions as an etching protective layer. In that case, formation of a depressed portion in the insulating layer 235 can be inhibited in processing a pixel electrode 111R, a pixel electrode 111G, a pixel electrode 111B, and the like. Alternatively, a depressed portion may be formed in the insulating layer 235 in processing the pixel electrode 111R, the pixel electrode 111G, the pixel electrode 111B, and the like.

The light-emitting element 60R, the light-emitting element 60G, and the light-emitting element 60B are provided over the insulating layer 235.

The light-emitting element 60R includes the pixel electrode 111R over the insulating layer 235, an EL layer 113R over the pixel electrode 111R, and a common electrode 115 over the EL layer 113R. The light-emitting element 60R illustrated in FIG. 37A emits red light (R). The EL layer 113R includes a light-emitting layer that emits red light.

The light-emitting element 60G includes the pixel electrode 111G over the insulating layer 235, an EL layer 113G over the pixel electrode 111G, and the common electrode 115 over the EL layer 113G. The light-emitting element 60G illustrated in FIG. 37A emits green light (G). The EL layer 113G includes a light-emitting layer that emits green light.

The light-emitting element 60B includes the pixel electrode 111B over the insulating layer 235, an EL layer 113B over the pixel electrode 111B, and the common electrode 115 over the EL layer 113B. The light-emitting element 60B illustrated in FIG. 37A emits blue light (B). The EL layer 113B includes a light-emitting layer that emits blue light.

Although the EL layer 113R, the EL layer 113G, and the EL layer 113B have the same thickness in FIG. 37A, the present invention is not limited thereto. The EL layer 113R, the EL layer 113G, and the EL layer 113B may have different thicknesses. For example, the thicknesses of the EL layer 113R, the EL layer 113G, and the EL layer 113B are preferably set in accordance with an optical path length that intensifies light emitted from each EL layer. In that case, a microcavity structure is achieved, and the color purity of light emitted from each light-emitting element can be improved.

The pixel electrode 111R is electrically connected to the conductive layer 112b included in the transistor 205R through an opening portion provided in the insulating layer 106, the insulating layer 107, and the insulating layer 235. In a similar manner, the pixel electrode 111G is electrically connected to the conductive layer 112b included in the transistor 205G, and the pixel electrode 111B is electrically connected to the conductive layer 112b included in the transistor 205B.

The end portions of the pixel electrode 111R, the pixel electrode 111G, and the pixel electrode 111B are covered with an insulating layer 237. The insulating layer 237 functions as a partition. The insulating layer 237 can have a single-layer structure or a stacked-layer structure including one or both of an inorganic insulating material and an organic insulating material. A material that can be used for the insulating layer 107 and a material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display device 10A.

The common electrode 115 is one continuous film shared by the light-emitting element 60R, the light-emitting element 60G, and the light-emitting element 60B. The common electrode 115 shared by the light-emitting elements is electrically connected to a conductive layer 183 provided in the connection portion 140. As the conductive layer 183, a conductive layer formed using the same material in the same step as the pixel electrode 111R, the pixel electrode 111G, and the pixel electrode 111B is preferably used.

In the display device of one embodiment of the present invention, a conductive film that transmits visible light is used for the electrode through which light is extracted, which is either the pixel electrode or the common electrode. A conductive film reflecting visible light is preferably used for the electrode through which light is not extracted.

A conductive film that transmits visible light may be used also for the electrode through which light is not extracted. In that case, this electrode is preferably provided between a reflective layer and the EL layer. In other words, light emitted by the EL layer may be reflected by the reflective layer to be extracted from the display device.

As the material of the pair of electrodes of the light-emitting element, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element that belongs to Group 1 or Group 2 of the periodic table of the elements and that is not listed above as an example (e.g., lithium, cesium, calcium, or strontium), a rare earth metal such as europium or ytterbium, an alloy containing an appropriate combination of any of these elements, and graphene.

The light-emitting element preferably employs a microcavity structure. Therefore, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

A transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The EL layer 113R, the EL layer 113G, and the EL layer 113B are each provided to have an island shape. In FIG. 37A, the end portion of the EL layer 113R and the end portion of the EL layer 113G adjacent to each other overlap with each other, the end portion of the EL layer 113G and the end portion of the EL layer 113B adjacent to each other overlap with each other, and the end portion of the EL layer 113R and the end portion of the EL layer 113B adjacent to each other overlap with each other. When island-shaped EL layers are formed using a fine metal mask, the end portions of the EL layers adjacent to each other may overlap with each other as illustrated in FIG. 37A; however, the present invention is not limited thereto. That is, it is also possible that the EL layers adjacent to each other do not overlap with each other and are apart from each other. It is also possible that the display device includes both a portion where the EL layers adjacent to each other overlap with each other and a portion where the EL layers adjacent to each other do not overlap with each other and are apart from each other.

Each of the EL layer 113R, the EL layer 113G, and the EL layer 113B includes at least a light-emitting layer. The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

The light-emitting layer may include one or more kinds of organic compounds (e.g., a host material or an assist material) in addition to the light-emitting substance (a guest material). As the one or more kinds of organic compounds, one or both of a substance having a good hole-transport property (a hole-transport material) and a substance having a good electron-transport property (an electron-transport material) can be used. As the one or more kinds of organic compounds, a substance having a bipolar property (a substance having a good electron-transport property and a good hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer including a substance having a good hole-injection property (a hole-injection layer), a layer including a hole-transport material (a hole-transport layer), a layer including a substance having a good electron-blocking property (an electron-blocking layer), a layer including a substance having a good electron-injection property (an electron-injection layer), a layer including an electron-transport material (an electron-transport layer), and a layer including a substance having a good hole-blocking property (a hole-blocking layer). The EL layer may further include one or both of a substance having a bipolar property and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when voltage is applied between the pair of electrodes. A tandem structure enables a light-emitting element capable of emitting light with high luminance. Furthermore, the amount of current needed for obtaining a predetermined luminance can be smaller in a tandem structure than in a single structure; thus, a tandem structure enables higher reliability. A tandem structure may be referred to as a stack structure.

In the case of using a tandem light-emitting element in FIG. 37A, the EL layer 113R preferably includes a plurality of light-emitting units that emit red light, the EL layer 113G preferably includes a plurality of light-emitting units that emit green light, and the EL layer 113B preferably includes a plurality of light-emitting units that emit blue light.

A protective layer 131 is provided over the light-emitting element 60R, the light-emitting element 60G, and the light-emitting element 60B. The protective layer 131 and the substrate 152 are bonded to each other with an adhesive layer 142. The substrate 152 is provided with a light-blocking layer 117. For example, a solid sealing structure or a hollow sealing structure can be employed to seal the light-emitting elements. In FIG. 37A, a solid sealing structure is employed, in which a space between the substrate 152 and the substrate 102 is filled with the adhesive layer 142. Alternatively, a hollow sealing structure may be employed, in which the space is filled with an inert gas (e.g., nitrogen or argon). In that case, the adhesive layer 142 may be provided not to overlap with the light-emitting elements. Furthermore, the space may be filled with a resin other than the frame-shaped adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. It is preferable that the protective layer 131 be provided to extend to the end portion of the display device 10A. Meanwhile, a connection portion 197 has a portion not provided with the protective layer 131 so that the FPC 172 and a conductive layer 166 are electrically connected to each other.

By providing the protective layer 131 over the light-emitting element 60R, the light-emitting element 60G, and the light-emitting element 60B, the reliability of the light-emitting elements can be increased.

The protective layer 131 may have a single-layer structure or a stacked-layer structure of two or more layers. There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting elements by preventing oxidation of the common electrode 115 and inhibiting entry of impurities (e.g., moisture and oxygen) into the light-emitting elements, for example; thus, the reliability of the display device can be improved.

The protective layer 131 preferably includes one or more of an inorganic insulating layer. For the protective layer 131, a material that can be used for the insulating layer 110 can be used. In particular, the protective layer 131 is preferably formed using a nitride or a nitride oxide, and is further preferably formed using a nitride.

An inorganic film including ITO, In—Zn oxide, Ga—Zn oxide, Al—Zn oxide, IGZO, or the like can be used for the protective layer 131. The inorganic film preferably has high resistance, specifically, higher resistance than the common electrode 115. The inorganic film may further include nitrogen.

When light emitted from the light-emitting element is extracted through the protective layer 131, the protective layer 131 preferably has a good visible-light-transmitting property. For example, ITO, IGZO, and aluminum oxide are preferable because they are inorganic materials having a good visible-light-transmitting property.

The protective layer 131 can be, for example, a single-layer structure of an aluminum oxide film and a silicon nitride film over the aluminum oxide film, or a single-layer structure of an aluminum oxide film and an IGZO film over the aluminum oxide film. Such a stacked-layer structure can inhibit entry of impurities (e.g., water and oxygen) into the EL layers.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 197 is provided in a region of the substrate 102 not overlapping with the substrate 152. In the connection portion 197, the conductive layer 165 is electrically connected to the FPC 172 through the conductive layer 166 and a connection layer 242. The conductive layer 165 can be a conductive layer obtained by processing the same conductive film as the conductive layer 112b. The conductive layer 166 can be a conductive layer obtained by processing the same conductive film as the pixel electrode 111R, the pixel electrode 111G, and the pixel electrode 111B. The connection portion between the conductive layer 165 and the conductive layer 166 can have a structure similar to that of a connection portion between the conductive layer 112b and each of the pixel electrode 111R, the pixel electrode 111G, and the pixel electrode 1111B. Specifically, FIG. 37A illustrates an example in which an opening portion is provided in the upper layer of the conductive layer 165 and the conductive layer 166 is in contact with the top surface of the conductive layer 165 through the opening portion. On the top surface of the connection portion 197, the conductive layer 166 is exposed. Thus, the connection portion 197 and the FPC 172 can be electrically connected to each other through the connection layer 242.

The display device 10A has a top-emission structure. Light from the light-emitting element is emitted toward the substrate 152. For the substrate 152, a material having a good visible-light-transmitting property is preferably used. The pixel electrode 111R, the pixel electrode 111G, and the pixel electrode 111B include a material that reflects visible light, and the counter electrode (the common electrode 115) includes a material that transmits visible light.

The light-blocking layer 117 is preferably provided on the surface of the substrate 152 on the substrate 102 side. The light-blocking layer 117 can be provided over a region between adjacent light-emitting elements, in the connection portion 140, in the circuit portion 164, and the like.

A coloring layer such as a color filter may be provided on the surface of the substrate 152 on the substrate 102 side or over the protective layer 131. When the color filter is provided to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, and the like can be used. Each coloring layer can be formed using one or more of a metal material, a resin material, a pigment, and a dye. Each coloring layer is formed in a desired position by a printing method, an inkjet method, an etching method using a photolithography method, or the like.

Moreover, a variety of optical members can be provided on the outer surface of the substrate 152 (the surface opposite to the substrate 102). Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 152. For example, a glass layer or a silica layer (SiOₓ layer) is preferably provided as the surface protective layer to inhibit the surface contamination and damage. For the surface protective layer, DLC (diamond-like carbon), aluminum oxide (AlOₓ), a polyester-based material, a polycarbonate-based material, or the like may be used. The surface protective layer is preferably formed using a material having high visible light transmittance. The surface protective layer is preferably formed using a material with high hardness.

For each of the substrate 102 and the substrate 152, glass, quartz, ceramics, sapphire, a resin, a metal, an alloy, a semiconductor, or the like can be used. For the substrate on the side from which light from the light-emitting element is extracted, a material that transmits the light is used. When the substrate 102 and the substrate 152 are formed using a flexible material, the flexibility of the display device can be increased and a flexible display can be achieved. Furthermore, a polarizing plate may be used as at least one of the substrate 102 and the substrate 152.

For each of the substrate 102 and the substrate 152, any of the following can be used: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as at least one of the substrate 102 and the substrate 152.

In the case where a circularly polarizing plate overlaps with the display device, a highly optically isotropic substrate is preferably used as the substrate included in the display device. A highly optically isotropic substrate has a low birefringence (in other words, a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene-vinyl acetate) resin. In particular, a material with low moisture permeability, such as an epoxy resin, is preferable. A two-component-mixture-type resin may be used. An adhesive sheet may be used, for example.

As the connection layer 242, an anisotropic conductive film (ACF), an anisotropic conductive paste (ACP), or the like can be used.

### [Display Device 10B]

FIG. 37B illustrates an example of a cross section of the display portion 162 of a display device 10B. The display device 10B is different from the display device 10A mainly in that the subpixels of different colors include respective coloring layers (color filters) and the light-emitting elements that share an EL layer 113. The structure illustrated in FIG. 37B can be combined with the structure of the region including the FPC 172, the circuit portion 164, the stacked-layer structure from the substrate 102 to the insulating layer 235 in the display portion 162, the connection portion 140, and the end portion, which is illustrated in FIG. 37A. Note that in the following description of display devices, the description of portions similar to those of the above-described display device may be omitted as appropriate.

In the display device 10B illustrated in FIG. 37B, the light-emitting element 60R, the light-emitting element 60G, the light-emitting element 60B, a coloring layer 132R transmitting red light, a coloring layer 132G transmitting green light, a coloring layer 132B transmitting blue light, and the like are provided.

The light-emitting element 60R includes the pixel electrode 111R, the EL layer 113 over the pixel electrode 111R, and the common electrode 115 over the EL layer 113. Light emitted from the light-emitting element 60R is extracted as red light to outside the display device 10B through the coloring layer 132R.

The light-emitting element 60G includes the pixel electrode 111G, the EL layer 113 over the pixel electrode 111G, and the common electrode 115 over the EL layer 113. Light emitted from the light-emitting element 60G is extracted as green light to outside the display device 10B through the coloring layer 132G.

The light-emitting element 60B includes the pixel electrode 111B, the EL layer 113 over the pixel electrode 111B, and the common electrode 115 over the EL layer 113. Light emitted from the light-emitting element 60B is extracted as blue light to outside the display device 10B through the coloring layer 132B.

The EL layer 113 and the common electrode 115 are shared by the light-emitting element 60R, the light-emitting element 60G, and the light-emitting element 60B. The number of manufacturing steps can be smaller in the structure where the EL layer 113 is provided to be shared by the subpixels of different colors than in the structure where the subpixels of different colors are provided with different EL layers.

The light-emitting element 60R, the light-emitting element 60G, and the light-emitting element 60B illustrated in FIG. 37B emit white light, for example. White light emitted from the light-emitting element 60R, the light-emitting element 60G, and the light-emitting element 60B passes through the coloring layer 132R, the coloring layer 132G, and the coloring layer 132B, respectively. Thus, light of desired colors can be obtained.

In the light-emitting element that emits white light, two or more light-emitting layers are preferably included. When two light-emitting layers are used to obtain white light, two light-emitting layers that emit light of complementary colors are selected. For example, when the emission colors of the first light-emitting layer and the second light-emitting layer are made complementary, the light-emitting element can be configured to emit white light as a whole. In the case where three or more light-emitting layers are used to obtain white light, the light-emitting element is configured to emit white light as a whole by combining emission colors of the three or more light-emitting layers.

For example, the EL layer 113 preferably includes a light-emitting layer including a light-emitting substance that emits blue light and a light-emitting layer including a light-emitting substance that emits visible light having a longer wavelength than blue light. The EL layer 113 preferably includes a light-emitting layer that emits yellow light and a light-emitting layer that emits blue light, for example. Alternatively, the EL layer 113 preferably includes a light-emitting layer that emits red light, a light-emitting layer that emits green light, and a light-emitting layer that emits blue light, for example.

A light-emitting element that emits white light preferably has a tandem structure. Specific examples include a two-unit tandem structure including a light-emitting unit that emits yellow light and a light-emitting unit that emits blue light; a two-unit tandem structure including a light-emitting unit that emits red light and green light and a light-emitting unit that emits blue light; a three-unit tandem structure in which a light-emitting unit that emits blue light, a light-emitting unit that emits yellow, yellow-green, or green light, and a light-emitting unit that emits blue light are provided in this order; and a three-unit tandem structure in which a light-emitting unit that emits blue light, a light-emitting unit that emits yellow, yellow-green, or green light and red light, and a light-emitting unit that emits blue light are provided in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Note that in the case where the light-emitting element emitting white light has a microcavity structure, light with a specific wavelength such as red, green, or blue is sometimes intensified to be emitted.

Alternatively, the light-emitting element 60R, the light-emitting element 60G, and the light-emitting element 60B illustrated in FIG. 37B emit blue light, for example. In this case, the EL layer 113 includes one or more light-emitting layers that emit blue light. In the subpixel 23B that emits blue light, blue light emitted from the light-emitting element 60B can be extracted. In each of the subpixel 23R that emits red light and the subpixel 23G that emits green light, by providing a color conversion layer between the light-emitting element 60R or the light-emitting element 60G and the substrate 152, blue light emitted from the light-emitting element 60R or the light-emitting element 60G can be converted into light with a longer wavelength, and red light or green light can be extracted. Furthermore, it is preferable that over the light-emitting element 60R, the coloring layer 132R be provided between the color conversion layer and the substrate 152 and over the light-emitting element 60G, the coloring layer 132G be provided between the color conversion layer and the substrate 152. In some cases, part of light emitted from the light-emitting element is transmitted through the color conversion layer without being converted. When light transmitted through the color conversion layer is extracted through the coloring layer, light other than light of the intended color can be absorbed by the coloring layer, and the color purity of light emitted from a subpixel can be improved.

### [Display Device 10C]

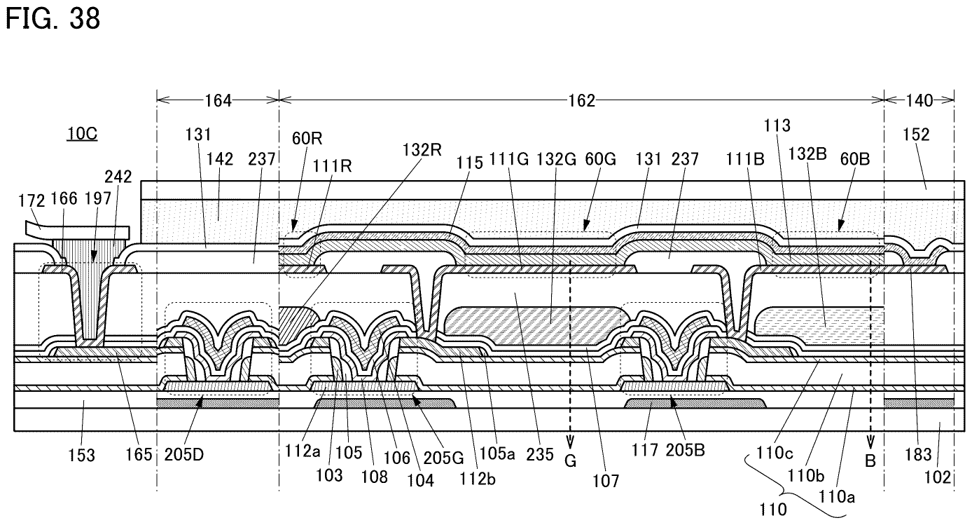

A display device 10C illustrated in FIG. 38 is different from the display device 10B mainly in having a bottom-emission structure.

Light from the light-emitting element is emitted toward the substrate 102. For the substrate 102, a material having a good visible-light-transmitting property is preferably used. By contrast, there is no limitation on the light-transmitting property of a material used for the substrate 152.

The light-blocking layer 117 is preferably formed between the substrate 102 and the transistor. In the example illustrated in FIG. 38, the light-blocking layers 117 are provided over the substrate 102, the insulating layer 153 is provided over the light-blocking layers 117, and the transistor 205D, the transistor 205R (not illustrated), the transistor 205G, the transistor 205B, and the like are provided over the insulating layer 153. In addition, the coloring layer 132R, the coloring layer 132G, and the coloring layer 132B are provided over the insulating layer 107, and the insulating layer 235 is provided over the coloring layer 132R, the coloring layer 132G, and the coloring layer 132B.

The light-emitting element 60R overlapping with the coloring layer 132R includes the pixel electrode 111R, the EL layer 113, and the common electrode 115.

The light-emitting element 60G overlapping with the coloring layer 132G includes the pixel electrode 111G, the EL layer 113, and the common electrode 115.

The light-emitting element 60B overlapping with the coloring layer 132B includes the pixel electrode 111B, the EL layer 113, and the common electrode 115.

A material having a good visible-light-transmitting property is used for each of the pixel electrode 111R, the pixel electrode 111G, and the pixel electrode 111B. A material that reflects visible light is preferably used for the common electrode 115. In the display device having a bottom-emission structure, the common electrode 115 can be formed using a metal with low electrical resistivity, for example; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 10D]

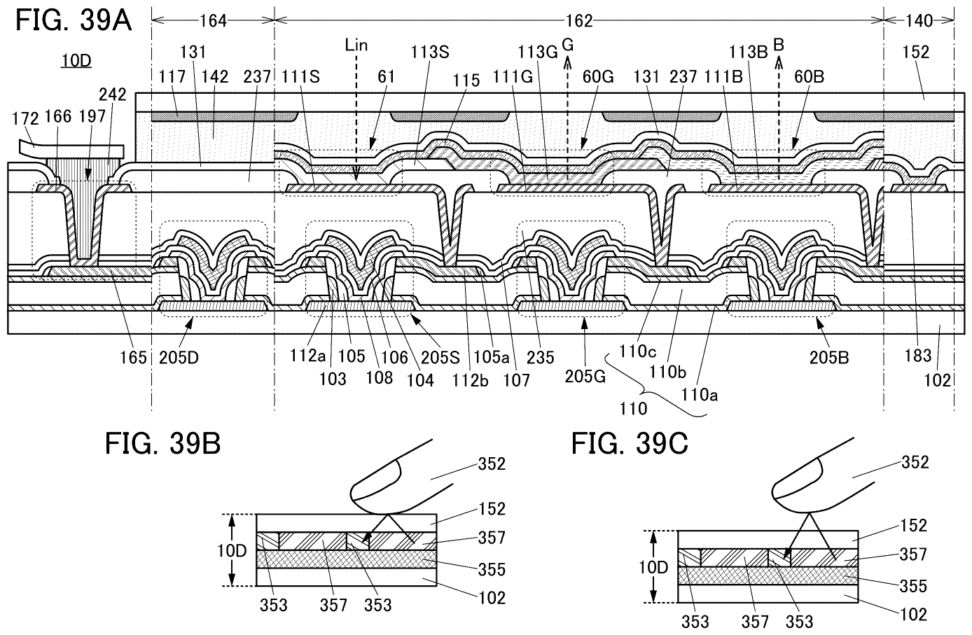

A display device 10D illustrated in FIG. 39A is different from the display device 10A mainly in including a light-receiving element 61.

The display device 10D includes light-emitting elements and a light-receiving element in a pixel. In the display device 10D, organic EL elements are preferably used as the light-emitting elements and an organic photodiode is preferably used as the light-receiving element. The organic EL elements and the organic photodiode can be formed over the same substrate. Thus, the organic photodiode can be incorporated in a display device including the organic EL elements.

In the display device 10D including the light-emitting elements and the light-receiving element in the pixel, the pixel has a light-receiving function; thus, the display device can detect the touch or proximity of an object while displaying an image. Accordingly, the display portion 162 has one or both of an image capturing function and a sensing function in addition to a function of displaying an image. For example, an image can be displayed by using all the subpixels included in the display device 10D; alternatively, light can be emitted by some of the subpixels as a light source, light can be detected by some other subpixels, and an image can be displayed by using the remaining subpixels.

Accordingly, a light-receiving portion and a light source do not need to be provided separately from the display device 10D; hence, the number of components of an electronic device can be reduced. For example, a biometric authentication device or a capacitive touch panel for scroll operation or the like does not need to be provided separately in the electronic device. Thus, with the use of the display device 10D, the electronic device can be manufactured at lower costs.

When the light-receiving element is used for an image sensor, the display device 10D can capture an image using the light-receiving element. For example, image capturing for personal authentication with the use of a fingerprint, a palm print, the iris, the shape of a blood vessel (including the shape of a vein and the shape of an artery), a face, or the like is possible by using the image sensor.

Moreover, the light-receiving element can be used in a touch sensor (also referred to as a direct touch sensor), a contactless sensor (also referred to as a hover sensor, a hover touch sensor, or a touchless sensor), or the like. The touch sensor can detect an object (e.g., a finger, a hand, or a pen) when the display device and the object come in direct contact with each other. Furthermore, the contactless sensor can detect the object even when the object is not in contact with the display device.

The light-receiving element 61 includes a pixel electrode 111S over the insulating layer 235, a functional layer 113S over the pixel electrode 111S, and the common electrode 115 over the functional layer 113S. Light Lin from outside the display device 10D enters the functional layer 113S.

The pixel electrode 111S is electrically connected to the conductive layer 112b included in a transistor 205S through an opening portion provided in the insulating layer 106, the insulating layer 107, and the insulating layer 235.

The end portion of the pixel electrode 111S is covered with the insulating layer 237.

The common electrode 115 is one continuous film shared by the light-receiving element 61, the light-emitting element 60R (not shown), the light-emitting element 60G, and the light-emitting element 60B. The common electrode 115 shared by the light-emitting elements and the light-receiving element is electrically connected to the conductive layer 183 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example in which an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer including a substance having a good hole-transport property, a substance having a good electron-transport property, a substance having a bipolar property, or the like. Without limitation to the above, the functional layer 113S may further include a layer including a substance having a good hole-injection property, a hole-blocking material, a substance having a good electron-injection property, an electron-blocking material, or the like. The functional layer 113S can be formed using a material that can be used for the light-emitting element, for example.

Either a low molecular compound or a high molecular compound can be used in the light-receiving element, and an inorganic compound may also be included. Each layer included in the light-receiving element can be formed by any of the following methods: an evaporation method (including a vacuum evaporation method), a transfer method, a printing method, an inkjet method, a coating method, and the like.

In the display device 10D illustrated in FIG. 39B and FIG. 39C, a layer 353 including a light-receiving element, a circuit layer 355, and a layer 357 including a light-emitting element are provided between the substrate 102 and the substrate 152.

The layer 353 includes the light-receiving element 61, for example. The layer 357 includes the light-emitting element 60R, the light-emitting element 60G, and the light-emitting element 60B, for example.

The circuit layer 355 includes a circuit for driving a light-receiving element and a circuit for driving a light-emitting element. The circuit layer 355 includes the transistor 205R, the transistor 205G, and the transistor 205B, for example. The circuit layer 355 can further include one or more of a switch, a capacitor, a resistor, a wiring, a terminal, and the like.

FIG. 39B illustrates an example in which the light-receiving element 61 is used as a touch sensor. Light emitted from the light-emitting element in the layer 357 is reflected by a finger 352 that touches the display device 10D as illustrated in FIG. 39B; then, the light-receiving element in the layer 353 detects the reflected light. Thus, the touch of the finger 352 on the display device 10D can be detected.

FIG. 39C illustrates an example in which the light-receiving element 61 is used as a contactless sensor. Light emitted from the light-emitting element in the layer 357 is reflected by the finger 352 that is close to (i.e., that does not touch) the display device 10D as illustrated in FIG. 39C; then, the light-receiving element in the layer 353 detects the reflected light.

### [Display Device 10E]

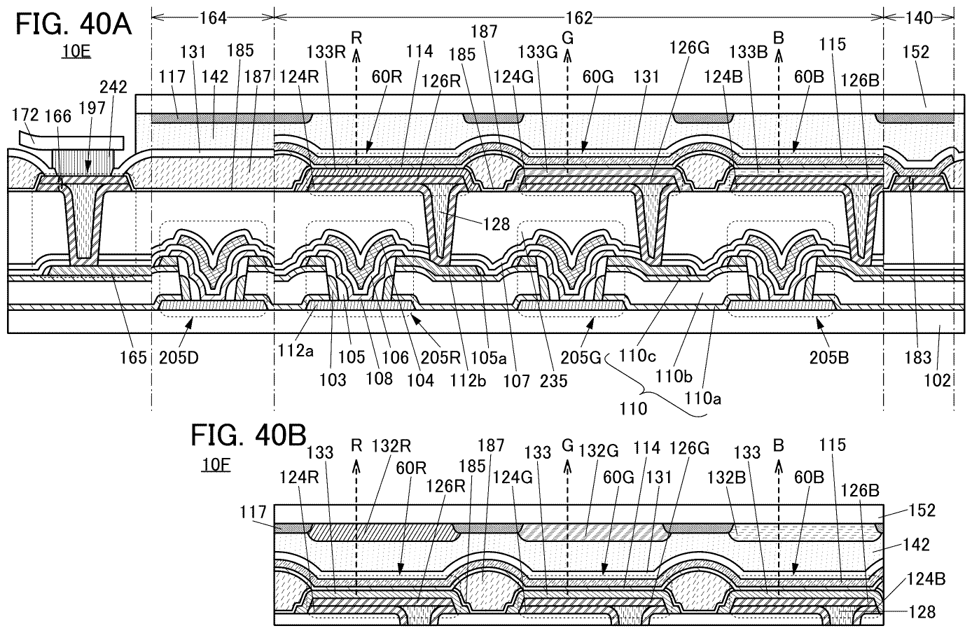

A display device 10E illustrated in FIG. 40A is an example of a display device having an MML (metal maskless) structure. In other words, the display device 10E includes a light-emitting element that is formed without using a fine metal mask.

An island-shaped light-emitting layer of the light-emitting element included in the display device having the MML structure is formed in the following manner: a light-emitting layer is formed on the entire surface, and then, the light-emitting layer is processed by a photolithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element that emits blue light, a light-emitting element that emits green light, and a light-emitting element that emits red light, three kinds of island-shaped light-emitting layers can be formed by repeating formation of a light-emitting layer and processing by photolithography three times.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. For processing by photolithography, an apparatus that is the same as or similar to an apparatus used for manufacturing a transistor can be used; thus, there is no need to introduce a special apparatus to manufacture the device having the MML structure. The MML structure can reduce the manufacturing cost as described above, and thus is suitable for mass production of devices.

A display device having the MML structure does not require a pseudo improvement in resolution by employing unique pixel arrangement such as PenTile arrangement, for example; thus, the display device can achieve high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

Moreover, providing a sacrificial layer over the light-emitting layer can reduce damage to the light-emitting layer in the manufacturing process of the display device, resulting in an increase in reliability of the light-emitting element.

Employing a film formation step using an area mask and a processing step using a resist mask enables a light-emitting element to be manufactured by a relatively easy process.

The stacked-layer structure from the substrate 102 to the insulating layer 235 and the stacked-layer structure from the protective layer 131 to the substrate 152 are similar to those in the display device 10A; therefore, description thereof is omitted.

In FIG. 40A, the light-emitting element 60R, the light-emitting element 60G, and the light-emitting element 60B are provided over the insulating layer 235.

The light-emitting element 60R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 60R illustrated in FIG. 40A emits red light (R). The layer 133R includes a light-emitting layer that emits red light. In the light-emitting element 60R, the layer 133R and the common layer 114 can be collectively referred to as an EL layer. One or both of the conductive layer 124R and the conductive layer 126R can be referred to as a pixel electrode.

The light-emitting element 60G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 60G illustrated in FIG. 40A emits green light (G). The layer 133G includes a light-emitting layer that emits green light. In the light-emitting element 60G, the layer 133G and the common layer 114 can be collectively referred to as an EL layer. One or both of the conductive layer 124G and the conductive layer 126G can be referred to as a pixel electrode.

The light-emitting element 60B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 60B illustrated in FIG. 40A emits blue light (B). The layer 133B includes a light-emitting layer that emits blue light. In the light-emitting element 60B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the light-emitting elements is referred to as the common layer 114. Note that in this specification and the like, only the layer 133R, the layer 133G, and the layer 133B are sometimes referred to as island-shaped EL layers, EL layers formed in an island shape, or the like, in which case the common layer 114 is not included in the EL layer. The light-emitting elements formed without using a metal mask do not necessarily include a common layer, and all the layers included in the EL layer may be formed in island shapes.

The layer 133R, the layer 133G, and the layer 133B are apart from each other. When the EL layer is provided to have an island shape for each light-emitting element, a leakage current between adjacent light-emitting elements can be inhibited. This can prevent crosstalk-induced unintended light emission, so that the display device can achieve extremely high contrast.

Although the layer 133R, the layer 133G, and the layer 133B have the same thickness in FIG. 40A, the present invention is not limited thereto. The layer 133R, the layer 133G, and the layer 133B may have different thicknesses.

The conductive layer 124R is electrically connected to the conductive layer 112b included in the transistor 205R through an opening portion provided in the insulating layer 106, the insulating layer 107, and the insulating layer 235. In a similar manner, the conductive layer 124G is electrically connected to the conductive layer 112b included in the transistor 205G, and the conductive layer 124B is electrically connected to the conductive layer 112b included in the transistor 205B.

The conductive layer 124R, the conductive layer 124G, and the conductive layer 124B are formed to cover the opening portions provided in the insulating layer 235. A layer 128 is embedded in each of the depressed portions of the conductive layer 124R, the conductive layer 124G, and the conductive layer 124B.

The layer 128 has a function of filling the depressed portions of the conductive layer 124R, the conductive layer 124G, and the conductive layer 124B. The conductive layer 126R, the conductive layer 126G, and the conductive layer 126B electrically connected to the conductive layer 124R, the conductive layer 124G, and the conductive layer 124B, respectively, are provided over the conductive layer 124R, the conductive layer 124G, the conductive layer 124B, and the layer 128. Thus, regions overlapping with the depressed portions of the conductive layer 124R, the conductive layer 124G, and the conductive layer 124B can also be used as the light-emitting regions, increasing the aperture ratio of the pixels. As each of the conductive layer 124R and the conductive layer 126R, a conductive layer functioning as a reflective electrode is preferably used.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although the top surface of the layer 128 includes a flat portion in the example illustrated in FIG. 40A, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

The end portion of the conductive layer 126R may match the end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0° and less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be favorable.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, the top surface and the side surface of the conductive layer 126G are covered with the layer 133G, and the top surface and the side surface of the conductive layer 126B are covered with the layer 133B. Accordingly, regions provided with the conductive layer 126R, the conductive layer 126G, and the conductive layer 126B can be entirely used as the light-emitting regions of the light-emitting element 60R, the light-emitting element 60G, and the light-emitting element 60B, thereby increasing the aperture ratio of the pixels.

A side surface and part of the top surface of each of the layer 133R, the layer 133G, and the layer 133B are covered with an insulating layer 185 and an insulating layer 187. The common layer 114 is provided over the layer 133R, the layer 133G, the layer 133B, the insulating layer 185, and the insulating layer 187, and the common electrode 115 is provided over the common layer 114. The common layer 114 and the common electrode 115 are each a continuous film provided to be shared by a plurality of light-emitting elements.

In FIG. 40A, the insulating layer 237 illustrated in FIG. 37A, for example, is not provided between the conductive layer 126R and the layer 133R. That is, an insulating layer (also referred to as a partition wall, a bank, a spacer, or the like) being in contact with the pixel electrode and covering the end portion of the top surface of the pixel electrode is not provided in the display device 10E. Thus, the interval between adjacent light-emitting elements can be extremely short. Accordingly, the display device can have high resolution or high definition. In addition, a mask for forming the insulating layer is not needed, which leads to a reduction in manufacturing cost of the display device.

As described above, the layer 133R, the layer 133G, and the layer 133B each include a light-emitting layer. The layer 133R, the layer 133G, and the layer 133B each preferably include a light-emitting layer and a carrier-transport layer (an electron-transport layer or a hole-transport layer) over the light-emitting layer. Alternatively, the layer 133R, the layer 133G, and the layer 133B each preferably include a light-emitting layer and a carrier-blocking layer (a hole-blocking layer or an electron-blocking layer) over the light-emitting layer. Alternatively, the layer 133R, the layer 133G, and the layer 133B each preferably include a light-emitting layer, a carrier-blocking layer over the light-emitting layer, and a carrier-transport layer over the carrier-blocking layer. Since surfaces of the layer 133R, the layer 133G, and the layer 133B are exposed in the manufacturing process of the display device, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting element 60R, the light-emitting element 60G, and the light-emitting element 60B.

The side surfaces of the layer 133R, the layer 133G, and the layer 133B are each covered with the insulating layer 185. The insulating layer 187 covers the side surfaces of the layer 133R, the layer 133G, and the layer 133B with the insulating layer 185 therebetween.

Since the side surface (and part of the top surface) of each of the layer 133R, the layer 133G, and the layer 133B are covered with at least one of the insulating layer 185 and the insulating layer 187, the common layer 114 (or the common electrode 115) can be inhibited from being in contact with the side surfaces of the pixel electrodes, the layer 133R, the layer 133G, and the layer 133B, leading to inhibition of a short circuit of the light-emitting elements. Thus, the reliability of the light-emitting elements can be increased.

The insulating layer 185 is preferably in contact with the side surfaces of the layer 133R, the layer 133G, and the layer 133B. The insulating layer 185 in contact with the layer 133R, the layer 133G, and the layer 133B can prevent film separation of the layer 133R, the layer 133G, and the layer 133B, whereby the reliability of the light-emitting elements can be increased.

The insulating layer 187 is provided over the insulating layer 185 to fill a depressed portion of the insulating layer 185. The insulating layer 187 preferably covers at least part of the side surface of the insulating layer 185.

The insulating layer 185 and the insulating layer 187 can fill a gap between adjacent island-shaped layers, whereby unevenness with a large level difference on the formation surface of the layers (e.g., the carrier-injection layer and the common electrode) provided over the island-shaped layers can be reduced and the formation surface can be flatter. Consequently, coverage with the carrier-injection layer, the common electrode, and the like can be improved.

The common layer 114 and the common electrode 115 are provided over the layer 133R, the layer 133G, the layer 133B, the insulating layer 185, and the insulating layer 187. Before the insulating layer 185 and the insulating layer 187 are provided, there is a step due to a region where the pixel electrode and the island-shaped EL layer are provided and a region where neither the pixel electrode nor the island-shaped EL layer is provided (a region between the light-emitting elements). In the display device of one embodiment of the present invention, the step can be reduced with the insulating layer 185 and the insulating layer 187, and the coverage with the common layer 114 and the common electrode 115 can be improved. Thus, connection defects caused by step disconnection can be inhibited. In addition, an increase in electrical resistance, which is caused by local thinning of the common electrode 115 due to the step, can be inhibited.

The top surface of the insulating layer 187 preferably has a shape with higher planarity. The top surface of the insulating layer 187 may include at least one of a flat surface, a convex surface, and a concave surface. For example, the top surface of the insulating layer 187 preferably has a convex shape with a large radius of curvature.

The insulating layer 185 may have a single-layer structure or a stacked-layer structure of two or more layers. The insulating layer 185 preferably includes one or more inorganic insulating layers. For the insulating layer 185, a material that can be used for the insulating layer 110 can be used. In particular, aluminum oxide is preferably used because it has high selectivity with respect to the EL layer in etching and has a function of protecting the EL layer in forming the insulating layer 187. In particular, when an inorganic insulating film such as an aluminum oxide film, a hafnium oxide film, or a silicon oxide film is formed by an ALD method as the insulating layer 185, the insulating layer 185 can have few pinholes and an excellent function of protecting the EL layer. The insulating layer 185 may have a stacked-layer structure of a film formed by an ALD method and a film formed by a sputtering method. The insulating layer 185 may have a stacked-layer structure of an aluminum oxide film formed by an ALD method and a silicon nitride film formed by a sputtering method, for example.

The insulating layer 185 preferably has a function of a barrier insulating layer against at least one of water and oxygen. The insulating layer 185 preferably has a function of inhibiting diffusion of at least one of water and oxygen. Alternatively, the insulating layer 185 preferably has a function of capturing or fixing (gettering) at least one of water and oxygen.

When the insulating layer 185 has a function of the barrier insulating layer, entry of impurities (typically, at least one of water and oxygen) that would be diffused to the light-emitting elements from the outside can be inhibited. With this structure, a highly reliable light-emitting element and a highly reliable display device can be provided.

The insulating layer 185 preferably has a low impurity concentration. In that case, degradation of the EL layer due to entry of impurities into the EL layer from the insulating layer 185 can be inhibited. In addition, when the impurity concentration is reduced in the insulating layer 185, a barrier property against at least one of water and oxygen can be increased. For example, the insulating layer 185 preferably has a sufficiently low hydrogen concentration or a sufficiently low carbon concentration, and further preferably has both a sufficiently low hydrogen concentration and a sufficiently low carbon concentration.

The insulating layer 187 provided over the insulating layer 185 has a function of reducing unevenness with a large level difference on the insulating layer 185, which is formed between the adjacent light-emitting elements. In other words, the insulating layer 187 has an effect of improving the planarity of the formation surface of the common electrode 115.

As the insulating layer 187, an insulating layer including an organic material can be suitably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic polymers in a broad sense in some cases.

Alternatively, the insulating layer 187 may be formed using an acrylic resin, a polyimide resin, an epoxy resin, an imide resin, a polyamide resin, a polyimide-amide resin, a silicone resin, a siloxane resin, a benzocyclobutene-based resin, a phenol resin, any of precursors of these resins, or the like. The insulating layer 187 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used as the photosensitive resin. As the photosensitive organic resin, either a positive-type material or a negative-type material may be used.

The insulating layer 187 may be formed using a material absorbing visible light. When the insulating layer 187 absorbs light emitted from the light-emitting element, light leakage (stray light) from the light-emitting element to the adjacent light-emitting element through the insulating layer 187 can be suppressed. Thus, the display quality of the display device can be improved. Since no polarizing plate is required to improve the display quality of the display device, the weight and thickness of the display device can be reduced.

Examples of the material absorbing visible light include a material containing a pigment of black or any other color, a material containing a dye, a light-absorbing resin material (e.g., polyimide), and a resin material that can be used for color filters (a color filter material). Using a resin material obtained by stacking or mixing color filter materials of two or three or more colors is particularly preferred to enhance the effect of blocking visible light. In particular, mixing color filter materials of three or more colors enables the formation of a black or nearly black resin layer.

### [Display Device 10F]

FIG. 40B illustrates an example of a cross section of the display portion 162 of a display device 10F. The display device 10F is different from the display device 10E mainly in that the subpixels of different colors each include a coloring layer (color filter) and a light-emitting element including a layer 133. The structure illustrated in FIG. 40B can be combined with the structure of the region including the FPC 172, the circuit portion 164, the stacked-layer structure from the substrate 102 to the insulating layer 235 in the display portion 162, the connection portion 140, and the end portion, which is illustrated in FIG. 40A.

In the display device 10F illustrated in FIG. 40B, the light-emitting element 60R, the light-emitting element 60G, the light-emitting element 60B, the coloring layer 132R transmitting red light, the coloring layer 132G transmitting green light, the coloring layer 132B transmitting blue light, and the like are provided.

Light emitted from the light-emitting element 60R is extracted as red light to outside the display device 10F through the coloring layer 132R. Similarly, light emitted from the light-emitting element 60G is extracted as green light to outside the display device 10F through the coloring layer 132G. Light emitted from the light-emitting element 60B is extracted as blue light to outside the display device 10F through the coloring layer 132B.

The light-emitting element 60R, the light-emitting element 60G, and the light-emitting element 60B each include the layer 133. The three layers 133 are formed using the same material in the same step. The three layers 133 are apart from each other. When the EL layer is provided to have an island shape for each light-emitting element, a leakage current between adjacent light-emitting elements can be inhibited. This can prevent crosstalk-induced unintended light emission, so that the display device can achieve extremely high contrast.

The light-emitting element 60R, the light-emitting element 60G, and the light-emitting element 60B illustrated in FIG. 40B emit white light, for example. White light emitted from the light-emitting element 60R passes through the coloring layer 132R, white light emitted from the light-emitting element 60G passes through the coloring layer 132G, and white light emitted from the light-emitting element 60B passes through the coloring layer 132B. Thus, light of desired colors can be obtained.

Alternatively, the light-emitting element 60R, the light-emitting element 60G, and the light-emitting element 60B illustrated in FIG. 40B emit blue light, for example. In this case, the layer 133 includes one or more light-emitting layers that emit blue light. In the subpixel 23B that emits blue light, blue light emitted from the light-emitting element 60B can be extracted. In each of the subpixel 23R that emits red light and the subpixel 23G that emits green light, by providing a color conversion layer between the light-emitting element 60R or the light-emitting element 60G and the substrate 152, blue light emitted from the light-emitting element 60R or the light-emitting element 60G can be converted into light with a longer wavelength, and red light or green light can be extracted. Furthermore, it is preferable that over the light-emitting element 60R, the coloring layer 132R be provided between the color conversion layer and the substrate 152 and over the light-emitting element 60G, the coloring layer 132G be provided between the color conversion layer and the substrate 152. When light transmitted through the color conversion layer is extracted through the coloring layer, light other than light of the intended color can be absorbed by the coloring layer, and the color purity of light emitted from a subpixel can be improved.

### [Display Device 10G]

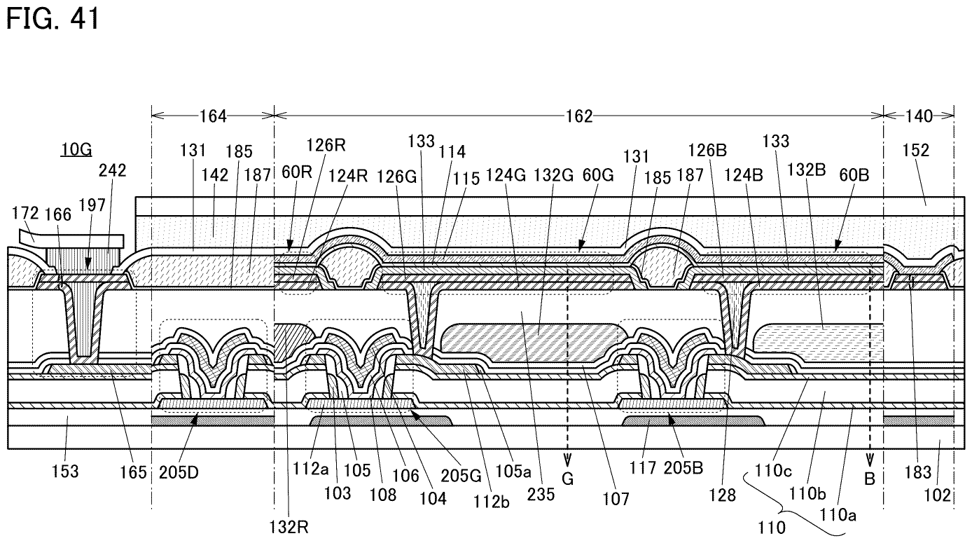

A display device 10G illustrated in FIG. 41 is different from the display device 10F mainly in having a bottom-emission structure.

Light from the light-emitting element is emitted toward the substrate 102. For the substrate 102, a material having a good visible-light-transmitting property is preferably used. By contrast, there is no limitation on the light-transmitting property of a material used for the substrate 152.

The light-blocking layer 117 is preferably formed between the substrate 102 and the transistor. In the example illustrated in FIG. 41, the light-blocking layers 117 are provided over the substrate 102, the insulating layer 153 is provided over the light-blocking layers 117, and the transistor 205D, the transistor 205R (not illustrated), the transistor 205G, the transistor 205B, and the like are provided over the insulating layer 153. In addition, the coloring layer 132R, the coloring layer 132G, and the coloring layer 132B are provided over the insulating layer 107, and the insulating layer 235 is provided over the coloring layer 132R, the coloring layer 132G, and the coloring layer 132B.

The light-emitting element 60R overlapping with the coloring layer 132R includes the conductive layer 124R, the conductive layer 126R, the layer 133, the common layer 114, and the common electrode 115.

The light-emitting element 60G overlapping with the coloring layer 132G includes the conductive layer 124G, the conductive layer 126G, the layer 133, the common layer 114, and the common electrode 115.

The light-emitting element 60B overlapping with the coloring layer 132B includes the conductive layer 124B, the conductive layer 126B, the layer 133, the common layer 114, and the common electrode 115.

A material having a good visible-light-transmitting property is used for each of the conductive layer 124R, the conductive layer 124G, the conductive layer 124B, the conductive layer 126R, the conductive layer 126G, and the conductive layer 126B. A material that reflects visible light is preferably used for the common electrode 115. In the display device having a bottom-emission structure, the common electrode 115 can be formed using a metal with low electrical resistivity, for example; thus, a voltage drop due to the resistance of the common electrode 115 can be suppressed and the display quality can be high.

The transistor of one embodiment of the present invention can be miniaturized and the area occupied by the transistor can be reduced, so that the aperture ratio of the pixel can be increased or the pixel size can be reduced in the display device having a bottom-emission structure.

### [Display Device 10H]

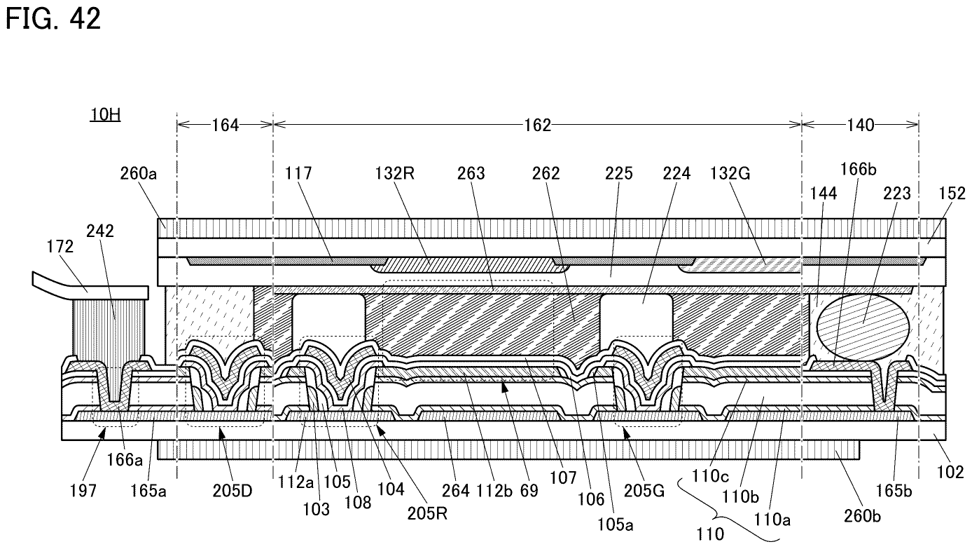

A display device 10H illustrated in FIG. 42 is a liquid crystal display device in a VA mode.

The substrate 102 and the substrate 152 are bonded to each other with an adhesive layer 144. The liquid crystal 262 is sealed in a region that is surrounded by the substrate 102, the substrate 152, and the adhesive layer 144. A polarizing plate 260a is positioned on the outer surface of the substrate 152, and a polarizing plate 260b is positioned on the outer surface of the substrate 102. Although not shown, a backlight can be provided outside the polarizing plate 260a or outside the polarizing plate 260b.

The substrate 102 is provided with the transistor 205D, the transistor 205R, the transistor 205G, the connection portion 197, a spacer 224, and the like. The transistor 205D is provided in the circuit portion 164, and the transistor 205R and the transistor 205G are provided in the display portion 162. The conductive layers 112b included in the transistor 205R and the transistor 205G each function as a pixel electrode of the liquid crystal element 69.

The coloring layer 132R, the coloring layer 132G, the light-blocking layer 117, an insulating layer 225, the conductive layer 263, and the like are provided on the substrate 152. The conductive layer 263 functions as a common electrode of the liquid crystal element 69.

As described above, this embodiment describes an example in which OS transistors are used as the transistor 205D, the transistor 205R, and the transistor 205G. Any of the transistors of embodiments of the present invention can be used as the transistor 205D, the transistor 205R, and the transistor 205G. In other words, the display device 10H includes any of the transistors of embodiments of the present invention in both the display portion 162 and the circuit portion 164. When the display portion 162 includes the transistor of one embodiment of the present invention, the pixel size can be reduced and high resolution can be achieved. When the circuit portion 164 includes the transistor of one embodiment of the present invention, the area occupied by the circuit portion 164 can be reduced and a narrower bezel can be achieved. The description in the above embodiment can be referred to for the transistor of one embodiment of the present invention.

The transistor 205D, the transistor 205R, and the transistor 205G are covered with the insulating layer 107. The insulating layer 107 functions as a protective layer for the transistor 205D, the transistor 205R, and the transistor 205G.

The subpixel included in the display portion 162 includes a transistor, the liquid crystal element 69, and a coloring layer. For example, a subpixel that emits red light includes the transistor 205R, the liquid crystal element 69, and the coloring layer 132R that transmits red light. A subpixel that emits green light includes the transistor 205G, the liquid crystal element 69, and the coloring layer 132G that transmits green light. Similarly, although not shown, a subpixel that emits blue light includes a transistor, the liquid crystal element 69, and a coloring layer that transmits blue light.

The liquid crystal element 69 includes the conductive layer 112b, a conductive layer 263, and a liquid crystal 262 interposed therebetween.

Over the substrate 102, a conductive layer 264 positioned on the same plane as the conductive layer 112a is provided. The conductive layer 264 includes a portion overlapping with the conductive layer 112b with the insulating layer 110 therebetween. The conductive layer 112b, the conductive layer 264, and the insulating layer 110 positioned therebetween form a storage capacitor. Note that any one or two layers included in the insulating layer 110 may be removed by etching as long as at least one insulating layer is provided between the conductive layer 112b and the conductive layer 264.

The insulating layer 225 is provided on the substrate 152 side to cover the coloring layer 132R, the coloring layer 132G, and the light-blocking layer 117. The insulating layer 225 may have a function of a planarization film. The conductive layer 263 can have a substantially flat surface owing to the insulating layer 225, resulting in a uniform alignment state of the liquid crystal 262.

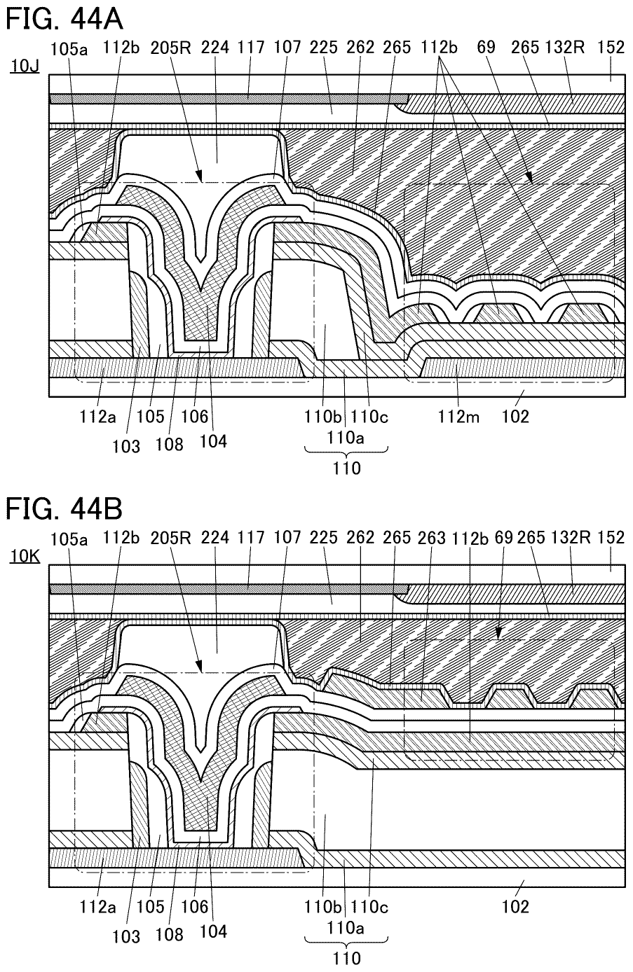

Note that in the conductive layer 263, the insulating layer 107, and the like, the surface in contact with the liquid crystal 262 may be provided with an alignment film for controlling the alignment of the liquid crystal 262 (see an alignment film 265 in FIG. 44A and FIG. 44B).

The conductive layer 112b and the conductive layer 263 transmit visible light. Thus, a transmissive liquid crystal device can be obtained. For example, in the case where a backlight is provided on the substrate 152 side, light from the backlight that is polarized by the polarizing plate 260a passes through the substrate 152, the conductive layer 263, the liquid crystal 262, the conductive layer 112b, and the substrate 102, and then reaches the polarizing plate 260b. In this case, optical modulation of the light can be controlled by controlling the alignment of the liquid crystal 262 with voltage supplied between the conductive layer 112b and the conductive layer 263. In other words, the intensity of light emitted through the polarizing plate 260b can be controlled. Incident light other than light in a particular wavelength range is absorbed by the coloring layer, and thus, extracted light is red light, for example.

Here, as the polarizing plate 260b, a linear polarizing plate may be used or a circularly polarizing plate can also be used. An example of a circularly polarizing plate is a stack including a linear polarizing plate and a quarter-wave retardation plate. Reflection of external light can be inhibited with a circularly polarizing plate used as the polarizing plate 260b.

Note that in the case where a circularly polarizing plate is used as the polarizing plate 260b, a circularly polarizing plate or a general linear polarizing plate may be used as the polarizing plate 260a. The cell gap, alignment, driving voltage, and the like of the liquid crystal element used as the liquid crystal element 69 are adjusted in accordance with the kinds of polarizing plates used as the polarizing plate 260a and the polarizing plate 260b so that desirable contrast is obtained.

The conductive layer 263 is electrically connected to a conductive layer 166b provided on the substrate 102 side through a connector 223 in the connection portion 140. The conductive layer 166b is connected to a conductive layer 165b through an opening portion provided in the insulating layer 110 and the insulating layer 105. Thus, a potential or a signal can be supplied to the conductive layer 263 from an FPC or an IC provided on the substrate 102 side. In the structure example illustrated in FIG. 42, the conductive layer 165b is formed using the same material in the same step as the conductive layer 112a, and the conductive layer 166b is formed using the same material in the same step as the conductive layer 104.

As the connector 223, a conductive particle can be used, for example. As the conductive particle, a particle of an organic resin, silica, or the like coated with a metal material can be used. It is preferable to use nickel or gold as the metal material to reduce contact resistance. It is also preferable to use a particle coated with layers of two or more kinds of metal materials, such as a particle coated with nickel and further with gold. As the connector 223, a material capable of elastic deformation or plastic deformation is preferably used. In that case, as illustrated in FIG. 42, the conductive particle sometimes has a shape that is vertically crushed. This increases the contact area between the connector 223 and a conductive layer electrically connected to the connector 223, thereby reducing contact resistance and inhibiting generation of defects such as poor connection. The connector 223 is preferably provided to be covered with the adhesive layer 144. For example, the connectors 223 are preferably dispersed in the adhesive layer 144 before curing of the adhesive layer 144.

The connection portion 197 is provided in a region near the end portion of the substrate 102. In the connection portion 197, a conductive layer 166a is electrically connected to the FPC 172 through the connection layer 242. The conductive layer 166a is connected to a conductive layer 165a through an opening portion provided in the insulating layer 110 and the insulating layer 105. In the structure example illustrated in FIG. 42, the conductive layer 165a is formed using the same material in the same step as the conductive layer 112a, and the conductive layer 166a is formed using the same material in the same step as the conductive layer 104.

### [Display Device 10I]

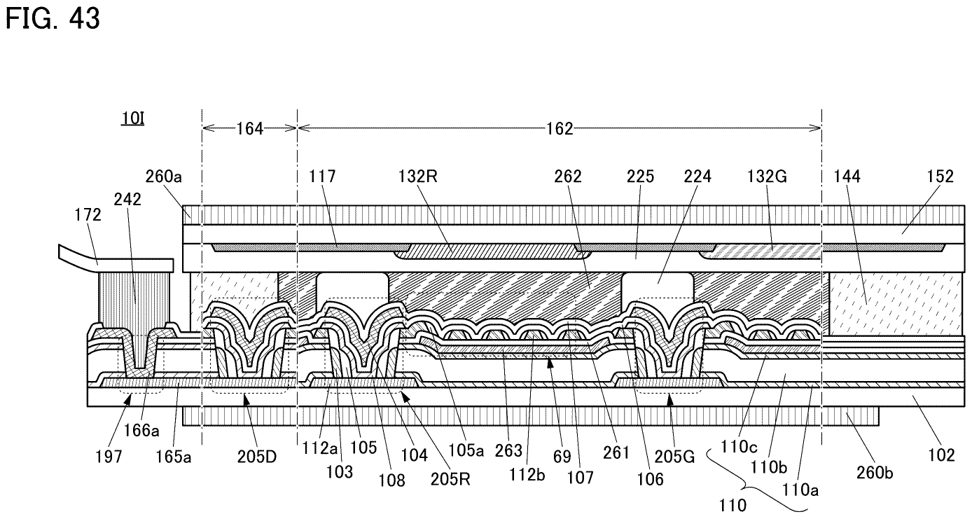

A display device 10I illustrated in FIG. 43 is a liquid crystal display device in an FFS mode. The display device 10I is different from the display device 10H mainly in the structure of the liquid crystal element 69.

The conductive layer 263 functioning as the common electrode of the liquid crystal element 69 is provided over the insulating layer 110, and an insulating layer 261 is provided over the conductive layer 263. The conductive layer 112b having a function of the other of the source electrode and the drain electrode of the transistor and a function of the pixel electrode of the liquid crystal element 69 is provided over the insulating layer 261. The insulating layer 107 is provided over the conductive layer 112b.

In a plan view, the conductive layer 112b has a comb-like shape or a shape with a slit. The conductive layer 263 is provided to overlap with the conductive layer 112b. There is a portion where the conductive layer 112b is not provided over the conductive layer 263 in a region overlapping with the coloring layer.

The conductive layer 112b and the conductive layer 263 are stacked with the insulating layer 261 therebetween, whereby a capacitor is formed. Therefore, it is not necessary to provide a capacitor separately, and the aperture ratio of the pixel can be increased.

Note that in the liquid crystal element 69, both the conductive layer 112b and the conductive layer 263 may have comb-like plan-view shapes. Meanwhile, when only one of the conductive layer 112b and the conductive layer 263 in the liquid crystal element 69 has a comb-like plan-view shape as in the display device 10I, the conductive layer 112b and the conductive layer 263 partly overlap with each other. This allows the capacitance between the conductive layer 112b and the conductive layer 263 to be used as a storage capacitor; thus, a capacitor does not need to be provided separately, and the aperture ratio of the display device can be increased.

[Display device 10J]

In a display device 10J illustrated in FIG. 44A, a portion of the insulating layer 110b that overlaps with the liquid crystal element 69 is removed by etching. The liquid crystal element 69 included in the display device 10J includes a portion where the conductive layer 112b, the insulating layer 110a, the insulating layer 110c, and the conductive layer 112b are stacked in this order. The liquid crystal element 69 and the insulating layer 110b do not overlap with each other, which enables not only an increase in the light transmittance but also a reduction in the number of interfaces positioned on the path of light from the light source; accordingly, the influences of interface reflection and interface scattering can be inhibited.

The conductive layer 112b functions as the pixel electrode of the liquid crystal element 69. A conductive layer 112m functions as the common electrode of the liquid crystal element 69. The conductive layer 112m and the conductive layer 112a are formed using the same conductive film.

Note that a portion of one or both of the insulating layer 106 and the insulating layer 107 that overlaps with the liquid crystal element 69 may be removed by etching. Alternatively, the insulating layer 107 is not necessarily provided. This facilitates transmission of the electric fields of the conductive layer 112b and the conductive layer 112m to the liquid crystal 262, which enables high-speed operation of the liquid crystal element 69. Furthermore, the light transmittance of a portion overlapping with the liquid crystal element 69 can be increased and the influences of interface reflection and interface scattering can be inhibited. A portion of one of the insulating layer 110a and the insulating layer 110c that overlaps with the liquid crystal element 69 may be removed by etching. This also facilitates transmission of the electric fields of the conductive layer 112b and the conductive layer 112m to the liquid crystal 262. Furthermore, the capacitance between the conductive layer 112b and the conductive layer 112m can be increased in some cases.

In the liquid crystal element 69, both the conductive layer 112b and the conductive layer 112m may have comb-like plan-view shapes. Meanwhile, when only one of the conductive layer 112b and the conductive layer 112m in the liquid crystal element 69 has a comb-like plan-view shape as in the display device 10J, the conductive layer 112b and the conductive layer 112m partly overlap with each other. This allows the capacitance between the conductive layer 112b and the conductive layer 112m to be used as a storage capacitor; thus, a capacitor does not need to be provided separately, and the aperture ratio of the display device can be increased.

### [Display Device 10K]

A display device 10K illustrated in FIG. 44B is different from the display device 10I mainly in that the pixel electrode is provided over the common electrode. The conductive layer 112b included in the transistor 100 functions as the pixel electrode of the liquid crystal element 69. The insulating layer 106 and the insulating layer 107 are provided over the conductive layer 112b, and the conductive layer 263 is provided over the insulating layer 107. The conductive layer 263 functions as the common electrode of the liquid crystal element 69. In a plan view, the conductive layer 263 has a comb-like shape or a shape with a slit.

This embodiment can be combined with any of the other embodiments as appropriate. In this specification, in the case where a plurality of structure examples are described in one embodiment, the structure examples can be combined as appropriate.

### Embodiment 4

In this embodiment, electronic devices of embodiments of the present invention will be described.

Electronic devices of this embodiment each include the display device of one embodiment of the present invention in a display portion. The display device of one embodiment of the present invention can be easily increased in resolution and definition. Thus, the display device of one embodiment of the present invention can be used for a display portion of a variety of electronic devices.

The semiconductor device of one embodiment of the present invention can also be applied to any other portion of an electronic device than a display portion. For example, the semiconductor device of one embodiment of the present invention is preferably used for a control portion of an electronic device to enable lower power consumption.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and notebook computers, a monitor of a computer and the like, digital signage, and a large game machine such as a pachinko machine.

In particular, the display device of one embodiment of the present invention can have high resolution, and thus can be suitably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, further preferably higher than or equal to 2000 ppi, further preferably higher than or equal to 3000 ppi, further preferably higher than or equal to 5000 ppi, further preferably higher than or equal to 7000 ppi. The use of the display device having one or both of such high definition and high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of this embodiment can have a variety of functions. For example, the electronic device of this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

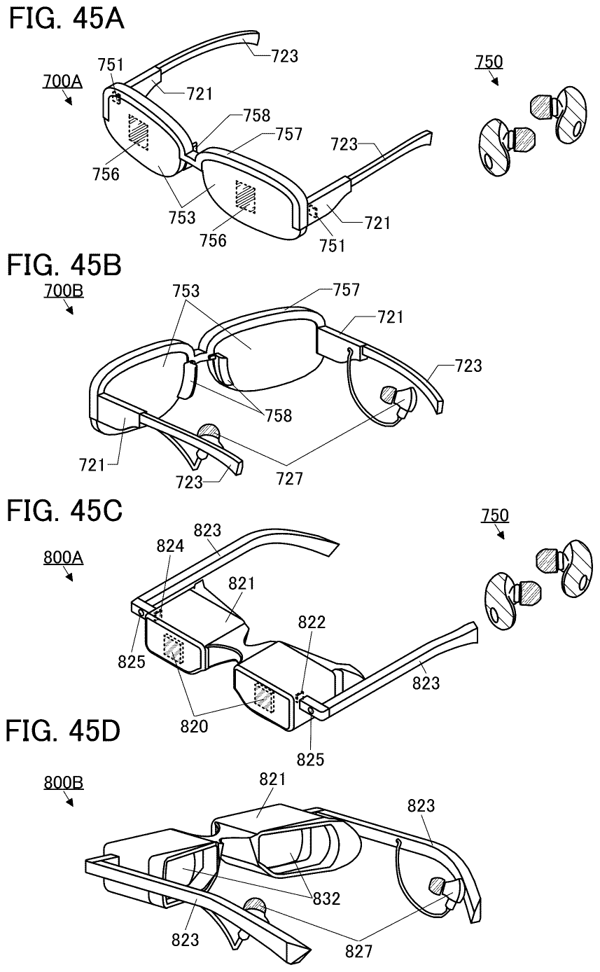

Examples of head-mounted wearable devices will be described with reference to FIG. 45A to FIG. 45D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 45A and an electronic device 700B illustrated in FIG. 45B each include a pair of display panels 751, a pair of housings 721, a communication portion (not shown), a pair of wearing portions 723, a control portion (not shown), an image capturing portion (not shown), a pair of optical members 753, a frame 757, and a pair of nose pads 758.

The display device of one embodiment of the present invention can be used for the display panels 751. Thus, the electronic device is capable of displaying a high-quality image.

The electronic device 700A and the electronic device 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic device 700A and the electronic device 700B are each provided with a battery, so that they can be charged wirelessly and/or by wire.

A touch sensor module may be provided in the housing 721. The touch sensor module has a function of detecting touch on the outer surface of the housing 721. Detecting a tap operation, a slide operation, or the like by the user with the touch sensor module enables executing various types of processing. For example, a moving image can be paused or restarted by a tap operation, and can be fast-forwarded or fast-reversed by a slide operation. When the touch sensor module is provided in each of the two housings 721, the range of the operation can be expanded.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 45C and an electronic device 800B illustrated in FIG. 45D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic device is capable of displaying a high-quality image. Moreover, the electronic devices are capable of performing ultrahigh-resolution display, and such electronic devices can provide an enhanced sense of immersion to the user.

The display portions 820 are positioned inside the housing 821 so as to be seen through the lenses 832. When the pair of display portions 820 display different images, three-dimensional display using parallax can be performed.

Each of the electronic device 800A and the electronic device 800B can be regarded as an electronic device for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic device 800A or the electronic device 800B can be mounted on the user's head with the wearing portions 823. FIG. 45C, for example, illustrates an example in which the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example in which the image capturing portion 825 is included is described here, a range sensor that is capable of measuring the distance to an object (hereinafter such a sensor is also referred to as a sensing portion) is provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more pieces of information can be obtained and a gesture operation with higher accuracy is possible.

The electronic device 800A may include a vibration mechanism that functions as a bone-conduction earphone. For example, any one or more of the display portion 820, the housing 821, and the wearing portion 823 can include the vibration mechanism. In that case, without additionally requiring an audio device such as headphones, earphones, or a speaker, the user can enjoy video and sound only by wearing the electronic device 800A.

The electronic device 800A and the electronic device 800B may each include an input terminal. To the input terminal, for example, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not shown) and have a wireless communication function. The earphones 750 can receive information (e.g., audio data) from the electronic device with the wireless communication function. For example, the electronic device 700A in FIG. 45A has a function of transmitting information to the earphones 750 with the wireless communication function. For another example, the electronic device 800A in FIG. 45C has a function of transmitting information to the earphones 750 with the wireless communication function.

The electronic device may include an earphone portion. The electronic device 700B in FIG. 45B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic device 800B in FIG. 45D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type devices (the electronic device 700A, the electronic device 700B, and the like) and the goggles-type devices (the electronic device 800A, the electronic device 800B, and the like) are suitable as the electronic devices of embodiments of the present invention.

The electronic device of one embodiment of the present invention can transmit information to earphones by wire or wirelessly.

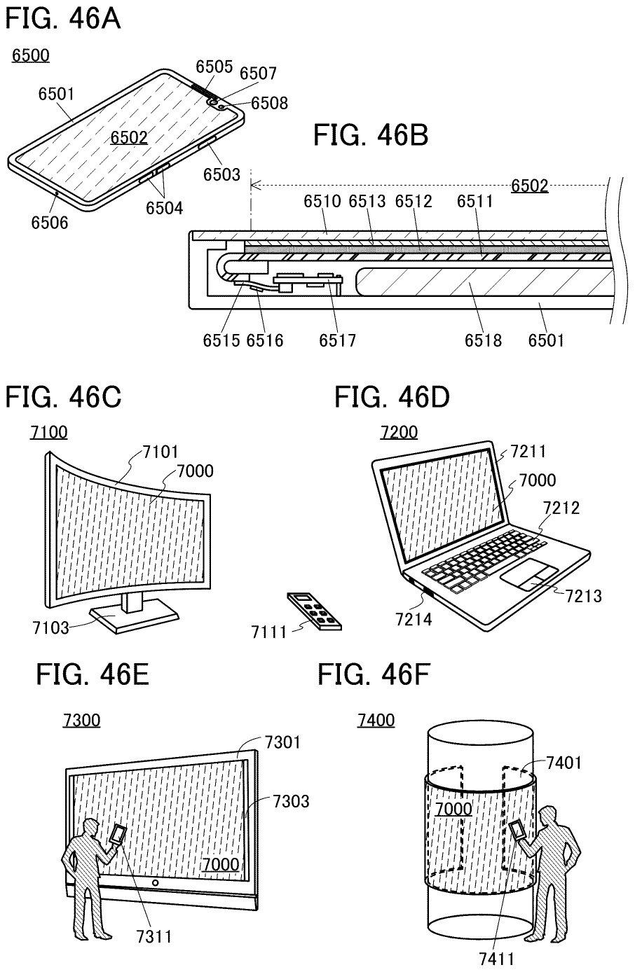

An electronic device 6500 illustrated in FIG. 46A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic device 6500 is capable of displaying a high-quality image.

FIG. 46B is a schematic cross-sectional view including the end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not shown).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be obtained.

FIG. 46C illustrates an example of a television device. In a television device 7100, a display portion 7000 is incorporated in a housing 7101. Here, the housing 7101 is supported by a stand 7103.

The display device of one embodiment of the present invention can be used in the display portion 7000. Thus, the television device 7100 is capable of displaying a high-quality image.

Operation of the television device 7100 illustrated in FIG. 46C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 46D illustrates an example of a notebook computer. The notebook computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, the notebook computer 7200 is capable of displaying a high-quality image.

FIG. 46E and FIG. 46F illustrate examples of digital signage.

Digital signage 7300 illustrated in FIG. 46E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 46F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIG. 46E and FIG. 46F. Thus, the digital signage 7300 and the digital signage 7400 are capable of displaying a high-quality image.

The display portion 7000 having a larger area can provide a larger amount of information at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 46E and FIG. 46F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

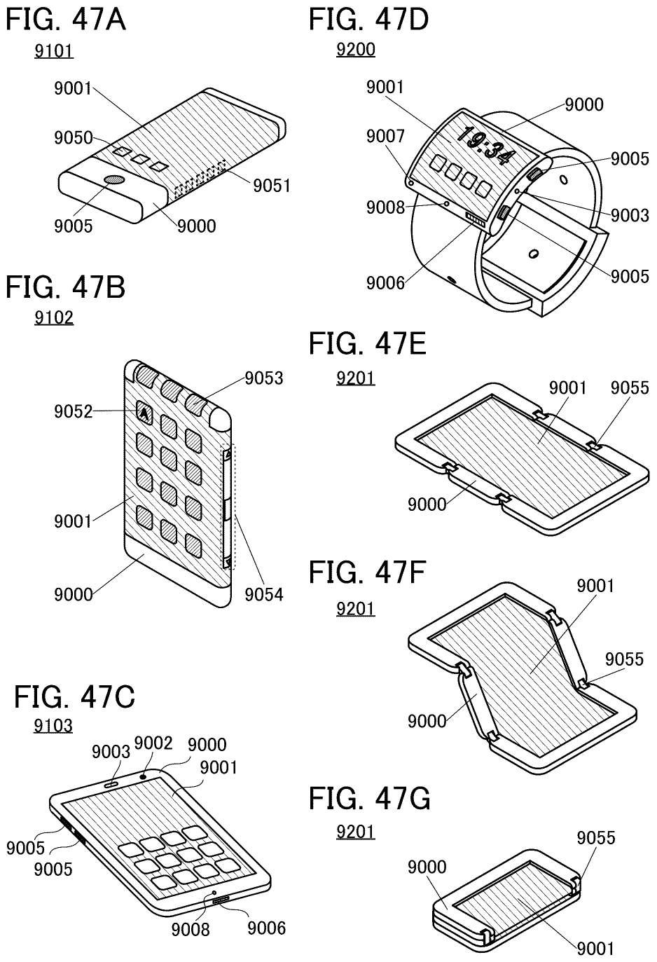

Electronic devices illustrated in FIG. 47A to FIG. 47G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

In FIG. 47A to FIG. 47G, the display device of one embodiment of the present invention can be used in the display portion 9001. Thus, the electronic devices illustrated in FIG. 47A to FIG. 47G are capable of displaying a high-quality image.

The electronic devices illustrated in FIG. 47A to FIG. 47G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera, for example, and have a function of capturing a still image or a moving image, a function of storing the captured image in a storage medium (an external storage medium or a storage medium incorporated in the camera), a function of displaying the captured image on the display portion, and the like.

The electronic devices in FIG. 47A to FIG. 47G will be described in detail below.

FIG. 47A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 47A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 47B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 47C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 47D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 47E to FIG. 47G are perspective views of a foldable portable information terminal 9201. FIG. 47E is a perspective view illustrating the portable information terminal 9201 that is opened. FIG. 47G is a perspective view illustrating the portable information terminal 9201 that is folded. FIG. 47F is a perspective view illustrating the portable information terminal 9201 that is shifted from one of the states in FIG. 47E and FIG. 47G to the other. The portable information terminal 9201 is highly portable in the folded state and is highly browsable in the opened state because of its seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate. In this specification, in the case where a plurality of structure examples are described in one embodiment, the structure examples can be combined as appropriate.

### REFERENCE NUMERALS

10A: display device, 10B: display device, 10C: display device, 10D: display device, 10E: display device, 10F: display device, 10G: display device, 10H: display device, 10I: display device, 10J: display device, 10K: display device, 10: display device, 11: scan line driver circuit, 13: signal line driver circuit, 20: display portion, 21a: pixel, 21b: pixel, 21: pixel, 23a: subpixel, 23B: subpixel, 23b: subpixel, 23c: subpixel, 23d: subpixel, 23e: subpixel, 23G: subpixel, 23R: subpixel, 23: subpixel, 30A: semiconductor device, 30B: semiconductor device, 30C: semiconductor device, 30D: semiconductor device, 30E: semiconductor device, 30: semiconductor device, 40A: pixel circuit, 40B: pixel circuit, 40C: pixel circuit, 40D: pixel circuit, 40E: pixel circuit, 41a: wiring, 41b: wiring, 41c: wiring, 41: wiring, 43: wiring, 45: wiring, 46a: wiring, 46b: wiring, 46: wiring, 47: wiring, 48: wiring, 49: wiring, 51: transistor, 52: transistor, 53: transistor, 54: transistor, 57: capacitor, 58: capacitor, 60B: light-emitting element, 60G: light-emitting element, 60R: light-emitting element, 60: light-emitting element, 61: light-receiving element, 69: liquid crystal element, 100: transistor, 102: substrate, 103f: conductive film, 103: conductive layer, 104: conductive layer, 105a: insulating layer, 105f: insulating film, 105: insulating layer, 106: insulating layer, 107: insulating layer, 108f: semiconductor film, 108: semiconductor layer, 109: insulating layer, 110a: insulating layer, 110b: insulating layer, 110c: insulating layer, 110: insulating layer, 111B: pixel electrode, 111G: pixel electrode, 111R: pixel electrode, 111S: pixel electrode, 112a: conductive layer, 112b: conductive layer, 112c: conductive layer, 112f: conductive film, 112m: conductive layer, 113B: EL layer, 113G: EL layer, 113R: EL layer, 113S: functional layer, 113: EL layer, 114: common layer, 115: common electrode, 116: conductive layer, 117: light-blocking layer, 119: conductive layer, 120: insulating layer, 121: portion, 123: portion, 124B: conductive layer, 124G: conductive layer, 124R: conductive layer, 125: region, 126B: conductive layer, 126G: conductive layer, 126R: conductive layer, 127: region, 128: layer, 129: depressed portion, 131: protective layer, 132B: coloring layer, 132G: coloring layer, 132R: coloring layer, 133B: layer, 133G: layer, 133R: layer, 133: layer, 140: connection portion, 141: opening portion, 142: adhesive layer, 143: opening portion, 144: adhesive layer, 145: opening portion, 146a: opening portion, 146b: opening portion, 147a: opening portion, 147b: opening portion, 149: opening portion, 150A: transistor, 150: transistor, 152: substrate, 153: insulating layer, 162: display portion, 164: circuit portion, 165a: conductive layer, 165b: conductive layer, 165: conductive layer, 166a: conductive layer, 166b: conductive layer, 166: conductive layer, 172: FPC, 173: IC, 183: conductive layer, 185: insulating layer, 187: insulating layer, 190: capacitor, 197: connection portion, 200: transistor, 202: conductive layer, 203: conductive layer, 204: conductive layer, 205B: transistor, 205D: transistor, 205G: transistor, 205R: transistor, 205S: transistor, 205: insulating layer, 208D: region, 208L: region, 208: semiconductor layer, 212a: conductive layer, 212b: conductive layer, 223: connector, 224: spacer, 225: insulating layer, 235: insulating layer, 237: insulating layer, 241: opening portion, 242: connection layer, 243: opening portion, 250: transistor, 252: insulating layer, 253D: region, 253: semiconductor layer, 254: insulating layer, 255: conductive layer, 256: insulating layer, 257a: opening portion, 257b: opening portion, 258a: conductive layer, 258b: conductive layer, 259: conductive layer, 260a: polarizing plate, 260b: polarizing plate, 261: insulating layer, 262: liquid crystal, 263: conductive layer, 264: conductive layer, 265: alignment film, 352: finger, 353: layer, 355: circuit layer, 357: layer, 700A: electronic device, 700B: electronic device, 721: housing, 723: wearing portion, 727: earphone portion, 750: earphones, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: notebook computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a transistor and a first insulating layer,
wherein the transistor comprises a first conductive layer, a second conductive layer, a third conductive layer, a fourth conductive layer, a semiconductor layer, a second insulating layer, and a third insulating layer,
wherein the first insulating layer comprises a first opening portion that is provided over the first conductive layer and reaches the first conductive layer,
wherein the second conductive layer comprises a second opening portion that is provided over the first insulating layer and comprises a region overlapping with the first opening portion,
wherein the third conductive layer comprises a region in contact with a side surface of the first insulating layer that is positioned in the first opening portion,
wherein the third conductive layer comprises a region in contact with the first conductive layer,
wherein an uppermost portion of the third conductive layer is positioned below an end portion of a top surface of the first insulating layer on the first opening portion side,
wherein the second insulating layer is provided to cover the third conductive layer in the first opening portion,
wherein the semiconductor layer is provided to comprise a region in contact with the first conductive layer and a region in contact with the second conductive layer and to comprise a region facing the third conductive layer with the second insulating layer therebetween in the first opening portion,
wherein the third insulating layer is provided over the semiconductor layer to comprise a region positioned in the first opening portion, and
wherein the fourth conductive layer is provided to comprise a region facing the third conductive layer with the second insulating layer, the semiconductor layer, and the third insulating layer therebetween in the first opening portion.

2. The semiconductor device according to claim 1,
wherein the semiconductor device comprises a fourth insulating layer,
wherein the fourth insulating layer is provided between the first insulating layer and the third insulating layer, and
wherein the fourth insulating layer comprises a region in contact with a side surface of the second conductive layer on a side opposite to the second opening portion.

3. The semiconductor device according to claim 1,
wherein the second insulating layer comprises a region positioned over the first insulating layer, and
wherein the second conductive layer is provided over the second insulating layer.

4. The semiconductor device according to claim 1,
wherein the semiconductor layer comprises a metal oxide.

5. The semiconductor device according to claim 4,
wherein the metal oxide comprises two or three selected from In, an element M, and Zn, and
wherein the element Mis one or more selected from Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb.

6. A method for manufacturing a semiconductor device, the method comprising:
forming a first conductive layer,
forming a first insulating layer over the first conductive layer,
forming a second conductive layer over the first insulating layer,
processing the second conductive layer to form a first opening portion comprising a region overlapping with the first conductive layer,
processing the first insulating layer to form a second opening portion that comprises a region overlapping with the first opening portion and reaches the first conductive layer,
forming a conductive film covering the first opening portion and the second opening portion,
performing anisotropic etching on the conductive film to form a third conductive layer that comprises a region in contact with the first conductive layer and has an uppermost portion positioned below an end portion of a bottom surface of the second conductive layer on the first opening portion side,
forming an insulating film covering the second conductive layer and the third conductive layer,
performing anisotropic etching on the insulating film until at least part of a top surface of the second conductive layer is exposed to form a second insulating layer covering the third conductive layer,
forming a semiconductor layer comprising a region in contact with the first conductive layer and a region in contact with the second conductive layer,
forming a third insulating layer comprising a region positioned in the second opening portion, and
forming, over the third insulating layer, a fourth conductive layer comprising a region positioned in the second opening portion.

7. A method for manufacturing a semiconductor device, the method comprising:
forming a first conductive layer,
forming a first insulating layer over the first conductive layer,
processing the first insulating layer to form a first opening portion reaching the first conductive layer,
forming a conductive film covering the first opening portion,
performing anisotropic etching on the conductive film to form a second conductive layer that comprises a region in contact with the first conductive layer and has an uppermost portion positioned below an end portion of a top surface of the first insulating layer on the first opening portion side,
forming a second insulating layer covering the first conductive layer, the second conductive layer, and the first insulating layer,
forming, over the second insulating layer, a third conductive layer comprising a second opening portion comprising a region overlapping with the first opening portion,
forming, in the second insulating layer, a third opening portion reaching the first conductive layer in the first opening portion,
forming a semiconductor layer comprising a region in contact with the first conductive layer and a region in contact with the third conductive layer,
forming a third insulating layer comprising a region positioned in the first opening portion, and
forming, over the third insulating layer, a fourth conductive layer comprising a region positioned in the first opening portion.

8. The method for manufacturing the semiconductor device, according to claim 6,
wherein the semiconductor layer is formed by forming a semiconductor film by an ALD method and then processing the semiconductor film.
